(19) United States
(12) Patent Application Publication
(10) Pub. No.: US 2026/0313938 A1
(43) Pub. Date: Oct. 8, 2026

(54) METHOD FOR MANUFACTURING SEMICONDUCTOR DEVICE

(71) Applicant: SEMICONDUCTOR ENERGY LABORATORY CO., LTD., Atsugi-shi, Kanagawa-ken (JP)

(72) Inventors: Hidekazu MIYAIRI, Hadano, Kanagawa (JP); Shunpei YAMAZAKI, Setagaya, Tokyo (JP)

(21) Appl. No.: 19/108,228

(22) PCT Filed: Sep. 1, 2023
(86) PCT No.: PCT/IB2023/058644

§ 371 Date: Mar. 3, 2025

(30) Foreign Application Priority Data
Sep. 8, 2022 (JP) 2022-142989

(51) Int. Cl. H10D 30/01

(52) U.S. Cl. CPC H10D 30/0318

(57) ABSTRACT

A semiconductor device that can be miniaturized or highly integrated is provided. Over a first layer, a second layer, a mask, and a first resist mask are formed in this order; a first opening portion is formed in the first resist mask; the first opening portion is reduced in size in a plan view; a second opening portion is formed in a position of the mask that overlaps with the first opening portion; the first resist mask is removed; a second resist mask is formed over the mask provided with the second opening portion; a third opening portion is formed in the second resist mask; the third opening portion is reduced in size in the plan view; a fourth opening portion is formed in a position of the mask that overlaps with the third opening portion and does not overlap with the second opening portion; the second resist mask is removed; a fifth opening portion is formed in each position of the second layer that overlaps with the second opening portion or overlaps with the fourth opening portion; the mask is removed; and an oxide semiconductor in contact with a side surface of the second layer and a top surface of the first layer is formed inside the fifth opening portion.

### TECHNICAL FIELD

One embodiment of the present invention relates to a semiconductor device and a method for manufacturing the semiconductor device. Another embodiment of the present invention relates to a memory device and a method for manufacturing the memory device. Another embodiment of the present invention relates to a transistor and a method for manufacturing the transistor. Another embodiment of the present invention relates to a capacitor and a method for manufacturing the capacitor.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic device themselves are semiconductor devices and also include a semiconductor device.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a semiconductor material applicable to a transistor and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a memory device that can retain stored contents for a long time by utilizing a feature of a low leakage current of the transistor including an oxide semiconductor.

In recent years, demand for an integrated circuit with higher density has risen with reductions in size and weight of electronic devices. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor using an oxide semiconductor film and a second transistor using an oxide semiconductor film.

Furthermore, with use of vertical transistors, an integrated circuit with higher density can be achieved. For example, Patent Document 4 discloses a vertical transistor in which a side surface of an oxide semiconductor is covered with a gate electrode with a gate insulator therebetween.

### REFERENCE

### Patent Document

[Patent Document 1] Japanese Published Patent Application No. 2012-257187

[Patent Document 2] Japanese Published Patent Application No. 2011-151383

[Patent Document 3] PCT International Publication No. 2021/053473

[Patent Document 4] Japanese Published Patent Application No. 2013-211537

### Non-Patent Document

[Non-Patent Document 1] M. Oota et. al, “3D-Stacked CAAC-In-Ga-Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a transistor, a semiconductor device, or a memory device that can be miniaturized or highly integrated. Another object of one embodiment of the present invention is to provide a highly reliable transistor, a highly reliable semiconductor device, or a highly reliable memory device. Another object of one embodiment of the present invention is to provide a transistor with a high on-state current. Another object of one embodiment of the present invention is to provide a transistor with favorable electrical characteristics. Another object of one embodiment of the present invention is to provide a semiconductor device or memory device with reduced power consumption. Another object of one embodiment of the present invention is to provide a memory device that operates at high speed. Another object of one embodiment of the present invention is to provide a method for manufacturing any of the above transistor, semiconductor device, or memory device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a method for manufacturing a semiconductor device including steps of: forming a second layer over a first layer; forming a mask over the second layer; forming a first resist mask over the mask; forming a first opening portion in the first resist mask; reducing the first opening portion in size in a plan view; forming a second opening portion in a position of the mask that overlaps with the first opening portion; removing the first resist mask; forming a second resist mask over the mask provided with the second opening portion; forming a third opening portion in the second resist mask; reducing the third opening portion in size in the plan view; forming a fourth opening portion in a position of the mask that overlaps with the third opening portion and does not overlap with the second opening portion; removing the second resist mask; forming a fifth opening portion in each position of the second layer that overlaps with the second opening portion or overlaps with the fourth opening portion; removing the mask; and forming an oxide semiconductor in contact with a side surface of the second layer and a top surface of the first layer inside the fifth opening portion.

Another embodiment of the present invention is a method for manufacturing a semiconductor device including steps of: forming a second layer over a first layer; forming a first mask over the second layer; forming a second mask over the first mask; forming a first resist mask over the second mask; forming a first opening portion in the first resist mask; reducing the first opening portion in size in a plan view; forming a second opening portion in a position of the second mask that overlaps with the first opening portion; removing the first resist mask; forming a second resist mask over the second mask provided with the second opening portion; forming a third opening portion in the second opening portion; reducing the third opening portion in size in the plan view; forming a fourth opening portion in a position of the second mask that overlaps with the third opening portion and does not overlap with the second opening portion; removing the second resist mask; forming a fifth opening portion in each position of the first mask that overlaps with the second opening portion or overlaps with the fourth opening portion; removing the second mask; forming a sixth opening portion in a position of the second layer that overlaps with the fifth opening portion; removing the first mask; and forming an oxide semiconductor in contact with a side surface of the second layer and a top surface of the first layer inside the sixth opening portion.

It is preferable to concurrently perform the step of reducing the first opening portion in size and the step of forming the second opening portion.

It is preferable to concurrently perform the step of reducing the third opening portion in size and the step of forming the fourth opening portion.

It is preferable that the second mask include the same material as at least a part of the second layer. It is preferable to remove the second resist mask during the step of forming the sixth opening portion.

It is preferable that the first layer be a conductor.

It is preferable that as the second layer, an insulator of one or more layers be formed and a conductor be formed over the insulator.

It is preferable to use an atomic layer deposition (ALD) method in the step of forming the oxide semiconductor.

### Effect of the Invention

According to one embodiment of the present invention, a transistor, a semiconductor device, or a memory device that can be miniaturized or highly integrated can be provided. According to one embodiment of the present invention, a highly reliable transistor, semiconductor device, or memory device can be provided. According to one embodiment of the present invention, a transistor with a high on-state current can be provided. According to one embodiment of the present invention, a transistor with better electrical characteristics can be provided. According to one embodiment of the present invention, a semiconductor device or a memory device with low power consumption can be provided. According to one embodiment of the present invention, a memory device that operates at high speed can be provided. According to one embodiment of the present invention, a method for manufacturing any of the above transistor, semiconductor device, or memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are planar layouts each illustrating an example of a memory device.

FIG. 2A to FIG. 2C are planar layouts each illustrating an example of a memory device.

FIG. 3A1, FIG. 3B1, and FIG. 3C1 are plan views illustrating a processing method example. FIG. 3A2, FIG. 3B2, and FIG. 3C2 are cross-sectional views illustrating the processing method example. FIG. 4A1, FIG. 4B1, and FIG. 4C1 are plan views illustrating a processing method example. FIG. 4A2, FIG. 4B2, and FIG. 4C2 are cross-sectional views illustrating the processing method example. FIG. 5A to FIG. 5C are cross-sectional views illustrating a processing method example.

FIG. 6A to FIG. 6F are plan views illustrating a processing method example.

FIG. 7A is a plan view illustrating an example of a memory device. FIG. 7B and FIG. 7C are cross-sectional views illustrating an example of the memory device. FIG. 7D is a circuit diagram illustrating a structure example of the memory device.

FIG. 8A and FIG. 8B are plan views illustrating an example of a memory device.

FIG. 9A to FIG. 9D are cross-sectional views each illustrating an example of a memory device.

FIG. 10A to FIG. 10D are cross-sectional views each illustrating an example of a memory device.

FIG. 11A is a cross-sectional view illustrating an example of a memory device. FIG. 11B is a cross-sectional view illustrating an example of the memory device.

FIG. 12A to FIG. 12D are cross-sectional views each illustrating an example of a memory device.

FIG. 13A is a plan view illustrating an example of a memory device. FIG. 13B and FIG. 13C are cross-sectional views illustrating an example of the memory device.

FIG. 14A and FIG. 14B are cross-sectional views illustrating an example of a memory device.

FIG. 15A to FIG. 15D are cross-sectional views each illustrating an example of a memory device.

FIG. 16A and FIG. 16B are cross-sectional views illustrating an example of a memory device.

FIG. 17A is a plan view illustrating an example of a memory device. FIG. 17B and FIG. 17C are cross-sectional views illustrating an example of a memory device.

FIG. 18A is a plan view illustrating an example of a method for manufacturing a memory device.

FIG. 18B and FIG. 18C are cross-sectional views illustrating the example of a method for manufacturing a memory device.

FIG. 19A is a plan view illustrating an example of a method for manufacturing a memory device.

FIG. 19B and FIG. 19C are cross-sectional views illustrating the example of a method for manufacturing a memory device.

FIG. 20A is a plan view illustrating an example of a method for manufacturing a memory device.

FIG. 20B and FIG. 20C are cross-sectional views illustrating the example of a method for manufacturing a memory device.

FIG. 21A is a plan view illustrating an example of a method for manufacturing a memory device.

FIG. 21B and FIG. 21C are cross-sectional views illustrating the example of a method for manufacturing a memory device.

FIG. 22A is a plan view illustrating an example of a method for manufacturing a memory device.

FIG. 22B and FIG. 22C are cross-sectional views illustrating the example of a method for manufacturing a memory device.

FIG. 23A is a plan view illustrating an example of a method for manufacturing a memory device.

FIG. 23B and FIG. 23C are cross-sectional views illustrating the example of a method for manufacturing a memory device.

FIG. 24A is a plan view illustrating an example of a method for manufacturing a memory device.

FIG. 24B and FIG. 24C are cross-sectional views illustrating the example of a method for manufacturing a memory device.

FIG. 25A is a plan view illustrating an example of a method for manufacturing a memory device.

FIG. 25B and FIG. 25C are cross-sectional views illustrating the example of a method for manufacturing a memory device.

FIG. 26A is a plan view illustrating an example of a method for manufacturing a memory device.

FIG. 26B and FIG. 26C are cross-sectional views illustrating the example of a method for manufacturing a memory device.

FIG. 27A is a plan view illustrating an example of a method for manufacturing a memory device.

FIG. 27B and FIG. 27C are cross-sectional views illustrating the example of a method for manufacturing a memory device.

FIG. 28A is a plan view illustrating an example of a method for manufacturing a memory device.

FIG. 28B and FIG. 28C are cross-sectional views illustrating the example of a method for manufacturing a memory device.

FIG. 29A is a plan view illustrating of a memory device example. FIG. 29B is a cross-sectional view illustrating the memory device example.

FIG. 30A is a plan view illustrating a memory device example. FIG. 30B is a cross-sectional view illustrating the memory device example.

FIG. 31A is a plan view illustrating a memory device example. FIG. 31B is a cross-sectional view illustrating the memory device example.

FIG. 32 is a cross-sectional view illustrating an example of a memory device.

FIG. 33 is a block diagram illustrating an example of a memory device.

FIG. 34A and FIG. 34B are schematic diagrams illustrating an example of a memory device.

FIG. 35A to FIG. 35D are circuit diagrams illustrating an example of a memory device.

FIG. 36 is a circuit diagram illustrating an example of a memory device.

FIG. 37A and FIG. 37B are diagrams each illustrating an example of an electronic component.

FIG. 38A and FIG. 38B are diagrams each illustrating an example of an electronic device. FIG. 38C to FIG. 38E are diagrams illustrating an example of a large computer.

FIG. 39 is a diagram illustrating an example of space equipment.

FIG. 40 illustrates an example of a storage system applicable to a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings. For example, in the actual manufacturing process, a layer, a resist mask, or the like might be unintentionally reduced in size by treatment such as etching, which might not be reflected in the drawings for easy understanding.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the SCOPE OF CLAIMS.

A transistor is a kind of semiconductor elements and enables amplification of a current or a voltage, switching operation for controlling conduction or non-conduction, and the like. A transistor in this specification includes, in its category, an IGFET (Insulated Gate Field Effect Transistor) and a thin film transistor (TFT).

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases or the crystallinity decreases in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material that contains more oxygen than nitrogen in its composition. A nitride oxide refers to a material that contains more nitrogen than oxygen in its composition.

The contents of elements contained in films, such as hydrogen, oxygen, carbon, and nitrogen, can be analyzed using secondary ion mass spectrometry (SIMS) or X-ray photoelectron spectroscopy (XPS). Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, the expression “parallel” indicates a state where two straight lines are placed at an angle greater than or equal to −10° and less than or equal to 10°. Thus, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, “perpendicular” refers to a state where two straight lines are placed at an angle greater than or equal to 80° and less than or equal to 100°. Thus, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

In this specification and the like, the term “electrically connected” includes the case where components are connected to each other through an object having any electric action. There is no particular limitation on an “object having any electric function” as long as electric signals can be transmitted and received between components that are connected through the object. Examples of the “object having any electric function” include a switching element such as a transistor, a resistor, a coil, a capacitor, and other elements with any of a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vₜₕ, and the off state of a p-channel transistor means that V_{gs} is higher than Vₜₕ.

Note that in this specification and the like, a top surface shape of a component means the contour shape of the component in a plan view. A plan view means that the component is observed from a normal direction of a surface where the component is formed or from a normal direction of a surface of a support (e.g., a substrate) where the component is formed.

Note that in this specification and the like, the tapered shape refers to a shape such that at least part of a side surface of a component is inclined to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

### Embodiment 1

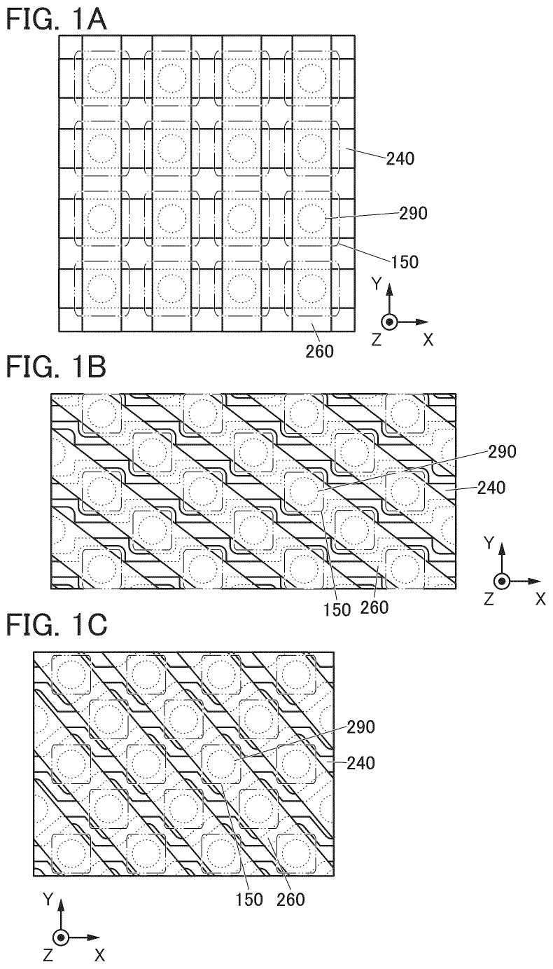

In this embodiment, a semiconductor device of one embodiment of the present invention and a manufacturing method thereof will be described with reference to FIG. 1 to FIG. 32. In this embodiment, a memory device will be mainly exemplified as a semiconductor device of one embodiment of the present invention. The memory device includes memory cells. The memory cell includes a transistor and a capacitor.

### Planar Layout of Memory Device

First, is shown a planar layout of the memory device of one embodiment of the present invention in FIG. 1A. Specifically, the planar layout of FIG. 1A shows a region including 4×4 memory cells 150. In addition, conductors 260 each functioning as a word line, conductors 240 each functioning as a bit line, and opening portions 290 are illustrated. Note that one memory cell 150 is provided in a region where one conductor 260, one conductor 240, and one opening portion 290 overlap with each other. In other words, the opening portion 290 is provided in a region of the conductor 240 where the conductor 240 and the conductor 260 intersect with each other.

FIG. 1A illustrates a structure in which the memory cells 150 are arranged in a matrix. Furthermore, the opening portions 290 are arranged in a matrix. Each conductor 260 is provided to extend in the Y direction (also referred to as a column direction), and each conductor 240 is provided to extend in the X direction (also referred to as a row direction). In other words, the conductor 260 and the conductor 240 are orthogonal to each other. In addition, the width of the conductor 260 in a direction (the X direction) perpendicular to the direction in which the conductor 260 extends is uniform, and the width of the conductor 240 in a direction (the Y direction) perpendicular to the direction in which the conductor 240 extends is uniform. Note that the present invention is not limited thereto.

FIG. 1B is another example of a planar layout of the memory device. In the planar layout of FIG. 1B, the conductors 260, the conductors 240, the memory cells 150, and the opening portions 290 are illustrated, as in FIG. 1A. The memory device illustrated in FIG. 1B is different from the memory device illustrated in FIG. 1A mainly in the arrangement of the memory cells 150, the arrangement of the opening portions 290, the shape of the conductors 240, and the direction in which the conductors 260 extend.

As illustrated in FIG. 1B, the memory cells 150 are arranged to shift by half a repeating unit of the memory cells 150 between the odd-numbered rows and the even-numbered rows. In addition, the memory cells 150 are arranged to shift by half the repeating unit between the odd-numbered columns and the even-numbered columns. Similarly, the opening portions 290 illustrated in FIG. 1B are arranged to shift by half a repeating unit of the opening portions 290 between the odd-numbered rows and the even-numbered rows. Moreover, the opening portions 290 are arranged to shift by half the repeating unit between the odd-numbered columns and the even-numbered columns.

In FIG. 1B, a memory cell adjacent to a first memory cell in the X direction is referred to as a second memory cell, and of memory cells adjacent to the first memory cell in the direction where the conductor 260 extends, a memory cell closer to the second memory cell is referred to as a third memory cell. In this configuration, it is preferable that the center of the third memory cell be positioned on a straight line parallel to the Y direction that passes through the middle of the first memory cell and the second memory cell. It can be said that the third memory cell is located in a position shifted in the X direction by half a repeating unit from each of the first memory cell and the second memory cell.

In FIG. 1B, the extending direction of the conductor 260 is inclined with respect to the Y direction. Meanwhile, the conductor 240 is provided to extend in the X direction. That is, the extending direction of the conductor 260 is not orthogonal to the extending direction of the conductor 240, in some cases, depending on the arrangement of the memory cells 150 (or the opening portions 290). In other words, the conductor 260 is not necessarily orthogonal to the conductor 240 and is located to intersect with the conductor 240.

As illustrated in FIG. 1B, the conductor 240 includes a first region and a second region. The first region is a region that includes the opening portion 290 and the vicinity thereof, and the width of the first region in the Y direction is a first width. In the plan view, the first region can be regarded as having a quadrangular shape with rounded corners. The second region is a region located between the adjacent opening portions 290 (also referred to as a region located between two adjacent first regions) in one conductor 240, and the width of the second region in the Y direction is referred to as a second width. In that case, the second width is preferably smaller than the first width. Such a configuration enables the physical distance between the conductors 240 to be reduced when the memory cells 150 (or the opening portions 290) are arranged to shift by half a repeating unit in every row and every column. Accordingly, miniaturization and high integration of the memory device can be achieved.

FIG. 1C is another example of a planar layout of the memory device. In the planar layout in FIG. 1C, the conductors 260, the conductors 240, the memory cells 150, and the opening portions 290 are illustrated, as in FIG. 1B. The memory device illustrated in FIG. 1C is different from the memory device illustrated in FIG. 1B mainly in the shape of the first region of the conductor 240.

The first region of the conductor 240 illustrated in FIG. 1B has a quadrangular shape with rounded corners in a plan view, and one side of the quadrangular shape is parallel to the X direction or the Y direction. Meanwhile, the first region of the conductor 240 illustrated in FIG. 1C has a quadrangular shape with rounded corners in a plan view, and the diagonal of the quadrangular shape is parallel to the X direction or the Y direction. Even such a configuration enables the physical distance between the conductors 240 to be reduced when the memory cells 150 (or the opening portions 290) are arranged to shift by half a repeating unit for every row and every column. Accordingly, miniaturization and high integration of the memory device can be achieved.

Although FIG. 1B and FIG. 1C each illustrate an example in which the first region of the conductor 240 has a quadrangular shape with rounded corners in the plan view, the present invention is not limited thereto.

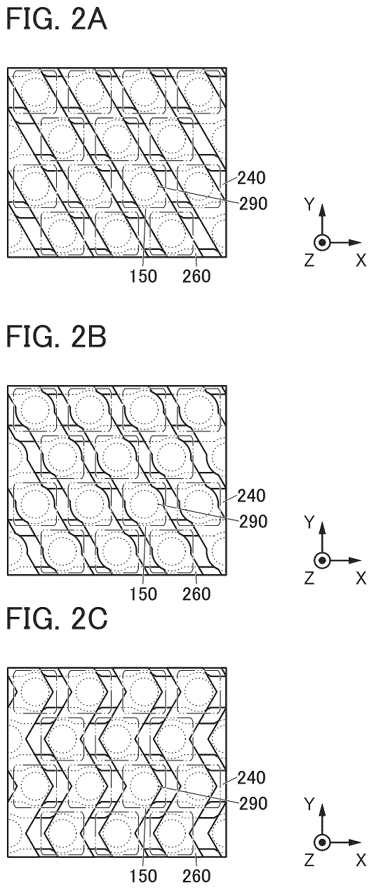

FIG. 2A is another example of a planar layout of the memory device. In the planar layout of FIG. 2A, the conductors 260, the conductors 240, the memory cells 150, and the opening portions 290 are illustrated, as in FIG. 1B. The memory device illustrated in FIG. 2A is different from the memory device illustrated in FIG. 1B or FIG. 1C mainly in the shape of the first region of the conductor 240.

The first region of the conductor 240 illustrated in FIG. 2A has a circular shape in a plan view. Even such a configuration enables the physical distance between the conductors 240 to be reduced when the memory cells 150 (or the opening portions 290) are arranged to shift by half a repeating unit for every row and every column. Accordingly, miniaturization and high integration of the memory device can be achieved.

Note that the first region of the conductor 240 in the plan view is not limited to the above-described shape. For example, the first region of the conductor 240 in the plan view may have an almost circular shape such as an elliptical shape, a polygonal shape such as a quadrangular shape, or a polygonal shape such as a quadrangular shape with rounded corners.

Although FIG. 2A illustrates the structure in which the width of the conductor 260 is uniform in the direction perpendicular to the direction where the conductor 260 extends, the present invention is not limited thereto.

FIG. 2B is another example of a planar layout of the memory device. In the planar layout of FIG. 2B, the conductors 260, the conductors 240, the memory cells 150, and the opening portions 290 are illustrated, as in FIG. 2A. The memory device illustrated in FIG. 2B is different from the memory device illustrated in FIG. 2A mainly in the shape of the conductor 260.

The conductor 260 illustrated in FIG. 2B includes a first region and a second region, like the conductor 240. The first region is a region that includes the opening portion 290 and the vicinity thereof, and has a circular shape in a plan view. The second region is a region located between the adjacent opening portions 290 (also referred to as a region located between two adjacent first regions) in one conductor 260. Note that the first region of the conductor 260 overlaps with the first region of the conductor 240. Such a configuration enables the physical distance between the conductors 260 to be reduced when the memory cells 150 (or the opening portions 290) are arranged to shift by half a repeating unit for every row and every column. Accordingly, miniaturization and high integration of the memory device can be achieved.

FIG. 2C is another example of a planar layout of the memory device. In the planar layout in FIG. 2C, the conductors 260, the conductors 240, the memory cells 150, and the opening portions 290 are illustrated, as in FIG. 2A. The memory device illustrated in FIG. 2C is different from the memory device illustrated in FIG. 2A mainly in the shape and the extending direction of the conductor 260.

The conductor 260 illustrated in FIG. 2C has a serpentine shape like a triangular wave in a plan view and is provided to extend in the Y direction. Such a configuration enables the physical distance between the conductors 260 to reduced when the memory cells 150 (or the opening portions 290) are arranged to shift by half a repeating unit for every row and every column. Accordingly, miniaturization and high integration of the memory device can be achieved. Note that the shape of the conductor 260 in the plan view is not limited to the above, and may have a meandering shape or the like.

With the above structure, one or both of the physical distance between the conductors 260 and the physical distance between the conductors 240 can be reduced, whereby the memory device can be miniaturized and highly integrated.

### Formation Method of Opening Portion

In order to arrange the memory cells 150 at higher density in the above-described memory device, the size of the opening portion 290 in a plan view needs to be extremely small. By contrast, there is a limitation on the resolution of a light-exposure apparatus used to form the opening portion 290.

In view of the above, in a method for manufacturing a semiconductor device of one embodiment of the present invention, a first resist mask is formed over a hard mask, and a first opening portion is formed in the first resist mask. Then, the first opening portion is reduced in size in a plan view. After the reduction in the size of the first opening portion (or while the size is being reduced), a second opening portion is provided in the hard mask. Subsequently, the first resist mask over the hard mask is removed, and a second resist mask is formed over the hard mask. After that, a third opening portion is formed in the second resist mask. Then, the third opening portion is reduced in size in the plan view. After the size of the third opening portion is reduced (while the size is being reduced), a fourth opening portion is provided in the hard mask. Note that in order to prevent the second opening portion and the fourth opening portion provided in the hard mask from overlapping with each other, the first opening portion provided in the first resist mask and the third opening portion provided in the second resist mask are located to be shifted from each other. The opening portion in the resist mask, which is formed with a light-exposure apparatus, is reduced in size in this manner, whereby the resist mask can be provided with a minute opening portion. In addition, a step of forming an opening portion in the hard mask is performed a plurality of times, with use of the resist mask provided with the minute opening portion, whereby an extremely minute opening portion that exceeds the resolution limit of the light-exposure apparatus can be formed.

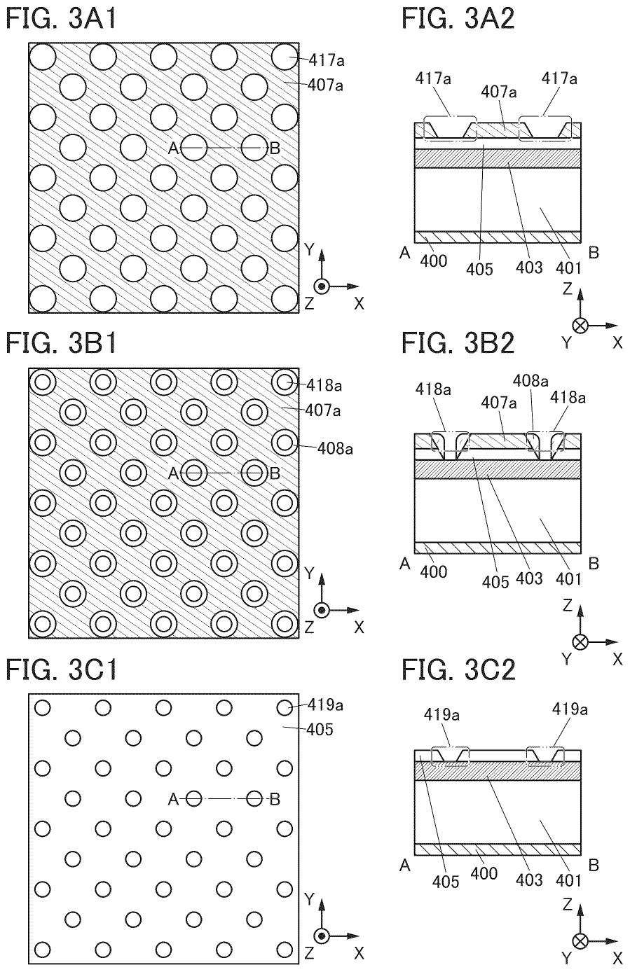

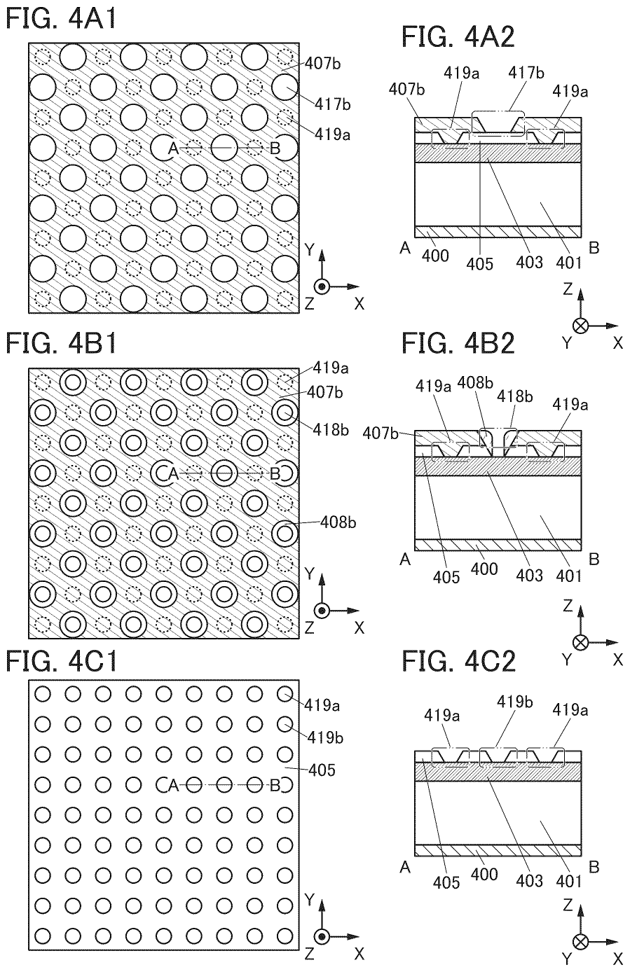

The method for manufacturing a semiconductor device of one embodiment of the present invention is described below with reference to FIG. 3 to FIG. 6.

First, an example in which the opening portion 290 in the planar layout illustrated in FIG. 1A is formed is described with reference to FIG. 3 to FIG. 5.

FIG. 3A1, FIG. 3B1, FIG. 3C1, FIG. 4A1, FIG. 4B1, and FIG. 4C1 are plan views of the semiconductor device. FIG. 3A2, FIG. 3B2, FIG. 3C2, FIG. 4A2, FIG. 4B2, and FIG. 4C2 are cross-sectional views taken along the dashed-dotted line A-B in FIG. 3A1, FIG. 3B1, FIG. 3C1, FIG. 4A1, FIG. 4B1, and FIG. 4C1, respectively. Note that for simplification of the drawings, some components are not illustrated in the plan views. FIG. 5A to FIG. 5C are cross-sectional views illustrating the steps subsequent to the step of FIG. 4C2.

In FIG. 3A2, a second layer 401 is provided over a first layer 400, a mask 403 is provided over the second layer 401, a mask 405 is provided over the mask 403, and a resist mask 407a is provided over the mask 405.

Here, the case where an opening portion reaching the first layer 400 is formed in the second layer 401 is described as an example. The first layer 400 and the second layer 401 may each have a single-layer structure or a stacked-layer structure. The first layer 400 and the second layer 401 can each include one or more of a conductor, a semiconductor, and an insulator.

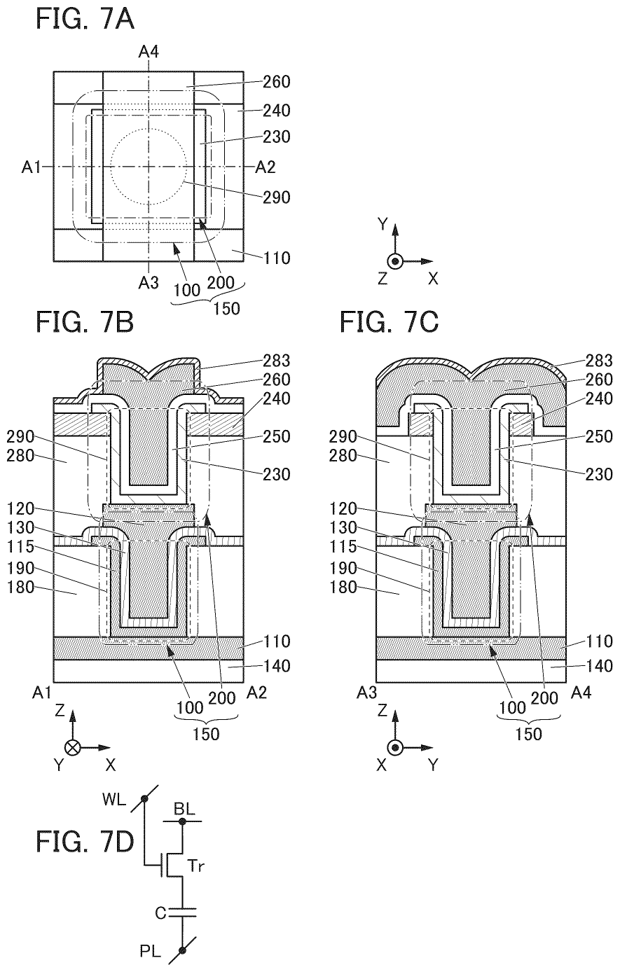

The method for manufacturing the semiconductor device of one embodiment of the present invention can be employed for manufacture of a transistor 200 illustrated in FIG. 7A to FIG. 7C described later, for example.

For example, the first layer 400 corresponds to a conductor 120, and the second layer 401 corresponds to a stacked-layer structure of an insulator 280 and the conductor 240. With use of the method for manufacturing a semiconductor device of one embodiment of the present invention, the extremely minute opening portion 290 can be formed in the insulator 280 and the conductor 240.

The method for manufacturing a semiconductor device of one embodiment of the present invention can be employed for manufacture of a capacitor 100 illustrated in FIG. 7A to FIG. 7C described later, for example.

For example, the first layer 400 corresponds to a conductor 110, and the second layer 401 corresponds to an insulator 180. With use of the method for manufacturing a semiconductor device of one embodiment of the present invention, an extremely minute opening portion 190 can be formed in the insulator 180.

As illustrated in FIG. 3A1 and FIG. 3A2, first, an opening portion 417a is formed in the resist mask 407a. The minimum size value of the opening portion 417a in the plan view depends on the resolution limit of the light-exposure apparatus.

For light used to expose the resist mask 407a, for example, an i-line (with a wavelength of 365 nm), a g-line (with a wavelength of 436 nm), an h-line (with a wavelength of 405 nm), or combined light of any of them can be used. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. EUV light, X-rays, or an electron beam is preferably used to enable extremely minute processing. Note that a photomask is not needed when light exposure is performed by scanning with a beam such as an electron beam.

Note that although the shape of the opening portion provided in each component is circular in the plan view, one embodiment of the present invention is not particularly limited thereto. For example, the opening portion in the plan view may have an almost circular shape such as an elliptical shape, a polygonal shape such as a quadrangular shape, or a polygonal shape such as a quadrangular shape with rounded corners.

Next, the opening portion 417a provided in the resist mask 407a is reduced in size. In FIG. 3B1 and FIG. 3B2, the downsized opening portion is denoted by an opening portion 418a. For example, when the shape of the opening portion 417a in the plan view is circular, the diameter of the opening portion 418a is smaller than the diameter of the opening portion 417a. For example, when the shape of the opening portion 417a in the plan view is quadrangular, the length of the diagonal line of the opening portion 418a is smaller than the length of the diagonal line of the opening portion 417a.

For example, the opening portion in the resist mask can be reduced in size by a chemical method. For example, by applying a shrink agent over the resist mask and performing predetermined treatment, the opening portion in the resist mask can be shrunk. For example, a material having a thermal shrinkage property may be applied and heat treatment may be performed, so that the opening portion in the resist mask is shrunk.

The reduction in the size of the opening portion in the resist mask 407a is preferably performed concurrently with etching of the mask 405.

For microfabrication, dry etching is preferably used for the etching of the mask 405. For example, when a reaction product 408a is attached to the side surface of the opening portion 417a with a dry etching apparatus, the opening portion 417a in the resist mask 407a is reduced to the opening portion 418a. Then, an opening portion 419a is formed in a position of the mask 405 overlapping with the opening portion 418a (FIG. 3C1 and FIG. 3C2). Specific examples of the reaction product 408a include a reaction product of a gas to be supplied and the resist mask 407a and a reaction product of the gas and the mask 405. After that, the resist mask 407a is removed.

An etching gas including a halogen can be used as an etching gas for dry etching treatment; specifically, an etching gas including one or more of fluorine, chlorine, and bromine can be used. As the etching gas, for example, a C₄F₆ gas, a C₅F₆ gas, a C₄F₈ gas, a CF₄ gas, a SF₆ gas, an NF₃ gas, a CHF₃ gas, a Cl₂ gas, a BCl₃ gas, a SiCl₄ gas, a CCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Next, as illustrated in FIG. 4A1 and FIG. 4A2, a resist mask 407b is formed over the mask 403 and the mask 405. An opening portion 417b is provided in the resist mask 407b. The minimum size value of the opening portion 417b in the plan view depends on the resolution limit of the light-exposure apparatus. The opening portion 417b is provided not to overlap with the opening portion 419a.

Next, the opening portion provided in the resist mask 407b is reduced in size. In FIG. 4B1 and FIG. 4B2, the downsized opening portion is denoted by an opening portion 418b. For example, when the shape of the opening portion 417b in the plan view is circular, the diameter of the opening portion 418b is smaller than the diameter of the opening portion 417b. For example, when the shape of the opening portion 417b in the plan view is a quadrangular shape, the length of the diagonal line of the opening portion 418b is smaller than the length of the diagonal line of the opening portion 417b.

It is preferable to concurrently perform the reduction in the size of the opening portion in the resist mask 407b and the etching of the mask 405. For example, when a reaction product 408b is attached to the side surface of the opening portion 417b due to a dry etching apparatus, the opening portion 417b in the resist mask 407b is reduced to the opening portion 418b. Then, an opening portion 419b is formed in a position of the mask 405 overlapping with the opening portion 418b is formed (FIG. 4C1 and FIG. 4C2). Specific examples of the reaction product 408b include a reaction product of a gas to be supplied and the resist mask 407b and a reaction product of the gas and the mask 405. After that, the resist mask 407b is removed.

The mask 405 is provided with the opening portion 419a and the opening portion 419b. Owing to the resolution issue of the light-exposure apparatus, it is difficult to form opening portions corresponding to the opening portion 419a and the opening portion 419b at a time in the resist mask. Meanwhile, as described above, with use of the method for manufacturing the semiconductor device of one embodiment of the present invention, an extremely minute opening portion can be formed in the mask 405.

Next, the mask 403 is processed to have an opening with use of the mask 405 as a hard mask (FIG. 5A). Then, an opening reaching the first layer 400 is formed in the second layer 401 using the mask 403 as a hard mask (FIG. 5B). At this time or after that, the mask 405 is removed. Furthermore, the mask 403 is removed. In the above manner, the second layer 401 having a minute opening portion can be formed over the first layer 400 (FIG. 5C).

For the mask 403, a material having high etching selectivity with respect to the mask 405 is preferably used. Furthermore, for the mask 403, a material having high etching selectivity with respect to at least the uppermost layer of the second layer 401 is preferably used. This can inhibit the etching of the mask 403 in the etching step of the mask 405 and the etching of the second layer 401 in the etching step of the mask 403.

For the mask 405, a material having low etching selectivity with respect to at least part of the second layer 401 is preferably used. For example, the mask 405 preferably contains the same material as at least part of the second layer 401. Accordingly, as illustrated in FIG. 5B, the mask 405 can be removed when the second layer 401 is processed to have an opening. Hence, the manufacturing process can be simplified.

Specifically, it is preferable that silicon oxide be used for the mask 405, silicon be used for the mask 403, and silicon oxide be used for at least part of the second layer 401. For example, the mask 403 using silicon can be removed with a chlorine-based gas. The removal of the mask 405 using silicon oxide and the processing of silicon oxide included in the second layer 401 can be performed with the fluorine-based gas at the same time.

In the method for manufacturing a semiconductor device of one embodiment of the present invention, an insulator, a semiconductor, or a conductor can be further formed over the second layer 401 illustrated in FIG. 5C.

For example, in the case where the transistor 200 illustrated in FIG. 7A to FIG. 7C described later is manufactured, an oxide semiconductor 230 is formed in contact with the side surface of the second layer 401 and the top surface of the first layer 400 in the opening portion of the second layer 401. The oxide semiconductor 230 is preferably formed by an ALD method, which enables deposition of a film with excellent coverage.

For example, in the case where the capacitor 100 illustrated in FIG. 7A to FIG. 7C described later is manufactured, a conductor 115 is formed to be in contact with the side surface of the second layer 401 and the top surface of the first layer 400 in the opening portion of the second layer 401. The conductor 115 is preferably formed by an ALD method, which enables deposition of a film with excellent coverage.

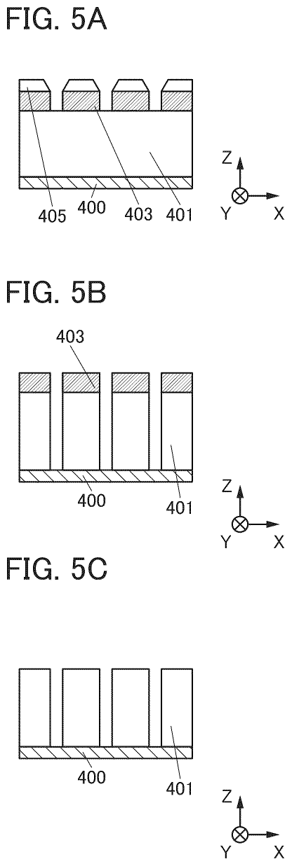

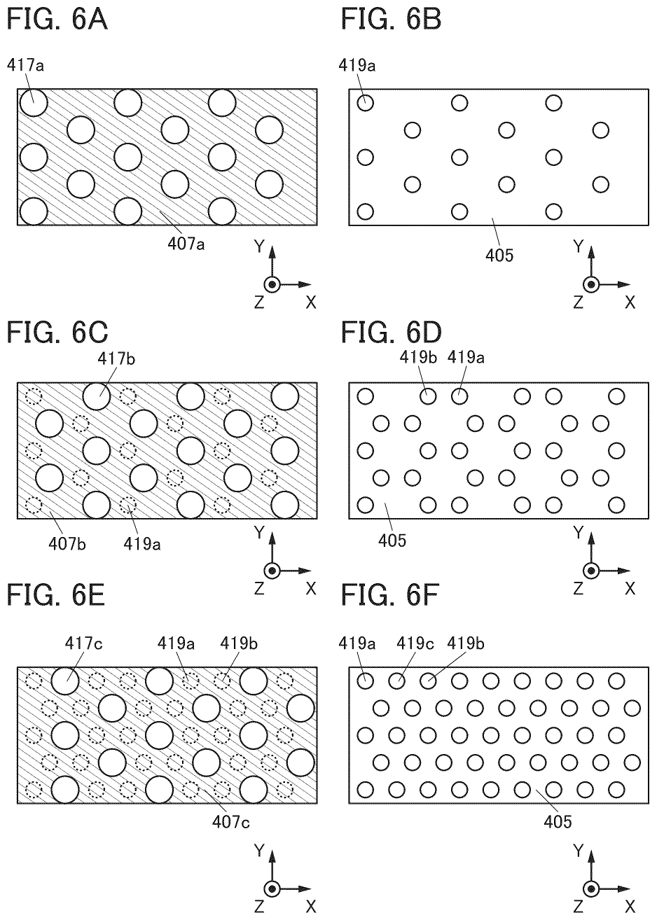

Next, the case where the opening portion 290 in the planar layout illustrated in FIG. 2A to FIG. 2C is formed will be described with reference to FIG. 6A to FIG. 6F.

FIG. 3 to FIG. 5 illustrate an example in which the resist mask is formed twice and the step of processing the mask 405 to have an opening is performed twice, i.e., an example in which the step of forming the opening portion 419a and the step of forming the opening portion 419b are included. The number of times of the step of processing the mask 405 to have an opening in the method for manufacturing the semiconductor device of one embodiment of the present invention is not limited to two, and may be three or more.

For example, in the planar layout illustrated in FIG. 2A to FIG. 2C, six memory cells 150 (or six opening portions 290) are adjacent to one memory cell 150 (or one opening portion 290) in the shortest distance. The case where the resist mask is formed three times and the step of processing the mask 405 to have an opening is performed three times is described as an example with FIG. 6A to FIG. 6F.

As illustrated in FIG. 6A, first, the opening portion 417a is formed in the resist mask 407a.

Next, the opening portion 417a provided in the resist mask 407a is reduced in size and the mask 405 is etched, so that the opening portion 419a is formed in the mask 405 (FIG. 6B). After that, the resist mask 407a is removed.

Next, as illustrated in FIG. 6C, the resist mask 407b is formed over the mask 405, and the opening portion 417b is provided in the resist mask 407b.

Next, the opening portion provided in the resist mask 407b is reduced in size and the mask 405 is etched, so that the opening portion 419b is formed in the mask 405 (FIG. 6D). After that, the resist mask 407b is removed.

Next, as illustrated in FIG. 6E, a resist mask 407c is formed over the mask 405, and an opening portion 417c is provided in the resist mask 407c.

Next, the opening portion provided in the resist mask 407c is reduced in size and the mask 405 is etched, so that an opening portion 419c is formed in the mask 405 (FIG. 6F). After that, the resist mask 407c is removed.

The mask 405 is provided with the opening portion 419a, the opening portion 419b, and the opening portion 419c. It is difficult to form the opening portions corresponding to the opening portion 419a to the opening portion 419c in the resist mask at a time. Meanwhile, as described above, with use of the method for manufacturing a semiconductor device of one embodiment of the present invention, an extremely minute opening portion can be formed in the mask 405.

The subsequent steps are as shown in FIG. 5A to FIG. 5C.

As described above, in the method for manufacturing a semiconductor device of one embodiment of the present invention, the size of the opening portion in the resist mask formed using the light-exposure apparatus is reduced, so that a minute opening portion can be formed in the resist mask. Then, the step of providing an opening portion in the hard mask is performed a plurality of times with use of a resist mask having the minute opening portion, whereby an extremely minute opening portion that exceeds the resolution limit of the light-exposure apparatus can be formed.

### Structure Example 1 of Memory Device

A structure of a memory device including a transistor and a capacitor is described with reference to FIG. 7. FIG. 7A to FIG. 7C are a plan view and cross-sectional views of the memory device including the transistor 200 and the capacitor 100. FIG. 7A is the plan view of the memory device. FIG. 7B and FIG. 7C are the cross-sectional views of the memory device. FIG. 7B is a cross-sectional view of a portion indicated by the dashed-dotted line A1-A2 in FIG. 7A. FIG. 7C is a cross-sectional view of a portion indicated by the dashed-dotted line A3-A4 in FIG. 7A. Note that for clarity of the drawing, some components are omitted in the top view of FIG. 7A.

The memory device illustrated in FIGS. 7A to 7C includes an insulator 140 over a substrate (not illustrated), the conductor 110 over the insulator 140, the memory cell 150 over the conductor 110, the insulator 180 over the conductor 110, the insulator 280, and an insulator 283 over the memory cell 150. The insulator 140, the insulator 180, the insulator 280, and the insulator 283 each function as an interlayer film. The conductor 110 functions as a wiring.

The memory cell 150 includes the capacitor 100 over the conductor 110 and the transistor 200 over the capacitor 100.

The capacitor 100 includes the conductor 115 over the conductor 110, an insulator 130 over the conductor 115, and the conductor 120 over the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 100 forms a MIM (Metal-Insulator-Metal) capacitor.

As illustrated in FIGS. 7B and 7C, the opening portion 190 reaching the conductor 110 provided in the insulator 180. At least part of the conductor 115 is placed in the opening portion 190. Note that the conductor 115 includes a region in contact with the top surface of the conductor 110 in the opening portion 190, a region in contact with the side surface of the insulator 180 in the opening portion 190, and a region in contact with at least part of the top surface of the insulator 180. The insulator 130 is placed so that at least part of the insulator 130 is positioned in the opening portion 190. The conductor 120 is provided so that at least part of the conductor 120 is positioned in the opening portion 190. Note that the conductor 120 is preferably provided to fill the opening portion 190 as illustrated in FIGS. 7B and 7C. Note that the films provided in the opening portion 190 are preferably formed by an ALD method. Thus, the coverage with the films can be improved. For example, the conductor 115, the insulator 130, and the conductor 120 are preferably formed by an ALD method.

The opening portion 190 is preferably formed by the above-described method for forming the opening portion. Thus, a minute opening portion can be formed.

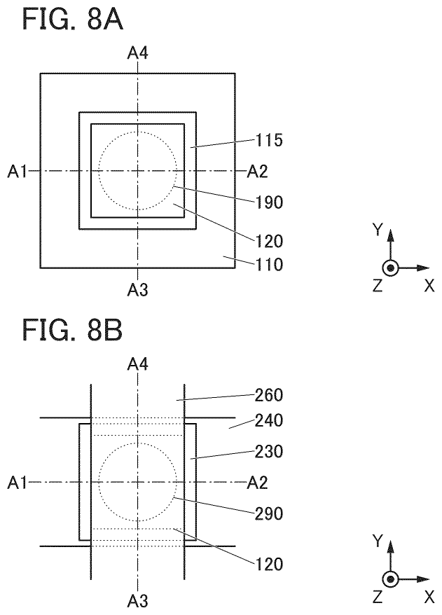

FIG. 8A is a plan view selectively illustrating the conductor 110, the conductor 115, the conductor 120, and the opening portion 190. Note that the opening portion 190 provided in the insulator 180 is indicated by dashed lines. As illustrated in FIG. 8A, the conductor 115 includes the opening portion 190 in a region overlapping with the conductor 110.

The capacitor 100 has a structure in which the upper electrode and the lower electrode face each other with the dielectric therebetween on a side surface as well as a bottom surface of the opening portion 190; thus, the capacitance per unit area can be increased. Thus, the deeper the opening portion 190 is, the larger the capacitance of the capacitor 100 can be. Increasing the capacitance per unit area of the capacitor 100 in this manner can stabilize the reading operation of the memory device. This also allows further miniaturization or high integration of the memory device.

Note that the sidewall of the opening portion 190 is preferably perpendicular to the top surface of the conductor 110. At this time, the opening portion 190 has a cylindrical shape. With such a structure, the memory device can be more miniaturized and highly integrated.

The conductor 115 and the insulator 130 are stacked along the sidewall of the opening portion 190 and the top surface of the conductor 110. The conductor 120 is provided over the insulator 130 to fill the opening portion 190. The capacitor 100 having such a structure may be referred to as a trench-type capacitor or a trench capacitor.

The insulator 280 is placed over the capacitor 100. That is, the insulator 280 is positioned over the conductor 115, the insulator 130, and the conductor 120. In other words, the conductor 120 is positioned under the insulator 280.

The transistor 200 includes the conductor 120, the conductor 240 over the insulator 280, the oxide semiconductor 230, an insulator 250 over the oxide semiconductor 230, and the conductor 260 over the insulator 250. Here, the oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode.

As illustrated in FIG. 7B and FIG. 7C, the opening portion 290 reaching the conductor 120 is formed in the insulator 280 and the conductor 240. At least part of the oxide semiconductor 230 is provided in the opening portion 290. The oxide semiconductor 230 includes a region in contact with the top surface of the conductor 120 in the opening portion 290, a region in contact with the side surface of the conductor 240 in the opening portion 290, and a region in contact with at least part of the top surface of the conductor 240 outside the opening portion 290. The insulator 250 is provided so that at least part of the insulator 250 is positioned in the opening portion 290. The conductor 260 is provided so that at least part of the conductor 260 is positioned in the opening portion 290. Note that the conductor 260 is preferably provided to fill the opening portion 290 as illustrated in FIG. 7B and FIG. 7C. Note that the films provided in the opening portion 290 are preferably formed by an ALD method. Thus, the coverage with the films can be improved. For example, the oxide semiconductor 230, the insulator 250, and the conductor 260 are each preferably formed by an ALD method.

The opening portion 290 is preferably formed by the above-described method for forming the opening portion. Thus, a minute opening portion can be formed.

FIG. 8B is a plan view selectively illustrating the conductor 120, the oxide semiconductor 230, the conductor 240, the conductor 260, and the opening portion 290. Note that the opening portion 290 provided in the insulator 280 is indicated by dashed lines. As illustrated in FIG. 8B, the conductor 240 includes the opening portion 290 in a region overlapping with the conductor 120. The conductor 240 is preferably not provided in the opening portion 290. That is, it is preferable that the conductor 240 not include a region in contact with the side surface of the insulator 280 on the opening portion 290 side.

The oxide semiconductor 230 includes a region in contact with the side surface of the conductor 240 in the opening portion 290 and a region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

As illustrated in FIG. 7A to FIG. 7C, the transistor 200 is provided to overlap with the capacitor 100. The opening portion 290 where part of the components of the transistor 200 is provided includes a region overlapping with the opening portion 190 where part of the components of the capacitor 100 is provided. In particular, since the conductor 120 has a function of one of the source electrode and the drain electrode of the transistor 200 and a function of the upper electrode of the capacitor 100, the transistor 200 and the capacitor 100 partly share the structure. With such a structure, the transistor 200 and the capacitor 100 can be provided without a great increase in the occupation area in the plan view. Thus, the area occupied by the memory cell 150 can be reduced, so that the memory cells 150 can be arranged densely and the memory capacity of the memory device can be increased. In other words, the memory device can be highly integrated.

FIG. 7D is a circuit diagram of the memory device described in this embodiment. As illustrated in FIG. 7D, the structure illustrated in FIG. 7A to FIG. 7C functions as a memory cell of the memory device. The memory cell includes a transistor Tr and a capacitor C. In this case, the transistor Tr and the capacitor C correspond to the transistor 200 and the capacitor 100, respectively.

One of a source and a drain of the transistor Tr is electrically connected to one of a pair of electrodes of the capacitor C. The other of the source and the drain of the transistor Tr is connected to a wiring BL. A gate of the transistor Tr is connected to a wiring WL. The other of the pair of electrodes of the capacitor C is connected to a wiring PL.

Here, the wiring BL corresponds to the conductor 240, the wiring WL corresponds to the conductor 260, and the wiring PL corresponds to the conductor 110. As illustrated in FIG. 7A to FIG. 7C, it is preferable that the conductor 260 be provided to extend in the Y direction and the conductor 240 be provided to extend in the X direction. In this structure, the wiring BL and the wiring WL are provided to intersect with each other. Although the wiring PL (the conductor 110) is provided in a plane shape in FIG. 7A, the present invention is not limited thereto. For example, the wiring PL may be provided parallel to the wiring WL (the conductor 260) or the wiring BL (the conductor 240).

The memory cell will be described in detail in a later embodiment.

### Capacitor 100

The capacitor 100 includes the conductor 115, the insulator 130, and the conductor 120. The conductor 110 is provided below the conductor 115. The conductor 115 includes a region in contact with the conductor 110.

The conductor 110 is provided over the insulator 140. The conductor 110 functions as the wiring PL and can be provided in a plane shape, for example. As the conductor 110, a single layer or stacked layers of any of conductors described in the section [Conductor] below can be used. For example, a conductive material with high conductivity such as tungsten can be used for the conductor 110. With use of a conductive material with high conductivity, the conductivity of the conductor 110 can be improved and the wiring PL can function sufficiently.

A single layer or stacked layers of a conductive material that is less likely to be oxidized, a conductive material having a function of inhibiting diffusion of oxygen, or the like is preferably used for the conductor 115. For example, titanium nitride, indium tin oxide to which silicon is added, or the like may be used. A structure where titanium nitride is stacked over tungsten may be used, for example. Alternatively, a structure where tungsten is stacked over first titanium nitride and second titanium nitride is stacked over the tungsten may be used, for example. With such a structure, when an oxide insulator is used for the insulator 130, the conductor 110 can be inhibited from being oxidized by the insulator 130. In the case of using an oxide insulator for the insulator 180, the oxidation of the conductor 110 due to the insulator 180 can be inhibited.

The insulator 130 is provided over the conductor 115. The insulator 130 is provided to be in contact with the top and side surfaces of the conductor 115. That is, the insulator 130 preferably covers the side end portion of the conductor 110. This can prevent a short circuit between the conductor 115 and the conductor 120.

Alternatively, the side end portion of the insulator 130 and the side end portion of the conductor 115 may be aligned with each other. This structure enables the insulator 130 and the conductor 115 to be formed using the same mask, so that the manufacturing process of the memory device can be simplified.

For the insulator 130, any of materials with high dielectric constants, that is, high-k materials, described in the section [Insulator] below may be used. Using such a high-k material for the insulator 130 allows the insulator 130 to be thick enough to inhibit a leakage current and the capacitor 100 to have a sufficiently high capacitance.

It is preferable for the insulator 130 to use stacked insulators formed of high-k materials, and it is preferable to use a stacked-layer structure of a high dielectric constant (high-k) material and a material having higher dielectric strength than the high dielectric constant (high-k) material. As the insulator 130, an insulating film in which zirconium oxide, aluminum oxide, and zirconium oxide are stacked in this order can be used, for example. Alternatively for example, an insulating film in which zirconium oxide, aluminum oxide, zirconium oxide, and aluminum oxide are stacked in this order can be used. Alternatively for example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 100.

Alternatively, a material having ferroelectricity may be used for the insulator 130. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though not containing the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a k-alumina-type structure, and the like.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the deposition conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can show ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. When a ferroelectric layer that can be thin is used, the capacitor 100 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. A device including such a ferroelectric layer, metal oxide film, or metal nitride film is sometimes referred to as a ferroelectric device in this specification and the like.

A metal oxide containing one or both of hafnium and zirconium is preferable because the metal oxide can show ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even with an area less than or equal to 10000 nm² or less than or equal to 1000 nm², a ferroelectric layer has ferroelectricity in some cases. With a small-area ferroelectric layer, the area occupied by the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable that the insulator 130 include a crystal having an orthorhombic crystal structure to exhibit ferroelectricity. Note that a crystal included in the insulator 130 may have one or more selected from cubic, tetragonal, orthorhombic, monoclinic, and hexagonal crystal structures. Alternatively, the insulator 130 may have an amorphous structure. In that case, the insulator 130 may have a composite structure including an amorphous structure and a crystal structure.

The conductor 120 is provided in contact with part of the top surface of the insulator 130. The side end portion of the conductor 120 is preferably positioned inside the side end portion of the conductor 115 in both the X direction and the Y direction, as shown in FIG. 8A. Note that in the structure where the insulator 130 covers the side end portion of the conductor 115, the side end portion of the conductor 120 may be positioned outside the side end portion of the conductor 115.

As the conductor 120, a single layer or stacked layers of any of the conductors described in the section [Conductor] below can be used. In addition, a conductive material that is less likely to be oxidized, a conductive material having a function of inhibiting diffusion of oxygen, or the like is preferably used for the conductor 120. For example, titanium nitride, tantalum nitride, or the like can be used. For example, a structure where tantalum nitride is stacked over titanium nitride may be used. In that case, titanium nitride is in contact with the insulator 130 and tantalum nitride is in contact with the oxide semiconductor 230. Such a structure enables the excessive oxidation of the conductor 120 due to the oxide semiconductor 230 to be inhibited. In the case of using an oxide insulator for the insulator 130, the excessive oxidation of the conductor 120 due to the insulator 130 can be inhibited. Alternatively, a structure where tungsten is stacked over titanium nitride may be used for the conductor 120, for example.

The conductor 120 includes a region in contact with the oxide semiconductor 230 and thus is preferably formed using a conductive material containing oxygen described in the section [Conductor] below. When a conductive material containing oxygen is used for the conductor 120, the conductor 120 can maintain its conductivity even when absorbing oxygen. In addition, also in the case of using an insulator containing zirconium oxide as the insulator 130, the conductor 120 can maintain its conductivity, which is preferable. As the conductor 120, a single layer or stacked layers of indium tin oxide (also referred to as ITO), indium tin oxide to which silicon is added (also referred to as ITSO), indium zinc oxide (IZO (registered trademark)), or the like can be used, for example.

The insulator 180, which functions as an interlayer film, preferably has a low dielectric constant. When a material with a low dielectric constant is used for an interlayer film, parasitic capacitance generated between wirings can be reduced. As the insulator 180, a single layer or stacked layers of any of the insulators including a material with a low dielectric constant described in the section [Insulator] below can be used. In particular, silicon oxide and silicon oxynitride are preferable because they are thermally stable. In this case, the insulator 180b contains at least silicon and oxygen.

Although FIG. 7B and FIG. 7C show that the insulator 180 has the single-layer structure, the present invention is not limited thereto. The insulator 180 may have a stacked-layer structure.

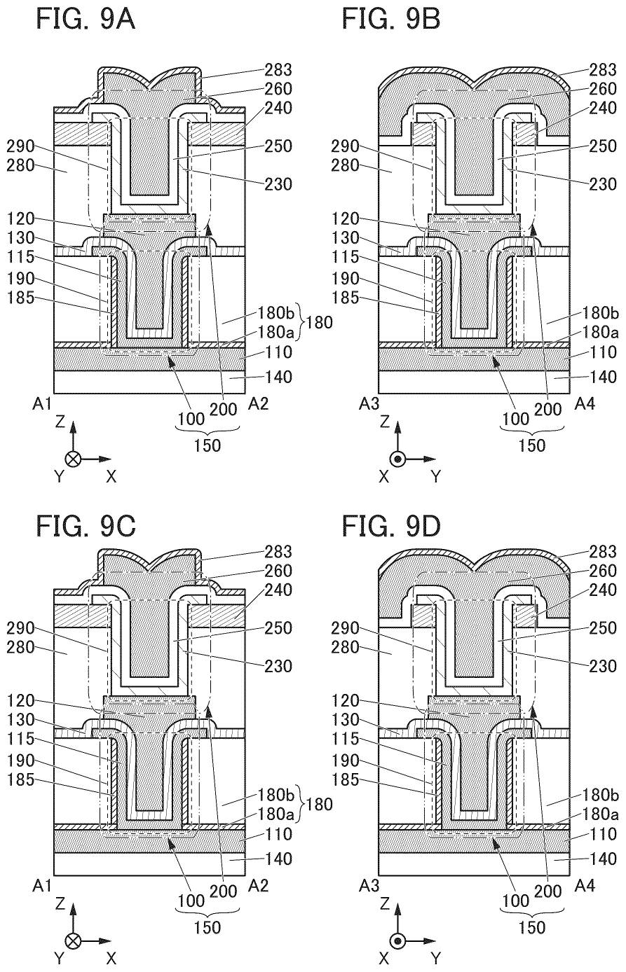

For example, as illustrated in FIG. 9A and FIG. 9B, the insulator 180 may have a stacked-layer structure of an insulator 180a and an insulator 180b over the insulator 180a.

The insulator 180b is preferably formed using an insulating material that can be used for the insulator 180.

For the insulator 180a, any of the insulators having a barrier property against oxygen described in the section [Insulator] below is preferably used. The conductor 110 is oxidized by oxygen contained in the insulator 180b and has high resistance in some cases. Providing the insulator 180a between the insulator 180b and the conductor 110 can inhibit the conductor 110 from being oxidized and having high resistance.

Entry of impurities such as hydrogen into the insulator 130 may cause an increase of the amount of the leakage current generated between the upper electrode and the lower electrode. In the case where a material that can have ferroelectricity is used for the insulator 130, entry of impurities such as hydrogen into the material that can have ferroelectricity might reduce the crystallinity of the material that can have ferroelectricity. Thus, impurities such as hydrogen are preferably inhibited from entering the insulator 130.

For the insulator 180a, any of the insulators having a barrier property against hydrogen described in the section [Insulator] below is preferably used. Thus, diffusion of hydrogen into the insulator 130 through the insulator 180b and the conductor 115 can be inhibited. Silicon nitride and silicon nitride oxide can be suitably used for the insulator 180a because the silicon nitride and the silicon nitride oxide release fewer impurities (e.g., water and hydrogen) and are less likely to transmit oxygen and hydrogen. In this case, the insulator 180a contains at least silicon and nitrogen.

For the insulator 180a, any of the insulators having a function of capturing or fixing hydrogen described in the section [Insulator] below is preferably used. With this structure, hydrogen in the insulator 130 can be captured or fixed, whereby the hydrogen concentration in the insulator 130 can be reduced. For the insulator 180a, magnesium oxide, aluminum oxide, hafnium oxide, or the like can be used. Alternatively, for example, a stacked-layer film of aluminum oxide and silicon nitride over the aluminum oxide may be used as the insulator 180a.

Although FIG. 9A and FIG. 9B illustrate the structure in which the insulator 180 has a stacked-layer structure of two layers, one embodiment of the present invention is not limited thereto. The insulator 180 may have a stacked structure of three or more layers.

For example, in the case where the insulator 180 has a three-layer stacked structure, in addition to the insulator 180a and the insulator 180b, an insulator is preferably provided between the insulator 180b and each of the conductor 115 and the insulator 130. As the insulator, an insulator that is applicable to the insulator 180a can be used. This can inhibit diffusion of hydrogen into the insulator 130 through the insulator 180b.

Alternatively, an insulator 185 is preferably provided between the conductor 115 and the insulator 180 as illustrated in FIG. 9A and FIG. 9B. The insulator 185 is preferably provided in contact with the side surface of the insulator 180 in the opening portion 190. That is, the insulator 185 is preferably provided between the conductor 115 and the side surface of the insulator 180 in the opening portion 190. Since the insulator 185 is provided along the opening portion 190, the insulator 185 is preferably formed by an ALD method.

For the insulator 185, any of the insulators having a barrier property against hydrogen described in the section [Insulator] below is preferably used. This can inhibit diffusion of hydrogen into the insulator 130 from the outside of the capacitor 100 through the insulator 180. For example, silicon nitride or silicon nitride oxide can be used as the insulator 185. In this case, the insulator 185 contains at least silicon and nitrogen.

For the insulator 185, any of the insulators having a function of capturing or fixing hydrogen described in the section [Insulator] below is preferably used. With this structure, hydrogen in the insulator 130 can be captured or fixed, whereby the hydrogen concentration in the insulator 130 can be reduced. For the insulator 185, magnesium oxide, aluminum oxide, hafnium oxide, or the like can be used. Alternatively, for example, a stacked-layer film of aluminum oxide and silicon nitride over the aluminum oxide may be used as the insulator 185.

Although the insulator 185 is provided in contact with the side surface of the insulator 180a in the opening portion 190 and the side surface of the insulator 180b in the opening portion 190 in FIG. 9A and FIG. 9B, the present invention is not limited thereto. For example, as illustrated in FIG. 9C and FIG. 9D, the insulator 185 may be provided in contact with part of the top surface of the insulator 180a and the side surface of the insulator 180b in the opening portion 190.

Although the conductor 120 is positioned on the inner side of the conductor 115 with the insulator 130 therebetween in FIG. 7B and FIG. 7C, the present invention is not limited thereto. For example, the conductor 120 may be positioned outside the conductor 115 with the insulator 130 therebetween.

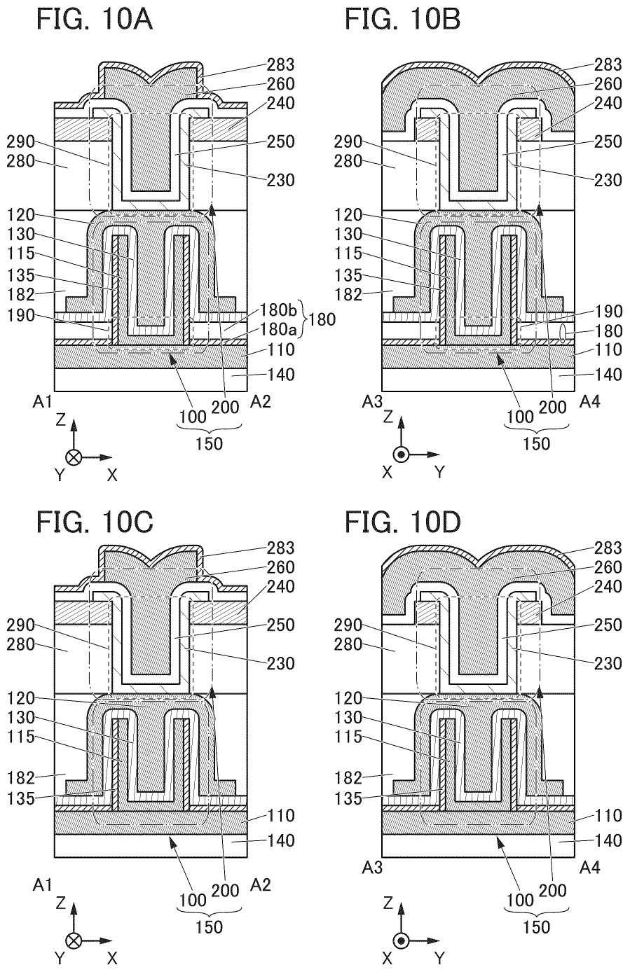

For example, as illustrated in FIG. 10A and FIG. 10B, the insulator 130 includes a region positioned on the outer side surface side of the conductor 115, in addition to a region in contact with the inner side of the depression defined by the conductor 115 and a region in contact with the top surface of the conductor 115.

The conductor 120 is provided to fill the depressed portion defined by the conductor 115 with the insulator 130 therebetween. Furthermore, the conductor 120 includes a region facing the part of the outer side surface of the conductor 115 with the insulator 130 therebetween.

With the above structure, the capacitance per unit area can be further increased.

Note that as illustrated in FIG. 10A and FIG. 10B, an insulator 135 may be provided between the outer side surface of the conductor 115 and each of the insulator 130 and the insulator 180.

An insulator 182 may be provided over the conductor 120 and the insulator 130. The insulator 182 is preferably subjected to planarization treatment so that the top surface of the conductor 120 is exposed. The planarization treatment for the insulator 182 allows the transistor 200 to be suitably formed over the capacitor 100.

The insulator 182, which functions as an interlayer film, preferably has a low dielectric constant. When a material with a low dielectric constant is used for an interlayer film, parasitic capacitance generated between wirings can be reduced. As the insulator 182, an insulator applicable to the insulator 180 can be used.

Note that the conductor 120 is provided on the inner side and the outer side of the conductor 115 as illustrated in FIG. 10A and FIG. 10B, and accordingly sufficient capacitance can be ensured for the memory cell, in which case a structure without the insulator 180 may be employed.

The memory device illustrated in FIG. 10C and FIG. 10D is different from the memory device illustrated in FIG. 10A and FIG. 10B in not including the insulator 180. Without the insulator 180, the manufacturing process of the memory device can be simplified.

### Transistor 200

As illustrated in FIG. 7A to FIG. 7C, the transistor 200 can have a structure including the conductor 120; the conductor 240 over the insulator 280; the oxide semiconductor 230 provided in contact with the top surface of the conductor 120, which is exposed in the opening portion 290, the side surface of the insulator 280 in the opening portion 290, the side surface of the conductor 240 in the opening portion 290, and at least part of the top surface of the conductor 240; the insulator 250 provided in contact with the top surface of the oxide semiconductor 230; and the conductor 260 provided in contact with the top surface of the insulator 250.

At least some of the components in the transistor 200 are placed in the opening portion 290. Here, the bottom portion of the opening portion 290 is the top surface of the conductor 120, and the sidewall of the opening portion 290 is the side surface of the insulator 280 and the side surface of the conductor 240.

Note that the sidewall of the opening portion 290 is preferably perpendicular to the top surface of the conductor 110. At this time, the opening portion 290 has a cylindrical shape. With the structure, the memory device can be more miniaturized and highly integrated.

Although this embodiment describes the example where the opening portion 290 has a circular shape in the plan view, the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 is calculated as appropriate in accordance with the shape of the uppermost portion of the opening portion 290. For example, in the case where the opening portion 290 is square in the plan view, the maximum width of the opening portion 290 may be the length of a diagonal line of the uppermost portion of the opening portion 290.

Portions of the oxide semiconductor 230, the insulator 250, and the conductor 260 that are placed in the opening portion 290 reflect the shape of the opening portion 290. Therefore, the oxide semiconductor 230 is provided so as to cover the bottom portion and the sidewall of the opening portion 290, the insulator 250 is provided to cover the oxide semiconductor 230, and the conductor 260 is provided so as to be embedded in a depressed portion reflecting the shape of the opening portion 290, of the insulator 250.

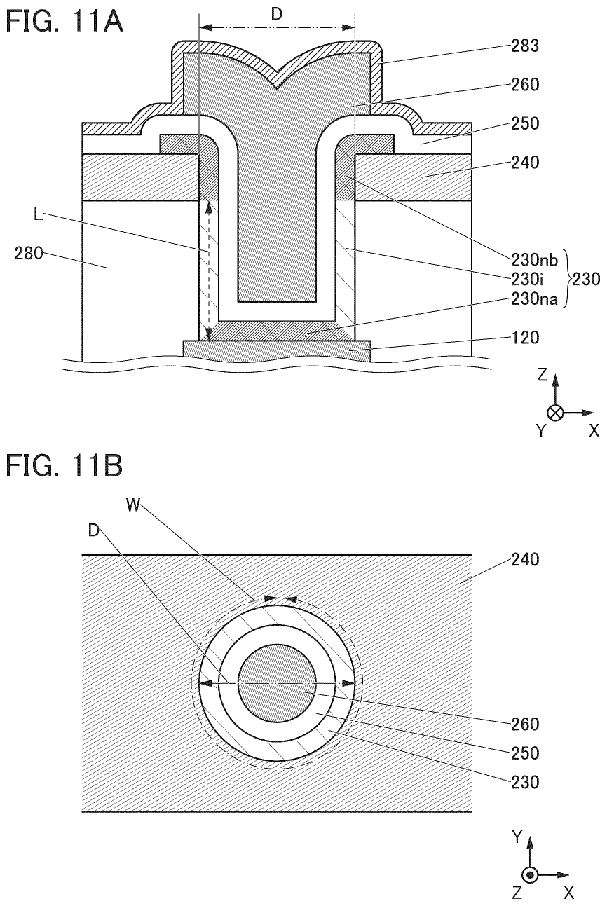

FIG. 11A is an enlarged view of the oxide semiconductor 230 and its vicinity in FIG. 7B. FIG. 11B is a cross-sectional view taken along the X-Y plane including the conductor 240.

As illustrated in FIG. 11A, the oxide semiconductor 230 includes a region 230i, and a region 230na and a region 230nb provided such that the region 230i is sandwiched therebetween.

The region 230na is a region in contact with the conductor 120 in the oxide semiconductor 230. At least part of the region 230na functions as one of the source region and the drain region of the transistor 200. The region 230nb is a region in contact with the conductor 240 in the oxide semiconductor 230. At least part of the region 230nb functions as the other of the source region and the drain region of the transistor 200. As illustrated in FIG. 11B, the conductor 240 is in contact with all the outer circumference of the oxide semiconductor 230. Thus, the other of the source region and the drain region of the transistor 200 can be formed along all the outer circumference of the oxide semiconductor 230 in a region formed in the same layer as the conductor 240.

The region 230i is a region between the region 230na and the region 230nb in the oxide semiconductor 230. At least part of the region 230i functions as a channel formation region of the transistor 200. That is, the channel formation region of the transistor 200 is positioned in a region of the oxide semiconductor 230 between the conductor 120 and the conductor 240. It can be said that the channel formation region of the transistor 200 is positioned in a region in contact with the insulator 280 or a region in the vicinity thereof in the oxide semiconductor 230.

The channel length of the transistor 200 is a distance between the source region and the drain region. In other words, the channel length of the transistor 200 is determined by the thickness of the insulator 280 over the conductor 120. In FIG. 11A, a channel length L of the transistor 200 is indicated by a dashed double-headed arrow. In the cross-sectional view, the channel length L is a distance between an end portion of a region where the oxide semiconductor 230 is in contact with the conductor 120 and an end portion of a region where the oxide semiconductor 230 is in contact with the conductor 240. That is, the channel length L corresponds to the length of the side surface of the insulator 280 on the opening portion 290 side in the cross-sectional view.

In a planar transistor, the channel length is determined by the light exposure limit of photolithography. Meanwhile, in the present invention, the channel length can be determined by the thickness of the insulator 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200 can have higher on-state current and improved frequency characteristics. Accordingly, the read speed and the write speed of the memory cell 150 can be increased, whereby a memory device with a high operation speed can be provided.

In addition, as described above, the channel formation region, the source region, and the drain region can be formed in the opening portion 290. Thus, the area occupied by the transistor 200 can be reduced as compared with a conventional transistor in which the channel formation region, the source region, and the drain region are provided separately on the X-Y plane. This allows high integration of the memory device; therefore, the memory capacity per unit area can be increased.

Furthermore, in the X-Y plane including the channel formation region of the oxide semiconductor 230, as illustrated in FIG. 11B, the oxide semiconductor 230, the insulator 250, and the conductor 260 are provided concentrically. Therefore, a side surface of the conductor 260 provided at the center faces a side surface of the oxide semiconductor 230 with the insulator 250 therebetween. That is, in the plan view, all the circumference of the oxide semiconductor 230 serves as the channel formation region. In this case, for example, the channel width of the transistor 200 is determined by the length of the outer circumference of the oxide semiconductor 230. In other words, the channel width of the transistor 200 is determined by the maximum width of the opening portion 290 (the maximum diameter in the case where the opening portion 290 is circular in the plan view). In FIG. 11A and FIG. 11B, a maximum width D of the opening portion 290 is indicated by a dashed double-dotted double-headed arrow. In FIG. 11B, a channel width W of the transistor 200 is indicated by a dashed-dotted double-headed arrow. By increasing the maximum width D of the opening portion 290, the channel width per unit area can be increased and the on-state current can be increased.

The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be “Dx”. When the above-described method for forming the opening portion of one embodiment of the present invention is employed, the maximum width D of the opening portion 290 can be easily reduced.

In the memory device of one embodiment of the present invention, the channel length L of the transistor 200 is preferably shorter than at least the channel width W of the transistor 200. In one embodiment of the present invention, the channel length L of the transistor 200 is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be circular in the plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

In the transistor including an oxide semiconductor in the semiconductor layer, it is preferable that the channel formation region contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

In the transistor including an oxide semiconductor in the semiconductor layer, the source region and the drain region of the transistor include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor is an n-type region that has a higher carrier concentration and a lower resistance than the channel formation region.

Although the opening portion 290 is provided so that the side surface of the opening portion 290 is substantially perpendicular to the top surface of the conductor 110 in FIG. 7B and FIG. 7C, the present invention is not limited thereto. The sidewall of the opening portion 290 may have a tapered shape, for example.

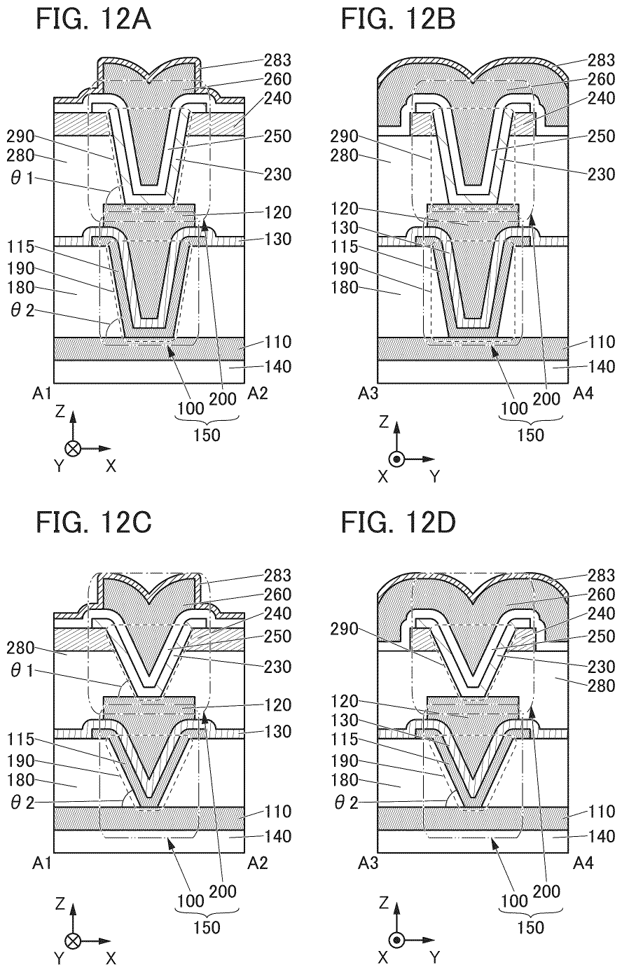

The memory device illustrated in FIG. 12A and FIG. 12B has a structure where the sidewall of the opening portion 290 has a tapered shape. Note that FIG. 7A can be referred to for the plan view of the memory device illustrated in FIG. 12A and FIG. 12B.

When the sidewall of the opening portion 290 has a tapered shape, the coverage with the oxide semiconductor 230, the insulator 250, and the like can be improved, so that defects such as voids can be reduced. For example, the angle (angle θ1 illustrated in FIG. 12A) formed between the side surface of the insulator 280 in the opening portion 290 and the top surface of the conductor 110 is preferably greater than or equal to 45° and less than 90°. Alternatively, the angle is preferably greater than or equal to 45° and less than or equal to 75°. Alternatively, the angle is preferably greater than or equal to 45° and less than or equal to 65°.

The opening portion 290 illustrated in FIG. 12A and FIG. 12B has a conical trapezoidal shape. In this structure, the opening portion 290 in the plan view is circular and the opening portion 290 in the cross-sectional view is rectangular. The area of the upper base surface of the conical trapezoidal shape (e.g., the opening portion provided in the conductor 240) is smaller than the area of the lower base surface of the conical trapezoidal shape (the top surface of the conductor 120 exposed in the opening portion 290). In this case, the maximum diameter of the opening portion 290 is preferably calculated on the basis of the upper base surface having a conical trapezoidal shape.

In the case where the sidewall of the opening portion 290 has a tapered shape, the channel length can be set by the thickness of the insulator 280 and the angle 01 formed between the top surface of the conductor 110 and the side surface of the insulator 280 in the opening portion 290. The length of the outer circumference of the oxide semiconductor 230 is determined, for example, on the basis of a region facing the conductor 240 or a position of half the thickness of the insulator 280. Note that the length of the circumference of the opening portion 290 at an arbitrary position may be regarded as the channel width of the transistor 200 as necessary. For example, the length of the circumference at the lowest portion of the opening portion 290 may be regarded as the channel width, or the length of the circumference at the uppermost portion of the opening portion 290 may be regarded as the channel width.

Although the structure in FIG. 12A and FIG. 12B shows a feature that the side surface of the conductor 240 in the opening portion 290 is aligned with the side surface of the insulator 280 in the opening portion 290, the present invention is not limited thereto. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. For example, the angle formed between the side surface of the conductor 240 in the opening portion 290 and the top surface of the conductor 110 is preferably smaller than the angle θ1. With such a structure, the coverage of the side surface of the conductor 240 with the oxide semiconductor 230 in the opening portion 290 is improved, so that defects such as voids can be reduced.

As illustrated in FIG. 12A and FIG. 12B, the bottom portion of the conductor 260 positioned in the opening portion 290 includes a flat region. Note that the bottom portion of the conductor 260 positioned in the opening portion 290 does not include a flat region in some cases depending on the maximum width of the opening portion 290 (the maximum diameter in the case where the opening portion 290 is circular in the plan view), the thickness of the insulator 280 (corresponding to the depth of the opening portion 290), the thickness of the oxide semiconductor 230, the thickness of the insulator 250, and the like. For example, as illustrated in FIG. 12C and FIG. 12D, the bottom portion of the conductor 260 positioned in the opening portion 290 sometimes has a needle-like shape. Note that FIG. 7A can be referred to for the plan view of the memory device illustrated in FIG. 12C and FIG. 12D.

Here, a needle-like shape refers to a shape that becomes thinner as it is closer to a tip (closer to the bottom portion of the conductor 260 positioned in the opening portion 290). Note that the needle-like tip may have an acute angle or a curved downward-convex shape. Note that a needle-like shape whose tip has an acute angle may be referred to as a V shape.

A region of the conductor 260 positioned in the opening portion 290 that faces the oxide semiconductor 230 with the insulator 250 therebetween functions as a gate electrode. Thus, the conductor 260 that fills the opening portion 290 and has a needle-like shape at the bottom portion may be referred to as a needle-like gate. Even when the bottom portion of the conductor 260 has a shape with a flat region as illustrated in FIG. 12A and FIG. 12B, such a shape can be referred to as a needle-like gate in some cases.

Although the opening portion 190 is provided so that the sidewall of the opening portion 190 is perpendicular to the top surface of the conductor 110 in FIG. 7B and FIG. 7C, the present invention is not limited thereto. For example, as in the opening portion 290, the sidewall of the opening portion 190 may have a tapered shape or an inverse tapered shape.

When the sidewall of the opening portion 190 has a tapered shape, the coverage with the conductor 115, the insulator 130, and the like can be improved, so that defects such as voids can be reduced. For example, the angle (angle θ2 illustrated in FIG. 12A) formed between the side surface of the insulator 180 in the opening portion 190 and the top surface of the conductor 110 is preferably greater than or equal to 45° and less than 90°. Alternatively, the angle is preferably greater than or equal to 45° and less than or equal to 75°. Alternatively, the angle is preferably greater than or equal to 45° and less than or equal to 65°.

As illustrated in FIG. 12A and FIG. 12B, the bottom portion of the conductor 120 positioned in the opening portion 190 includes a flat region. Note that the bottom portion of the conductor 120 positioned in the opening portion 190 does not include a flat region in some cases depending on the maximum width of the opening portion 190 (the maximum diameter in the case where the opening portion 190 is circular in the plan view), the thickness of the insulator 180 (corresponding to the depth of the opening portion 190), the thickness of the conductor 115, the thickness of the insulator 130, and the like. For example, as illustrated in FIG. 12C and FIG. 12D, the bottom portion of the conductor 120 positioned in the opening portion 190 sometimes has a needle-like shape. Note that FIG. 7A can be referred to for the plan view of the memory device illustrated in FIG. 12C and FIG. 12D.

In the case where the insulator 180 and the insulator 280 are formed using the same material, the angle θ1 and the angle θ2 are equal to or substantially equal to each other. Note that the angle θ1 and the angle θ2 may be different from each other depending on materials used for the insulator 180 and the insulator 280, methods for forming the opening portion 190 and the opening portion 290, or the like. For example, the angle θ1 may be larger than or smaller than the angle θ2. Alternatively, one of the angle θ1 and the angle θ2 may be 90° or a value in the neighborhood thereof.

Alternatively, the sidewall of the opening portion 290 may have an inverse tapered shape, for example.

Here, the inverse tapered shape refers to a shape in which a side portion or an upper portion extends beyond a bottom portion in the direction parallel to a substrate. At this time, the opening portion 290 has a conical trapezoidal shape. In this case, the opening portion 290 is circular in the plan view and the opening portion 290 is trapezoid in the cross-sectional view. The area of the upper base surface of the conical trapezoidal shape (e.g., the opening portion provided in the conductor 240) is larger than the area of the lower base surface of the conical trapezoidal shape (the top surface of the conductor 120 exposed in the opening portion 290). Such a structure can increase the area where the oxide semiconductor 230 and the conductor 120 are in contact with each other.

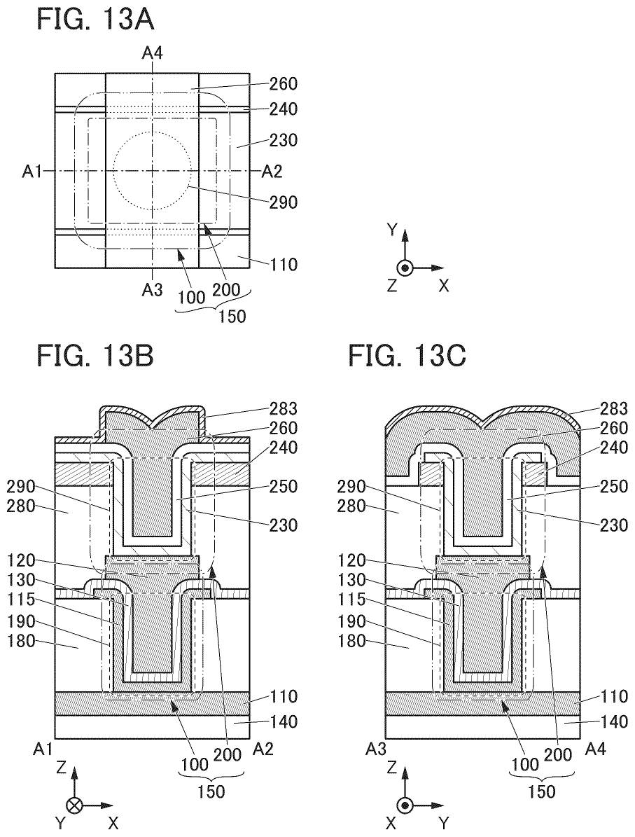

As illustrated in FIG. 7B and FIG. 7C, part of the oxide semiconductor 230 is positioned outside the opening portion 290, that is, over the conductor 240. Although FIG. 7B illustrates the structure in which the oxide semiconductor 230 is divided in the X direction, the present invention is not limited thereto. For example, as illustrated in FIG. 13A and FIG. 13B, the oxide semiconductor 230 may be provided to extend in the X direction. Note that also in the structure illustrated in FIG. 13A and FIG. 13B, the oxide semiconductor 230 is divided in the Y direction (see FIG. 13C).

The structure in FIG. 7C shows that the side end portion of the oxide semiconductor 230 is positioned inwardly from the side end portion of the conductor 240. Note that the present invention is not limited thereto. For example, in the Y direction, the side end portion of the oxide semiconductor 230 and the side end portion of the conductor 240 may be aligned with each other. Alternatively, the side end portion of the oxide semiconductor 230 may be positioned outside the side end portion of the conductor 240.

The metal oxide used as the oxide semiconductor 230 preferably has a band gap of 2 eV or higher, further preferably 2.5 eV or higher. With use of a metal oxide having a wide band gap as the oxide semiconductor 230, the off-state current of the transistor can be reduced. When the transistor with a low off-state current is use in a memory cell, the memory cell can retain stored contents for a long time. In other words, such a memory device does not require refresh operation or has extremely low frequency of the refresh operation, which leads to a sufficient reduction in power consumption of the memory device. For example, the frequency of refresh operation in a general DRAM is approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, a single layer or stacked layers including any of metal oxides described in the section [Metal oxide] below can be used.

As the oxide semiconductor 230, a metal oxide with an atomic ratio of In:M:Zn is 1:3:2 or in the neighborhood thereof, a metal oxide with an atomic ratio of In:M:Zn is 1:3:4 or a composition in the neighborhood thereof, a metal oxide with an atomic ratio of In:M:Zn is 1:1:0.5 or a composition in the neighborhood thereof, a metal oxide with an atomic ratio of In:M:Zn is 1:1:1 or a composition in the neighborhood thereof, a metal oxide with an atomic ratio of In:M:Zn is 1:1:1.2 or a composition in the neighborhood thereof, a metal oxide with an atomic ratio of In:M:Zn is 1:1:2 or a composition in the neighborhood thereof, or a metal oxide with an atomic ratio of In:M:Zn is 4:2:3 or a composition in the neighborhood thereof can be specifically used. Note that a composition in the neighborhood includes the range of ±30 % of an intended atomic ratio. Gallium is preferably used as the element M.

Note that when a film of the metal oxide is formed by a sputtering method, the above atomic ratio is not limited to the atomic ratio of the formed metal oxide and may be the atomic ratio of a sputtering target used for forming the film of the metal oxide.

As an analysis method of the composition of the metal oxide used in the oxide semiconductor 230, for example, energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

An ALD method can be suitably used for forming the metal oxide.

Alternatively, a sputtering method or a CVD method may be used to form the metal oxide.

Note that in the case where the metal oxide is formed by a sputtering method, the composition of the formed metal oxide may be different from the composition of a sputtering target. In particular, the content percentage of the zinc in the formed metal oxide may be reduced to approximately 50 % of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. For the oxide semiconductor 230, the CAAC-OS or the nc-OS is preferably used, and the CAAC-OS is particularly preferably used.

CAAC-OS preferably includes a plurality of layered crystal regions and a c-axis is preferably aligned in a normal direction of a surface where the CAAC-OS is deposited. For example, the oxide semiconductor 230 preferably includes a layered crystal that is substantially parallel to the sidewall of the opening portion 290, particularly the side surface of the insulator 280. With this structure, the layered crystals of the oxide semiconductor 230 are formed substantially in parallel to the channel length direction of the transistor 200, so that the on-state current of the transistor can be increased.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), electron diffraction, or the like, for example. Alternatively, such kinds of analysis methods may be performed in combination.

Although the oxide semiconductor 230 being a single layer is illustrated in FIG. 7B and FIG. 7C, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

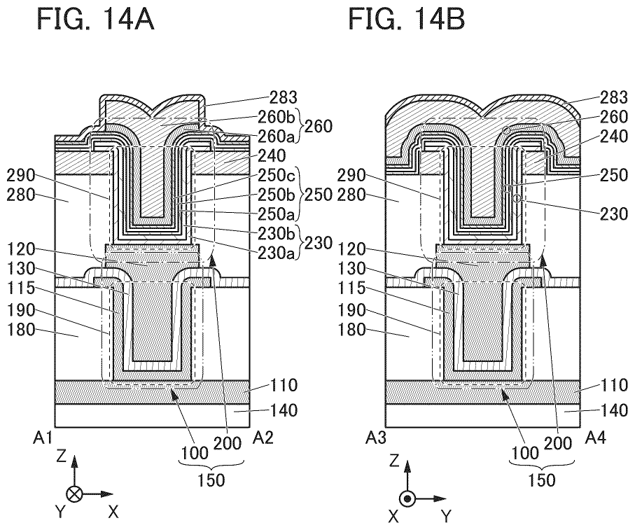

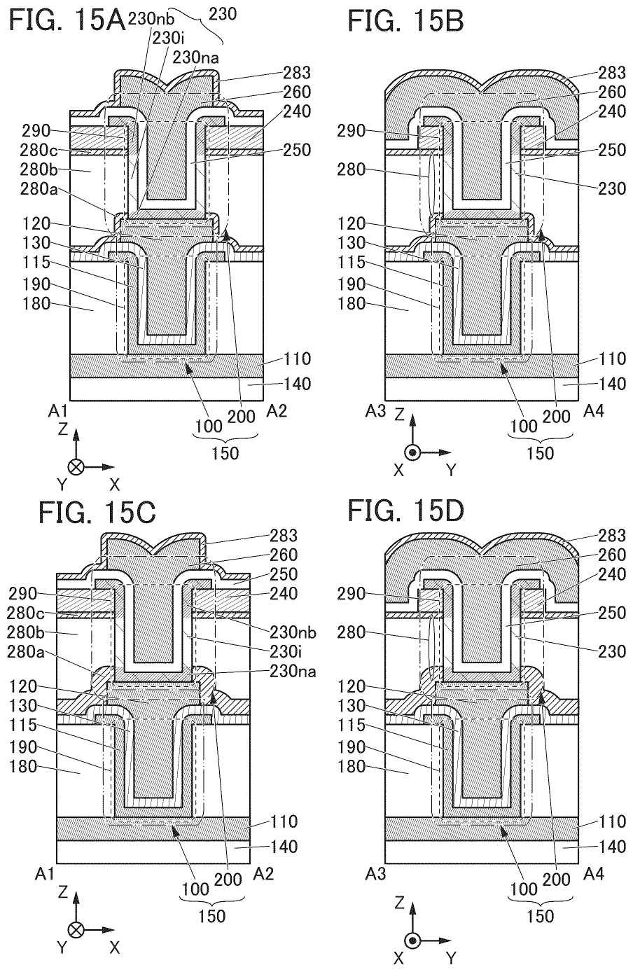

For example, as illustrated in FIG. 14A and FIG. 14B, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than the oxide semiconductor 230b can be used for the oxide semiconductor 230a. The use of the material having high conductivity for the oxide semiconductor 230a, which is in contact with the conductor 120 and the conductor 240 functioning as the source electrode or the drain electrode, can reduce the contact resistance between the oxide semiconductor 230 and the conductor 120 and the contact resistance between the oxide semiconductor 230 and the conductor 240, so that the transistor can have high on-state current.

Here, in the case where a material having high conductivity is used for the oxide semiconductor 230b provided on the side of the conductor 260 functioning as the gate electrode, the threshold voltage of the transistor is shifted and drain current flowing when the gate voltage is 0 V (hereinafter also referred to as cutoff current) becomes large in some cases. Specifically, the threshold voltage might be low when the transistor 200 is an n-channel transistor. Thus, a material having lower conductivity than the oxide semiconductor 230a is preferably used for the oxide semiconductor 230b. Accordingly, the transistor 200 can have high threshold voltage in the case where the transistor is an n-channel transistor; the transistor 200 can have low cut-off current. Note that characteristics with a low cut-off current are sometimes referred to as normally-off characteristics.

When the oxide semiconductor 230 has a stacked-layer structure and a material having higher conductivity than a material for the oxide semiconductor 230b is used for the oxide semiconductor 230a, as described above, the transistor can have normally-off characteristics and high on-state current. Consequently, the memory device can have both low power consumption and high performance.

Note that the carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 120 and the contact resistance between the oxide semiconductor 230 and the conductor 240, so that the transistor can have high on-state current. When the carrier concentration of the oxide semiconductor 230b is reduced, the conductivity is reduced, so that the transistor can have normally-off characteristics.

Although an example in which a material having higher conductivity than the oxide semiconductor 230b is used for the oxide semiconductor 230a is described here, one embodiment of the present invention is not limited thereto. A material having lower conductivity than the oxide semiconductor 230b may be used for the oxide semiconductor 230a. The carrier concentration of the oxide semiconductor 230a can be lower than that of the oxide semiconductor 230b.

The band gap of the first metal oxide used for the oxide semiconductor 230a and the band gap of the second metal oxide used for the oxide semiconductor 230b are preferably different from each other. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 120 and the contact resistance between the oxide semiconductor 230 and the conductor 240 can be reduced, so that the transistor can have high on-state current. Furthermore, the transistor 200 can have high threshold voltage in the case where the transistor is an n-channel transistor; the transistor 200 can be a normally-off transistor.

Although an example in which the band gap of the first metal oxide is smaller than that of the second metal oxide is described here, one embodiment of the present invention is not limited thereto. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In—M—Zn oxide, the first metal oxide can have an atomic ratio of In:M:Zn=1:1:1 or a composition in the neighborhood thereof, and the second metal oxide can have an atomic ratio of In:M:Zn=1:3:2 or a composition in the neighborhood thereof. It is particularly preferable to use one or more of gallium, aluminum, and tin as the element M.

The first metal oxide may have a composition not including the element M. For example, the first metal oxide used for the oxide semiconductor 230a can be an In—Zn oxide, and the second metal oxide used for the oxide semiconductor 230b can be an In—M—Zn oxide. Specifically, the first metal oxide can be an In—Zn oxide, and the second metal oxide can be an In—Ga—Zn oxide. More specifically, the first metal oxide can have an atomic ratio of In:Zn=1:1 or a composition in the neighborhood thereof or an atomic ratio of In:Zn=4:1 or a composition in the neighborhood thereof, and the second metal oxide can have an atomic ratio of In:Ga:Zn=1:1:1 or a composition in the neighborhood thereof.

Although an example in which the content percentage of the element M in the first metal oxide is lower than that of the element M in the second metal oxide is described here, one embodiment of the present invention is not limited thereto. The content percentage of the element M in the first metal oxide may be higher than that of the element M in the second metal oxide. Note that as long as the compositions of the first metal oxide and the second metal oxide are different from each other, the content percentages of elements other than the element M may be different from each other.

The thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thickness of each layer included in the oxide semiconductor 230 (here, the oxide semiconductor 230a and the oxide semiconductor 230b) is determined so that the thickness of the oxide semiconductor 230 is within the above range. The thickness of the oxide semiconductor 230a can be determined so that the contact resistance between the oxide semiconductor 230a and the conductor 120 and the contact resistance between the oxide semiconductor 230a and the conductor 240 are within the required range. The thickness of the oxide semiconductor 230b can be determined so that the threshold voltage of the transistor is within the required range. Note that the thickness of the oxide semiconductor 230a may be the same as or different from the thickness of the oxide semiconductor 230b.

Although the structure in FIG. 14A and FIG. 14B shows that the oxide semiconductor 230 has a two-layer-stacked structure of the oxide semiconductor 230a and the oxide semiconductor 230b, the present invention is not limited thereto. The oxide semiconductor 230 may have a stacked-layer structure of three of more layers.

In the case where the oxide semiconductor 230 has a three-layer structure, the oxide semiconductor 230 may have a structure in which a metal oxide with an atomic ratio of In:Ga:Zn=1:1:1 or a composition in the neighborhood thereof, a metal oxide with an atomic ratio of In:Zn=1:1 or a composition in the neighborhood thereof or with an atomic ratio of In:Zn=4:1 or a composition in the neighborhood thereof, and a metal oxide with an atomic ratio of In:Ga:Zn=1:1:1 or a composition in the neighborhood thereof are provided in order from the conductor 120 side. With this structure, the on-state current of the transistor 200 can be increased, and the transistor can have high reliability with small variations.

As the insulator 250, a single layer or stacked layers of any of the insulators described in the section [Insulator] below can be used. For the insulator 250, silicon oxide or silicon oxynitride can be used. In particular, silicon oxide and silicon oxynitride, which are thermally stable, are preferable.

As the insulator 250, any of insulators with high dielectric constants, that is, high-k materials, described in the section [Insulator] below may be used. For example, hafnium oxide, aluminum oxide, or the like may be used.

The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. In this case, at least part of the insulator 250 preferably has a region with the above-described thickness.

The concentration of impurities such as water and hydrogen in the insulator 250 is preferably reduced. This can inhibit entry of impurities such as water and hydrogen into the channel formation region of the oxide semiconductor 230.

As illustrated in FIG. 7B and FIG. 7C, part of the insulator 250 is positioned outside the opening portion 290, that is, over the conductor 240 and the insulator 280. In that case, the insulator 250 preferably covers side end portions of the oxide semiconductor 230. This can prevent a short circuit between the conductor 260 and the oxide semiconductor 230. The insulator 250 preferably covers side end portions of the conductor 240. This can prevent a short circuit between the conductor 260 and the conductor 240.

Although FIG. 7B and FIG. 7C show that the insulator 250 has the single-layer structure, the present invention is not limited thereto. The insulator 250 may have a stacked-layer structure.

For example, as illustrated in FIG. 14A and FIG. 14B, the insulator 250 may have a stacked-layer structure including an insulator 250a, an insulator 250b over the insulator 250a, and an insulator 250c over the insulator 250b.

For the insulator 250b, a material with a low dielectric constant described in the section [Insulator] below is preferably used. In particular, silicon oxide and silicon oxynitride, which are thermally stable, are preferable. The insulator 250b in this case is an insulator containing at least oxygen and silicon. With such a structure, parasitic capacitance generated between the conductor 260 and the conductor 240 can be reduced. Furthermore, the concentration of impurities such as water and hydrogen in the insulator 250b is preferably reduced.

For the insulator 250a, any of the insulators having a barrier property against oxygen described in the section [Insulator] below is preferably used. The insulator 250a includes a region in contact with the oxide semiconductor 230. When the insulator 250a has a barrier property against oxygen, release of oxygen from the oxide semiconductor 230 at the time of performing heat treatment or the like can be inhibited. This can inhibit formation of oxygen vacancies in the oxide semiconductor 230. Accordingly, the transistor 200 can have favorable electrical characteristics and higher reliability. As the insulator 250a, aluminum oxide may be used, for instance. In this case, the insulator 250a contains at least oxygen and aluminum.

For the insulator 250c, any of the insulators having a barrier property against hydrogen described in the section [Insulator] below is preferably used. Accordingly, diffusion of impurities contained in the conductor 260 into the oxide semiconductor 230 can be inhibited. In particular, silicon nitride is suitably used for the insulator 250c because of its high hydrogen barrier property. In this case, the insulator 250c contains at least nitrogen and silicon.

The insulator 250c may further have a barrier property against oxygen. The insulator 250c is provided between the insulator 250b and the conductor 260. Thus, diffusion of oxygen contained in the insulator 250b into the conductor 260 can be prevented, so that oxidation of the conductor 260 can be inhibited. A reduction in the amount of oxygen supplied to the region 230i can be inhibited.

An insulator may be provided between the insulator 250b and the insulator 250c. For the insulator, any of the insulators having a function of capturing or fixing hydrogen described in the section [Insulator] below is preferably used. With the insulator, hydrogen contained in the oxide semiconductor 230 can be captured or fixed more effectively. Thus, the hydrogen concentration in the oxide semiconductor 230 can be lowered. For the insulator, hafnium oxide may be used, for example. In this case, the above insulator contains at least oxygen and hafnium. Alternatively, the insulator may have an amorphous structure.

The thicknesses of the insulator 250a to the insulator 250c are preferably small for microfabrication of the transistor 200 and are preferably within the above range. Typically, the thicknesses of the insulator 250a, the insulator 250b, the insulator having a function of capturing or fixing hydrogen, and the insulator 250 c are respectively 1 nm, 2 nm, 2 nm, and 1 nm. Such a structure enables the transistor 200 to have favorable electrical characteristics even when the transistor is miniaturized or highly integrated.

Although the structure illustrated in FIG. 14A and FIG. 14B shows that the insulator 250 has a three-layer-stacked structure of the insulator 250a to the insulator 250c, the present invention is not limited thereto. The insulator 250 may be a stacked-layer structure of two layers or four or more layers. In that case, the layers included in the insulator 250 are preferably selected as appropriate from the insulator 250a to the insulator 250c and the insulator having a function of capturing or fixing hydrogen.

As the conductor 260, a single layer or stacked layers of any of the conductors described in the section [Conductor] below can be used. For example, a conductive material with high conductivity such as tungsten can be used for the conductor 260, for example.

In addition, a conductive material that is less likely to be oxidized, a conductive material having a function of inhibiting diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

Although FIG. 7B and FIG. 7C show that the conductor 260 has the single-layer structure, the present invention is not limited thereto. Note that the conductor 260 may have a stacked-layer structure. For example, as illustrated in FIG. 14A and FIG. 14B, the conductor 260 may have a stacked-layer structure of a conductor 260a and a conductor 260b over the conductor 260a. In that case, titanium nitride may be used as the conductor 260a, and tungsten may be used as the conductor 260b. When tungsten is stacked in this manner, the conductivity of the conductor 260 can be improved and can serve well as the wiring WL.

Although the structure in FIG. 14A and FIG. 14B shows that the conductor 260 has a stacked-layer structure of two layers of the conductor 260a and the conductor 260b, the present invention is not limited thereto. The conductor 260 may have a stacked-layer structure of three or more layers.

Although the conductor 260 is provided to fill the opening portion 290 in FIG. 7B and FIG. 7C, the present invention is not limited thereto. For example, the depressed portion reflecting the shape of the opening portion 290 is formed in a center portion of the conductor 260, and part of the depressed portion is placed in the opening portion 290, in some cases. In such a case, the depressed portion may be filled with an inorganic insulating material or the like.

As illustrated in FIG. 7B and FIG. 7C, part of the conductor 260 is positioned outside the opening portion 290, that is, over the conductor 240 and the insulator 280. In this case, as illustrated in FIG. 7B, the side end portion of the conductor 260 is preferably positioned inward from the side end portion of the oxide semiconductor 230. This can prevent a short circuit between the conductor 260 and the oxide semiconductor 230. Note that the side end portion of the conductor 260 may be aligned with the side end portion of the oxide semiconductor 230 or positioned outward from the side end portion of the oxide semiconductor 230.

The conductor 120 is provided as described in the section [Capacitor 100].

Although the structure in FIG. 7B and FIG. 7C shows that the top surface of the conductor 120 is flat, the present invention is not limited thereto. For example, a depressed portion overlapping with the opening portion 290 may be formed on the top surface of the conductor 120. When at least parts of the oxide semiconductor 230, the insulator 250, and the conductor 260 are formed to fill the depressed portion, the gate electric field of the conductor 260 can be easily applied to the vicinity of the conductor 120 in the oxide semiconductor 230.

As the conductor 240, a single layer or stacked layers of any of the conductors described in the section [Conductor] below can be used. Moreover, a conductive material with high conductivity such as tungsten can be used for the conductor 240, for example.

A conductive material that is less likely to be oxidized, a conductive material having a function of inhibiting diffusion of oxygen, or the like is preferably used for the conductor 240, like the conductor 260. For example, titanium nitride, tantalum nitride, or the like can be used. Such a structure can inhibit the excessive oxidation of the conductor 240 due to the oxide semiconductor 230.

In addition, a structure in which tungsten is stacked over titanium nitride may be used, for example. When tungsten is stacked in this manner, the conductivity of the conductor 240 can be improved and can serve well as the wiring BL.

In the case where the conductor 240 has a structure where a first conductor and a second conductor are stacked, the first conductor may be formed using a conductive material with high conductivity and the second conductor may be formed using a conductive material containing oxygen, for example. When a conductive material containing oxygen is used as the second conductor of the conductor 240 that is in contact with the insulator 250, oxygen in the insulator 250 can be prevented from diffusing into the first conductor of the conductor 240. For example, tungsten is preferably used as the first conductor of the conductor 240, and indium tin oxide to which silicon is added is preferably used as the second conductor of the conductor 240.

When the oxide semiconductor 230 and the conductor 120 are in contact with each other, a metal compound or oxygen vacancies are formed, so that the resistance of the region 230na in the oxide semiconductor 230 is reduced. The reduction in the resistance of the oxide semiconductor 230 in contact with the conductor 120 can reduce the contact resistance between the oxide semiconductor 230 and the conductor 120. Similarly, when the oxide semiconductor 230 and the conductor 240 are in contact with each other, the resistance of the region 230nb in the oxide semiconductor 230 is reduced. Accordingly, the contact resistance between the oxide semiconductor 230 and the conductor 240 can be reduced.

The insulator 140 and the insulator 280 each function as an interlayer film and thus preferably has a low dielectric constant. When a material with a low dielectric constant is used for an interlayer film, parasitic capacitance generated between wirings can be reduced. As the insulator 140 and the insulator 280, a single layer or stacked layers of an insulator containing any of the materials with low dielectric constants described in the section [Insulator] below can be used. In particular, silicon oxide and silicon oxynitride are preferable because they are thermally stable.

The concentration of impurities such as water and hydrogen in each of the insulator 140 and the insulator 280 is preferably reduced. This can inhibit entry of impurities such as water and hydrogen into the channel formation region of the oxide semiconductor 230.

As the insulator 280 placed in the vicinity of the channel formation region, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 230 and oxygen vacancies and VoH can be reduced. Thus, the transistor 200 can have stable electrical characteristics and increased reliability.

As the insulator 280, any of the insulators having a function of capturing or fixing hydrogen described in the section [Insulator] below may be used. With this structure, hydrogen in the oxide semiconductor 230 can be captured or fixed, so that the concentration of hydrogen in the oxide semiconductor 230 can be reduced. As the insulator 280, magnesium oxide, aluminum oxide, or the like can be used.

Although FIG. 7B and FIG. 7C show that the insulator 280 has the single-layer structure, the present invention is not limited thereto. The insulator 280 may have a stacked-layer structure.

For example, as illustrated in FIG. 15A and FIG. 15B, the insulator 280 may have a stacked-layer structure of an insulator 280a, an insulator 280b over the insulator 280a, and an insulator 280c over the insulator 280b.

An insulator containing oxygen is preferably used as the insulator 280b. It is preferable that the insulator 280b include a region having a higher oxygen content than at least one of the insulator 280a and the insulator 280c. It is particularly preferable that the insulator 280b include a region having a higher oxygen content than each of the insulator 280a and the insulator 280c. The insulator 280b has high oxygen content, which can facilitate formation of an i-type region in the region of the oxide semiconductor 230 that is in contact with the insulator 280b and the vicinity of this region.

It is further preferable that a film from which oxygen is released by heating be used for the insulator 280b. When the insulator 280b releases oxygen by heat applied during the manufacturing process of the transistor 200, the oxygen can be supplied to the oxide semiconductor 230. The supply of oxygen from the insulator 280b to the oxide semiconductor 230, particularly to the channel formation region of the oxide semiconductor 230, reduces the amount of oxygen vacancy in the oxide semiconductor 230, so that the transistor can have favorable electrical characteristics and high reliability.

For example, the insulator 280b can be supplied with oxygen when heat treatment or plasma treatment is performed in an oxygen-containing atmosphere or plasma treatment is performed in an oxygen-containing atmosphere. Alternatively, an oxide film may be formed over the top surface of the insulator 280b by a sputtering method in an oxygen atmosphere to supply oxygen. After that, the oxide film may be removed.

The insulator 280b is preferably formed by a film formation method such as a sputtering method or a plasma-enhanced chemical vapor deposition (PECVD) method. It is particularly preferable to employ a sputtering method, in which a hydrogen gas does not need to be used as a film formation gas, to form a film having an extremely low hydrogen content. In that case, supply of hydrogen to the oxide semiconductor 230 is inhibited and the electrical characteristics of the transistor 200 can be stabilized.

In the case where the channel length of the transistor 200 is short, oxygen vacancy and V_{O}H in the channel formation region greatly affect electrical characteristics and reliability. Supplying oxygen from the insulator 280b to the oxide semiconductor 230 can inhibit an increase in oxygen vacancies and V_{O}H at least in a region of the oxide semiconductor 230 that is in contact with the insulator 280b. Thus, the transistor with a short channel length can have favorable electrical characteristics and high reliability.

For each of the insulator 280a and the insulator 280c, any of the insulators having a barrier property against hydrogen described in the section [Insulator] below is preferably used. Accordingly, oxygen contained in the insulator 280b can be inhibited from diffusing by heating to the substrate side through the insulator 280a and to the insulator 250 side through the insulator 280c. In other words, when the insulator 280a and the insulator 280c that do not easily allow diffusion of oxygen are respectively provided below and above the insulator 280b so that the insulator 280b is sandwiched therebetween, oxygen can be enclosed in the insulator 280b. Thus, oxygen can be effectively supplied to the oxide semiconductor 230.

The conductor 120 and the conductor 240 are oxidized by oxygen contained in the insulator 280b and have high resistance in some cases. Providing the insulator 280a between the insulator 280b and the conductor 120 can inhibit the conductor 120 from being oxidized and having high resistance. Furthermore, providing the insulator 280c between the insulator 280b and the conductor 240 can inhibit the conductor 240 from being oxidized and having high resistance. Accordingly, the amount of oxygen supplied from the insulator 280b to the oxide semiconductor 230 is increased, so that oxygen vacancies in the oxide semiconductor 230 can be reduced.

The contact region between the oxide semiconductor 230 and the insulator 280a and the contact region between the oxide semiconductor 230 and the insulator 280c are supplied with a smaller amount of oxygen than the contact region between the oxide semiconductor 230 and the insulator 280b. Thus, the contact region between the oxide semiconductor 230 and the insulator 280a and the contact region between the oxide semiconductor 230 and the insulator 280c each have a low resistance in some cases. That is, by adjusting the thickness of the insulator 280a, the range of the region 230na functioning as one of the source region and the drain region can be controlled. Similarly, by adjusting the thickness of the insulator 280c, the range of the region 230nb functioning as the other of the source region and the drain region can be controlled.

As described above, the source region and the drain region can be controlled by the thicknesses of the insulator 280a and the insulator 280c; thus, the thicknesses of the insulator 280a and the insulator 280c can be set as appropriate in accordance with characteristics required for the transistor 200.

For example, as illustrated in FIG. 15A and FIG. 15B, the thickness of the insulator 280c and the thickness of the insulator 280a may be substantially the same. Alternatively, as illustrated in FIG. 15C and FIG. 15D, the thickness of the insulator 280c may be smaller than that of the insulator 280a, for example. With the structure illustrated in FIG. 15C and FIG. 15D, the region 230na can be close to the bottom portion of the conductor 260 in the opening portion 290. In this case, the area of the region 230i can be regarded as being narrowed. Thus, the on-state current of the transistor 200 can be improved.

Although the structure in FIG. 15C and FIG. 15D shows that the insulator 280c is provided over the planarized insulator 280b, the present invention is not limited thereto. For example, the insulator 280c may be deposited on the insulator 280b that is not subjected to planarization treatment. By not performing planarization treatment, manufacturing cost can be reduced and production yield can be increased. The insulator 280a, the insulator 280b, and the insulator 280c can be successively deposited without exposure to the air. By the deposition without exposure to the air, impurities or moisture from the atmospheric environment can be prevented from being attached onto the insulator 280a to the insulator 280c, so that the vicinity of the interface between the insulator 280a and insulator 280b and the vicinity of the interface between the insulator 280b and the insulator 280c can be kept clean.

For each of the insulator 280a and the insulator 280c, any of the insulators having a barrier property against hydrogen described in the section [Insulator] below is preferably used. In that case, hydrogen can be inhibited from diffusing from the outside of the transistor to the oxide semiconductor 230 through the insulator 280a or the insulator 280c. The silicon nitride film and the silicon nitride oxide film can be suitably used for the insulator 280a and the insulator 280c because the silicon nitride film and the silicon nitride oxide film release fewer impurities (e.g., water and hydrogen) and are less likely to transmit oxygen and hydrogen. For the insulator 280a and the insulator 280c, the same material or different materials may be used.

For the insulator 280a, any of the insulators having a function of capturing or fixing hydrogen described in the section [Insulator] below is preferably used. With this structure, diffusion of hydrogen into the oxide semiconductor 230 from below the insulator 280a can be inhibited, and hydrogen in the oxide semiconductor 230 can be captured or fixed, whereby the hydrogen concentration in the oxide semiconductor 230 can be reduced. Furthermore, diffusion of hydrogen into the insulator 130 from above the insulator 280a can be inhibited, and hydrogen in the insulator 130 can be captured or fixed, so that the hydrogen concentration in the insulator 130 can be reduced. For the insulator 280a, magnesium oxide, aluminum oxide, hafnium oxide, or the like can be used. Alternatively, for example, a stacked-layer film of aluminum oxide and silicon nitride over the aluminum oxide may be used as the insulator 280a.

The thickness of the insulator 280a is preferably smaller than the thickness of the insulator 280b. The thickness of the insulator 280c is preferably smaller than the thickness of the insulator 280b. The thickness of each of the insulator 280a and the insulator 280c is preferably greater than or equal to 1 nm and less than or equal to 15 nm, further preferably greater than or equal to 2 nm and less than or equal to 10 nm, still further preferably greater than or equal to 3 nm and less than or equal to 7 nm, and yet still further preferably greater than or equal to 3 nm and less than or equal to 5 nm. The thickness of the insulator 280 b is preferably greater than or equal to 3 nm and less than or equal to 30 nm, further preferably greater than or equal to 5 nm and less than or equal to 20 nm, still further preferably greater than or equal to 7 nm and less than or equal to 15 nm. When the thicknesses of the insulator 280 a to the insulator 280 c are in the above range, oxygen vacancies in the oxide semiconductor 230, particularly in the channel formation region, can be reduced.

For example, silicon nitride is preferably used for the insulator 280a and the insulator 280c, and silicon oxide is preferably used for the insulator 280b. In that case, each of the insulator 280a and the insulator 280c contains at least silicon and nitrogen. The insulator 280b contains at least silicon and oxygen.

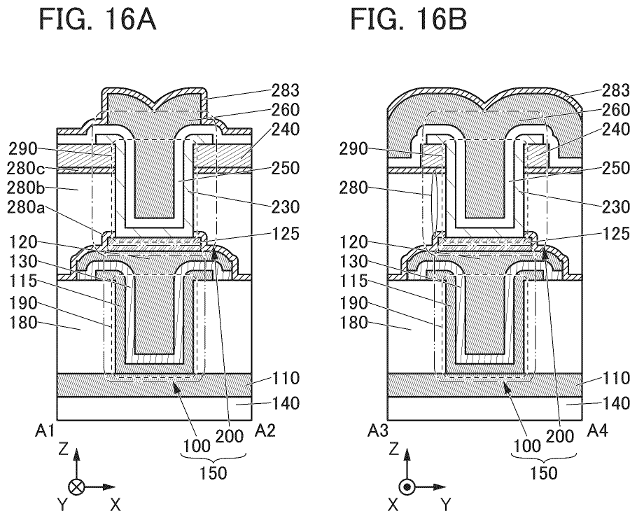

Although FIG. 16A and FIG. 16B illustrate a structure in which the insulator 280 has a stacked-layer structure of three layers, one embodiment of the present invention is not limited thereto. The insulator 280 may have a stacked-layer structure of two layers or four or more layers.

For the insulator 283, any of the insulators having a barrier property against hydrogen described in the section [Insulator] below is preferably used. In that case, hydrogen can be inhibited from diffusing from the outside of the transistor to the oxide semiconductor 230 through the insulator 250. A silicon nitride film and a silicon nitride oxide film are suitable for the insulator 283 because they release fewer impurities (e.g., water and hydrogen) and are less likely to transmit oxygen and hydrogen.

For the insulator 283, any of the insulators having a function of capturing or fixing hydrogen described in the section [Insulator] below is preferably used. With this structure, diffusion of hydrogen into the oxide semiconductor 230 from above the insulator 283 can be inhibited, and hydrogen in the oxide semiconductor 230 can be captured or fixed, whereby the hydrogen concentration in the oxide semiconductor 230 can be reduced. For the insulator 283, magnesium oxide, aluminum oxide, hafnium oxide, or the like can be used. Alternatively, for example, a stacked-layer film of aluminum oxide and silicon nitride over the aluminum oxide may be used as the insulator 283.

Although the structure in FIG. 7B and FIG. 7C shows that the insulator 283 is formed over the top surface of the transistor 200, one embodiment of the present invention is not limited thereto. For example, the insulator 283 (or an insulator having a function or a material similar to that of the insulator 283) may be formed on the side surface and the bottom surface of the transistor 200, and the transistor 200 may be surrounded by the insulator 283. Alternatively, the insulator 283 may be formed on the top surfaces, the side surfaces, and the bottom surfaces of the transistor 200 and the capacitor 100, and the transistor 200 and the capacitor 100 may be surrounded by the insulator 283. Such a structure can inhibit entry of impurities (e.g., impurities such as water and hydrogen) into the transistor 200 or the capacitor 100.

Although the structure in FIG. 7B and FIG. 7C includes a region where the top surface of the conductor 120 and the bottom surface of the oxide semiconductor 230 are in contact with each other, the present invention is not limited thereto. For example, another conductor may be provided between the conductor 120 and the oxide semiconductor 230.

For example, as illustrated in FIG. 16A and FIG. 16B, a conductor 125 may be provided between the conductor 120 and the oxide semiconductor 230. For the conductor 125, a conductive material containing oxygen described in the section [Conductor] below is preferably used. When a conductive material containing oxygen is used for the conductor 125, the conductor 125 can maintain its conductivity even when absorbing oxygen. Furthermore, diffusion of oxygen from the oxide semiconductor 230 into the conductor 120 can be inhibited. As the conductor 125, a single layer or stacked layers of indium tin oxide, indium tin oxide to which silicon is added, indium zinc oxide, or the like can be used, for example.

The structure in FIG. 7B and FIG. 7C shows that the conductor 240 is provided over the insulator 280. Furthermore, a region of the insulator 250 that does not overlap with the conductor 240 includes a region in contact with the top surface of the insulator 280. Note that the present invention is not limited thereto.

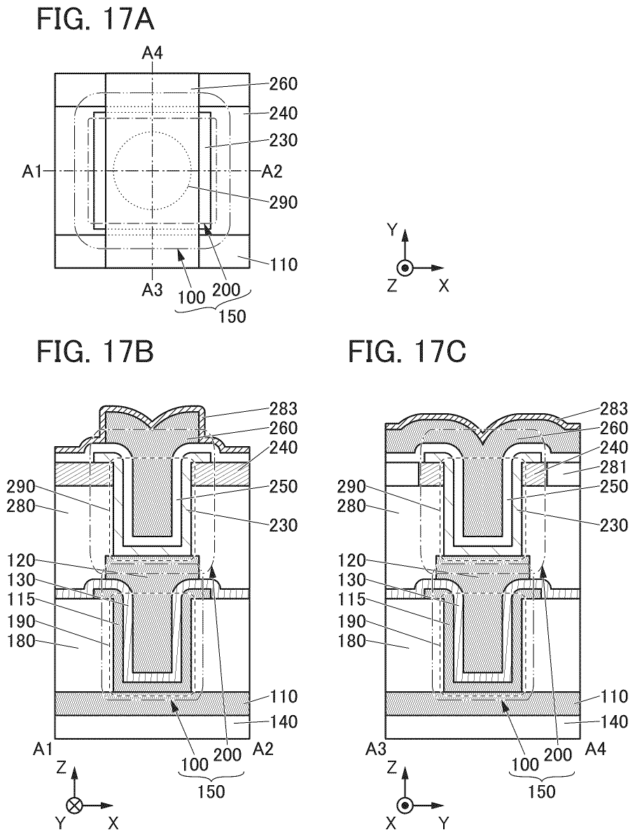

For example, as illustrated in FIG. 17B and FIG. 17C, the conductor 240 may be provided to be embedded in an insulator 281. In that case, the top surface of the conductor 240 and the top surface of the insulator 281 are preferably level with each other. With such a structure, the physical distance from the conductor 260 to the conductor 240 (particularly to the side end portion of the conductor 240) can be increased, so that a short circuit between the conductor 260 and the conductor 240 can be prevented. Note that FIG. 17A is a plan view of the memory device illustrated in FIG. 17B and FIG. 17C.

The insulator 281 functions as an interlayer film and thus preferably include a material with a low dielectric constant. When a material with a low dielectric constant is used for an interlayer film, parasitic capacitance generated between wirings can be reduced. As the insulator 281, a single layer or stacked layers of any of the insulators including a material with a low dielectric constant described in the section [Insulator] below can be used.

### Component Material of Memory Device

Component materials that can be used for the memory device are described below.

### Substrate

As a substrate where the transistor 200 and the capacitor 100 are formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a low-dielectric-constant material is used for the insulator functioning as an interlayer film, parasitic capacitance generated between wirings can be reduced. Thus, a material is preferably selected depending on the function of the insulator. Note that the low-dielectric-constant material is a material with high dielectric strength.

Examples of the high-dielectric-constant (high-k) material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low dielectric constant include silicon oxide to which fluorine is added, silicon oxide to which carbon is added, and silicon oxide to which carbon and nitrogen are added. Another example is porous silicon oxide. These silicon oxides may contain nitrogen. Silicon oxide may be formed using, for example, organosilane such as tetraethoxy silane (TEOS).

When a transistor including a metal oxide is surrounded by an insulator having a function of inhibiting passage of oxygen, the transistor can have stable electrical characteristics. As the insulator having a function of inhibiting passage of oxygen and impurities such as hydrogen, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the barrier insulator against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of an insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that the metal oxide preferably has an amorphous structure, but a crystal region may be partly formed.

Note that in this specification and the like, a barrier insulating film refers to an insulating film having a barrier property. Note that the barrier property in this specification and the like refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### Conductor

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide (, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With use of such a material, hydrogen contained in the metal oxide where the channel is formed can be captured in some cases. Alternatively, hydrogen entering from an external insulator or the like can be captured in some cases.

### Metal Oxide

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (V_{O}) and impurities exist in a region of the metal oxide where a channel is formed, which might degrade the reliability. In some cases, a defect that is an oxygen vacancy into which hydrogen in the vicinity of the oxygen vacancy has entered (hereinafter sometimes referred to as V_{O}H) is formed, which generates an electron serving as a carrier. Therefore, when the channel formation region in the metal oxide includes oxygen vacancies, the transistor is likely to have normally-on characteristics (characteristics with which, even when no voltage is applied to the gate electrode, the channel exists and current flows through the transistor). Therefore, oxygen vacancies and impurities are preferably reduced as much as possible in the channel formation region in the metal oxide. In other words, it is preferable that the region of the metal oxide where a channel is formed have a reduced carrier concentration and be of an i-type (intrinsic) or substantially i-type.

The kind of a lattice defect that is likely to exist in a metal oxide and the number of lattice defects that exist vary depending on the structure of the metal oxide, a method for depositing the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a c-axis aligned crystalline oxide semiconductor (CAAC-OS).

The c-axis of the above crystal is preferably aligned in the normal direction with respect to the formation surface or film surface of the metal oxide. This enables the plurality of layers to be placed parallel to or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three kinds selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M included in the metal oxide is gallium, the metal oxide in one embodiment of the present invention preferably includes one or more selected from indium, gallium, and zinc. Note that in this specification and the like, a metal element and a metalloid element may be collectively referred to as a “metal element”, and a “metal element” in this specification and the like may refer to a metalloid element.

For example, as the metal oxide of one embodiment of the present invention, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (Ga—Zn oxide, also referred to as GZO), an aluminum zinc oxide (Al—Zn oxide, also referred to as AZO), an indium aluminum zinc oxide (In—Al—Zn oxide, also referred to as IAZO), an indium tin zinc oxide (In—Sn—Zn oxide), an indium titanium zinc oxide (In—Ti—Zn oxide), an indium gallium zinc oxide (In—Ga—Zn oxide, also referred to as IGZO), an indium gallium tin zinc oxide (In—Ga—Sn—Zn oxide, also referred to as IGZTO), and an indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of or in addition to indium, one or more kinds of metal elements with large period numbers in the periodic table of the elements. Alternatively, the metal oxide may contain, in addition to indium, one or more kinds of metal elements with large period numbers in the periodic table. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, an atomic layer is preferably deposited one by one. By an ALD method, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in an ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS.

When an ALD method is used as the deposition method of a metal oxide, one or both of a deposition condition with a high substrate temperature and impurity removal treatment can form a film with smaller amounts of carbon and chlorine than the case of using an ALD method without the condition and the treatment.

For example, impurity removal treatment is preferably intermittently performed during deposition of the metal oxide in an atmosphere containing oxygen. Furthermore, impurity removal treatment is preferably performed in an atmosphere containing oxygen after the deposition of the metal oxide. The impurities in the film can be removed by performing impurity removal treatment during and/or after the deposition of the metal oxide. This can inhibit impurities (e.g., hydrogen, carbon, and nitrogen) contained in a raw material such as a precursor from remaining in the metal oxide. Accordingly, the impurity concentration in the metal oxide can be reduced. Furthermore, the crystallinity of the metal oxide can be increased.

Examples of the impurity removal treatment include plasma treatment, microwave treatment, and heat treatment.

When plasma treatment or microwave treatment is performed, the substrate temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. The heat treatment temperature is preferably higher than or equal to 100° C., higher than or equal to 200° C., higher than or equal to 300° C., or higher than or equal to 400° C., and lower than or equal to 500° C. or lower than or equal to 450° C.

The temperature of the impurity removal treatment is particularly preferably set lower than or equal to the maximum temperature in the manufacturing process of a transistor or a semiconductor device, in which case the impurity content in the metal oxide can be reduced without decrease in productivity. For example, when the maximum temperature in manufacturing the semiconductor device or the memory device of one embodiment of the present invention is lower than or equal to 500° C., preferably lower than or equal to 450° C., the productivity of the semiconductor device or the memory device can be improved.

Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHz, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the film efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

After the microwave treatment or plasma treatment is performed, heat treatment may be successively performed without exposure to the air. The temperature of the heat treatment is preferably higher than or equal to 100° C. and lower than or equal to 750° C., further preferably higher than or equal to 300° C. and lower than or equal to 500° C., still further preferably higher than or equal to 400° C. and lower than or equal to 450° C.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%.

The heat treatment is performed in a nitrogen gas or inert gas atmosphere, or an atmosphere containing an oxidizing gas at 10 ppm or more, 1% or more, or 10% or more. For example, in the case where the heat treatment is performed in an atmosphere of mixing a nitrogen gas and an oxygen gas, the proportion of the oxygen gas is preferably approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at 10 ppm or more, 1% or more, or 10% or more in order to compensate for released oxygen. The first heat treatment may be performed under ultra-dry air (air with a water content of 20 ppm or less, preferably 1 ppm or less, further preferably 10 ppb or less).

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity, specifically, a metal oxide having a CAAC structure can be formed.

Unlike a deposition method in which particles ejected from a target or the like are deposited, an ALD method is a deposition method in which a film is formed by reaction at a surface of an object. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with use of the crystal part as a nucleus.

When an ALD method is employed, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film in which the composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is omitted. Thus, the productivity of the memory device can be increased in some cases.

### Transistor Including Metal Oxide

Next, the case where a metal oxide (oxide semiconductor) is used for a transistor is described. Hereinafter, a transistor with a semiconductor layer of an oxide semiconductor is sometimes referred to as an OS transistor, and a transistor with a semiconductor layer of silicon is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor having a low carrier concentration is preferably used for a channel formation region of a transistor. For example, the carrier concentration of an oxide semiconductor in the channel formation region is lower than or equal to 1×10¹⁸ cm⁻³, preferably 1×10¹⁷ cm⁻³, further preferably lower than or equal to 1×10¹⁵ cm⁻³, further preferably lower than or equal to 1×10¹³ cm⁻³, further preferably lower than or equal to 1×10¹¹cm⁻³, further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably wider than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a wider band gap than silicon, the off-state current (also referred to as I_{off}) of the transistor can be reduced.

In a Si transistor, a short-channel effect (also referred to as SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus, can have an inhibited short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value refers to the amount of change in a gate voltage which makes the drain current change by one digit in a subthreshold region at a constant drain voltage.

The characteristic length is widely used as an indicator of resistance to a short-channel effect. The characteristic length is an indicator of curving of a potential in a channel formation region. The smaller the characteristic length is, the more sharply the potential rises; thus, a smaller characteristic length indicates higher resistance to a short-channel effect.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source and drain regions become n⁺-type regions in the OS transistor.

An OS transistor having the above structure enables a memory device to have favorable electrical characteristics even when the memory device is miniaturized or highly integrated. For example, the semiconductor device can have favorable electrical characteristics even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

A miniaturized OS transistor can have improved high frequency characteristics. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### Impurity in Metal Oxide

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the concentration of carbon obtained by SIMS in the oxide semiconductor is set lower than or equal to 1×10²⁰ atoms/cm³, preferably lower than or equal to 5×10¹⁹atoms/cm³, further preferably lower than or equal to 3×1019atoms/cm 3 , further preferably lower than or equal to 1×10¹⁹atoms/cm³, further preferably lower than or equal to 3×10¹⁸ atoms/cm³, and further preferably lower than or equal to 1×10¹⁸atoms/cm³. The concentration of silicon obtained by SIMS in the channel formation region of the oxide semiconductor is set lower than or equal to 1×10²⁰atoms/cm³, preferably lower than or equal to 5×10¹⁹atoms/cm3, further preferably lower than or equal to 3×10¹⁹ atoms/cm³, further preferably lower than or equal to 1×10¹⁹atoms/cm³, further preferably lower than or equal to 3×10¹⁸atoms/cm³, and further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen obtained by SIMS in the channel formation region of the oxide semiconductor is set lower than or equal to 1×10²⁰atoms/cm³, preferably lower than or equal to 5×10¹⁹atoms/cm³, further preferably lower than or equal to 1×10¹⁹atoms/cm³, further preferably lower than or equal to 5×10¹⁸atoms/cm³, further preferably lower than or equal to 1×10¹⁸atoms/cm³, and further preferably lower than or equal to 5×10¹⁷atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the concentration of hydrogen obtained by SIMS in the channel formation region of the oxide semiconductor is set lower than 1×10²⁰atoms/cm³, preferably lower than 5×10¹⁹atoms/cm³, further preferably lower than 1×10¹⁹atoms/cm³, further preferably lower than 5×10¹⁸atoms/cm³, and further preferably lower than 1×10¹⁸atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal obtained by SIMS in the channel formation region of the oxide semiconductor is set lower than or equal to 1×10¹⁸atoms/cm³, preferably lower than or equal to 2×10¹⁶atoms/cm³.

When an oxide semiconductor with sufficiently reduced impurities is used for the channel formation region of the transistor, the transistor can have stable electrical characteristics.

### Other Semiconductor Materials

The oxide semiconductor 230 can be rephrased as a semiconductor layer including a channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above-described transition metal chalcogenide for the semiconductor layer enables a memory device with a high on-state current to be provided.

### Manufacturing Method Example 1 for Memory Device

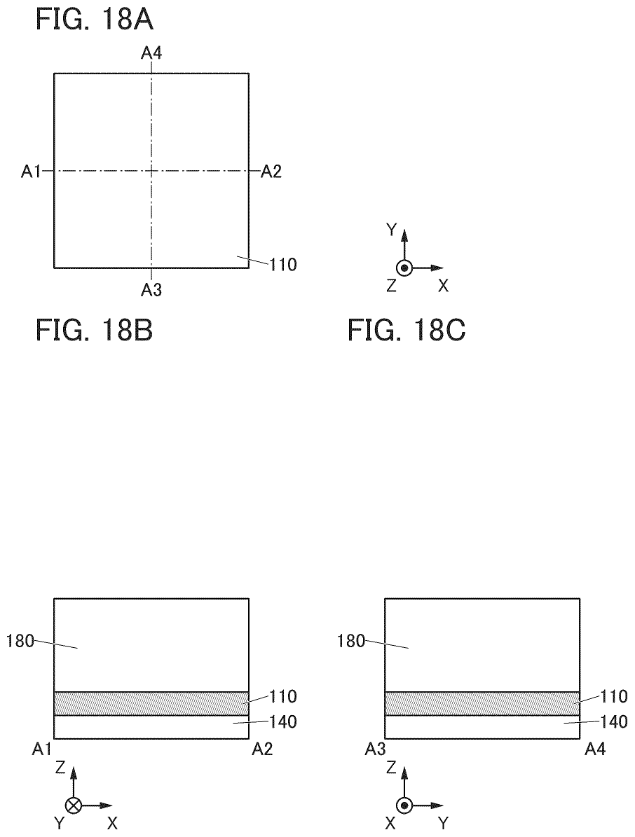

Next, a method for manufacturing the memory device of one embodiment of the present invention illustrated in FIG. 7A to FIG. 7C is described with reference to FIG. 18A to FIG. 28C.

Note that A of each drawing is a top view. Moreover, B of each drawing is a cross-sectional view corresponding to a portion indicated by the dashed-dotted line A1-A2 in A of each drawing. Furthermore, C of each drawing is a cross-sectional view corresponding to a portion indicated by the dashed-dotted line A3-A4 in A of each drawing. Note that for clarity of the drawing, some components are not illustrated in the top view of A of each drawing.

Hereinafter, a film of an insulating material for forming an insulator, a film of a conductive material for forming a conductor, or a film of a semiconductor material for forming a semiconductor can be formed by a sputtering method, a CVD method, an MBE method, a PLD method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that CVD methods can be classified into a plasma CVD (PECVD) method using plasma, a thermal CVD (TCVD) method using heat, a photo CVD method using light, and the like. Furthermore, CVD methods can be classified into a metal CVD (MOCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a memory device may be charged up by receiving charge from plasma. In that case, accumulated charge may break the wiring, the electrode, the element, or the like included in the memory device. In contrast, such plasma damage is not caused in the case of a thermal CVD method, which does not use plasma, and thus the yield of the memory device can be increased. In addition, the thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the memory device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

First, a substrate (not illustrated) is prepared, and the insulator 140 is formed over the substrate (see FIG. 18A to FIG. 18C). Any of the above-described insulating materials can be used for the insulator 140 as appropriate. The insulator 140 can be formed by a sputtering method, a CVD method, an MBE method, a PLD method, an ALD method, or the like as appropriate.

Then, the conductor 110 is formed over the insulator 140. Any of the above-described conductive materials can be used for the conductor 110 as appropriate. The conductor 110 can be deposited by a sputtering method, a CVD method, an MBE method, a PLD method, an ALD method, or the like as appropriate. For example, as the conductor 110, a stacked-layer film in which tungsten and titanium nitride are deposited in this order by a CVD method may be formed.

Note that the conductor 110 may be processed to have a shape extending in the X direction or the Y direction. For the processing of the conductor 110, a lithography method can be employed. A dry etching method or a wet etching method can be used for the processing. Processing by a dry etching method is suitable for microfabrication. By the processing, the side end portion of the conductor 110 is covered with the insulator 130 to be formed later.

In the lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask may be formed through, for example, exposure of the resist to KrF excimer laser light, ArF excimer laser light, EUV light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

Next, the insulator 180 is formed over the conductor 110 (FIG. 18A to FIG. 18C). Any of the above-described insulating materials can be appropriately used for the insulator 180. The insulator 180 can be deposited by a sputtering method, a CVD method, an MBE method, a PLD method, an ALD method, or the like as appropriate. A silicon oxide film is formed by a sputtering method as the insulator 180, for example. The top surface of the deposited insulator 180 is preferably planarized by CMP (chemical mechanical polishing) treatment. Note that the CMP treatment is not necessarily performed in some cases. In such a case, the top surface of the insulator 180 has a convex shape. By not performing planarization treatment, manufacturing cost can be reduced and production yield can be increased.

Here, the thickness of the insulator 180 corresponds to the capacitance of the capacitor 100; thus, the thickness of the insulator 180 can be set as appropriate in accordance with the design value of the capacitance of the capacitor 100.

By using a sputtering method that does not need to use a molecule containing hydrogen as a deposition gas for deposition of the insulator 180, the hydrogen concentration in the insulator 180 can be reduced.

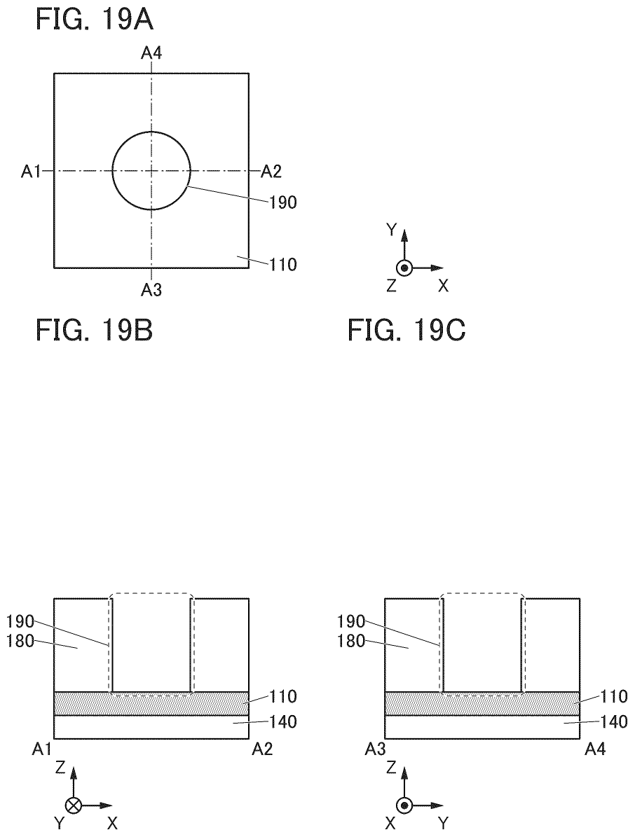

Next, part of the insulator 180 is processed to form the opening portion 190 reaching the conductor 120 (FIG. 19A to FIG. 19C). The opening portion 190 can be formed by a lithography method. Note that the opening portion 190 has a circular shape in the plan view; however, the shape is not limited to the circular shape. For example, the opening portion 190 in the plan view may have an almost circular shape such as an elliptical shape, a polygonal shape such as a quadrangular shape, or a polygonal shape such as a quadrangular shape with rounded corners.

The opening portion 190 is preferably formed using <Formation method of opening portion> in the above section. Accordingly, miniaturization or high integration of the memory device can be achieved.

As described above, the sidewall of the opening portion 190 is preferably perpendicular to the top surface of the conductor 110. With such a structure, the memory device can be more miniaturized and highly integrated. The sidewall of the opening portion 190 may be tapered. When the sidewall of the opening portion 190 has a tapered shape, coverage with a conductive film to be the conductor 115 described later or the like can be improved, so that defects such as a void can be reduced.

The maximum width of the opening portion 190 (the maximum diameter in the case where the opening portion 190 is circular in the plan view) is preferably small. For example, the maximum width of the opening portion 190 is preferably less than or equal to 60 nm, less than or equal to 50 nm, less than or equal to 40 nm, less than or equal to 30 nm, or less than or equal to 20 nm and greater than or equal to 1 nm or greater than or equal to 5 nm.

Since the opening portion 190 has a high aspect ratio, part of the insulator 180 is preferably processed by anisotropic etching. Processing by a dry etching method is particularly preferable because it is suitable for fine processing.

Next, a conductive film to be the conductor 115 is formed in contact with the bottom portion and sidewall of the opening portion 190 and at least part of the top surface of the insulator 180. For the conductive film, any of the conductors that can be used for the conductor 115 can be appropriately used. The conductive film can be formed by a sputtering method, a CVD method, an MBE method, a PLD method, an ALD method, or the like. Here, the conductive film is preferably formed in contact with the bottom portion and sidewall of the opening portion 190 with a high aspect ratio. Thus, the conductive film is preferably formed by a deposition method providing favorable coverage, and is further preferably formed by a CVD method, an ALD method, or the like. For example, as the conductive film, a titanium nitride film is deposited by a CVD method.

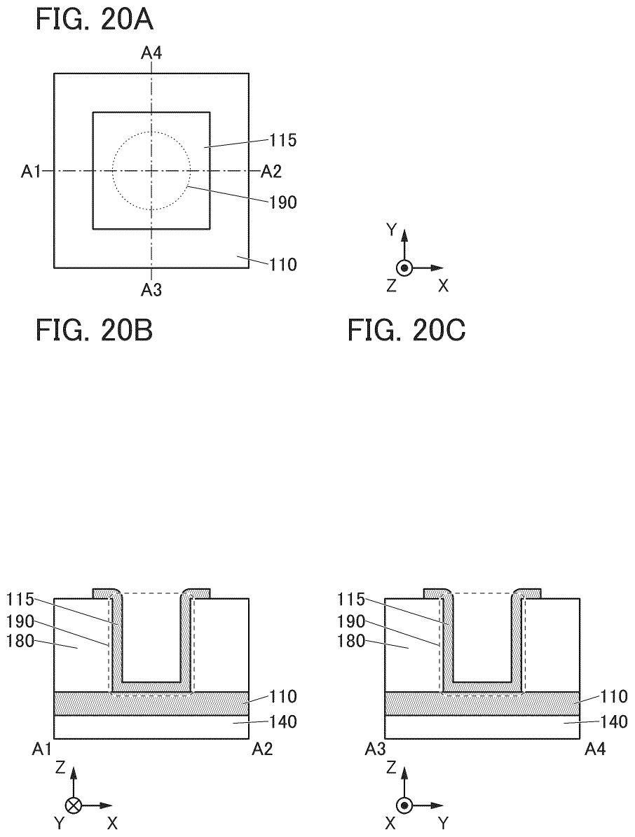

Next, the conductive film to be the conductor 115 is processed by a lithography method to form the conductor 115 (see FIG. 20A to FIG. 20C). Accordingly, part of the conductor 115 is formed in the opening portion 190. The conductor 115 is in contact with the side surface and part of the top surface of the insulator 180.

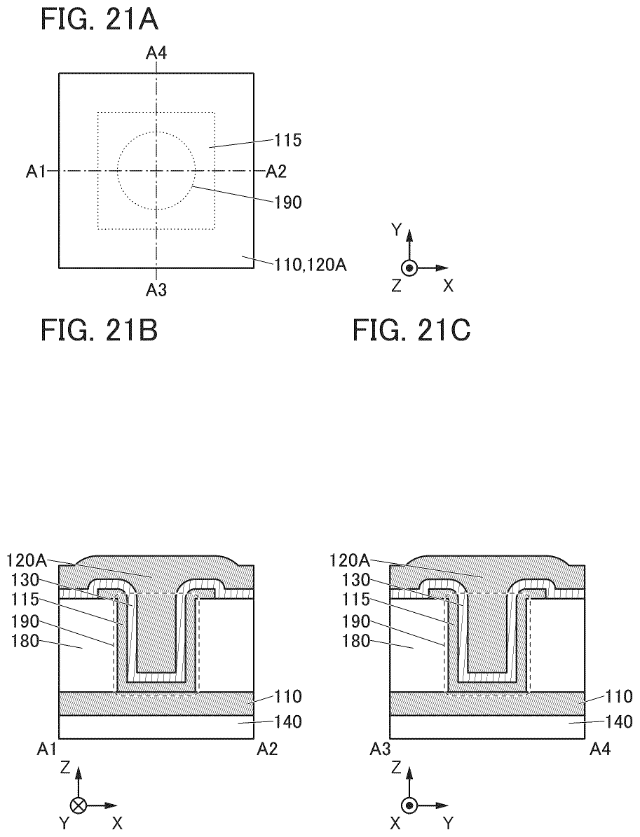

Next, the insulator 130 is formed over the conductor 115 and the insulator 180 (FIG. 21A to FIG. 21C). For the insulator 130, any of the above-described high-k materials or materials that can show ferroelectricity can be appropriately used. The insulator 130 can be deposited by a sputtering method, a CVD method, an MBE method, a PLD method, an ALD method, or the like as appropriate. For example, a stacked-layer film in which zirconium oxide, aluminum oxide, and zirconium oxide are deposited in this order by an ALD method may be formed as the insulator 130.

Next, a conductive film 120A is deposited over the insulator 130 (see FIG. 21A to FIG. 21C). The above-described conductive material can be used for the conductive film 120A. The conductive film 120A can be formed by a sputtering method, a CVD method, an MBE method, a PLD method, an ALD method, or the like as appropriate. For example, as the conductive film 120A, a stacked film in which titanium nitride and tantalum nitride are deposited in this order may be formed by a CVD method. Alternatively, for example, a stacked film in which titanium nitride and tungsten are formed in this order by a CVD method may be used as the conductive film 120A.

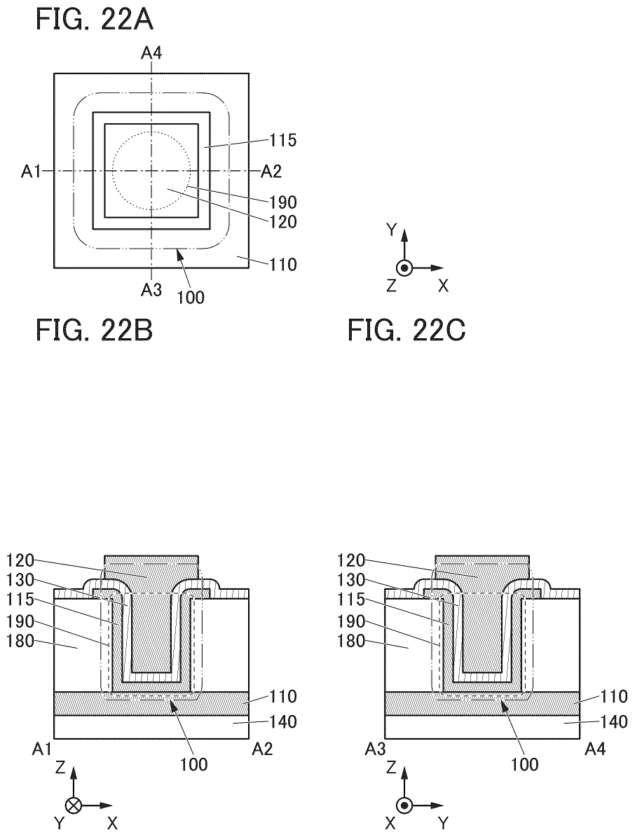

Next, the conductive film 120A is processed to form the conductor 120 (see FIG. 22A to FIG. 22C). The conductor 120 can be formed by a lithography method. For the processing of the conductive film 120A, a dry etching method or a wet etching method can be employed. Processing by a dry etching method is suitable for microfabrication.

In the above manner, the capacitor 100 including the conductor 115, the insulator 130, and the conductor 120 can be formed.

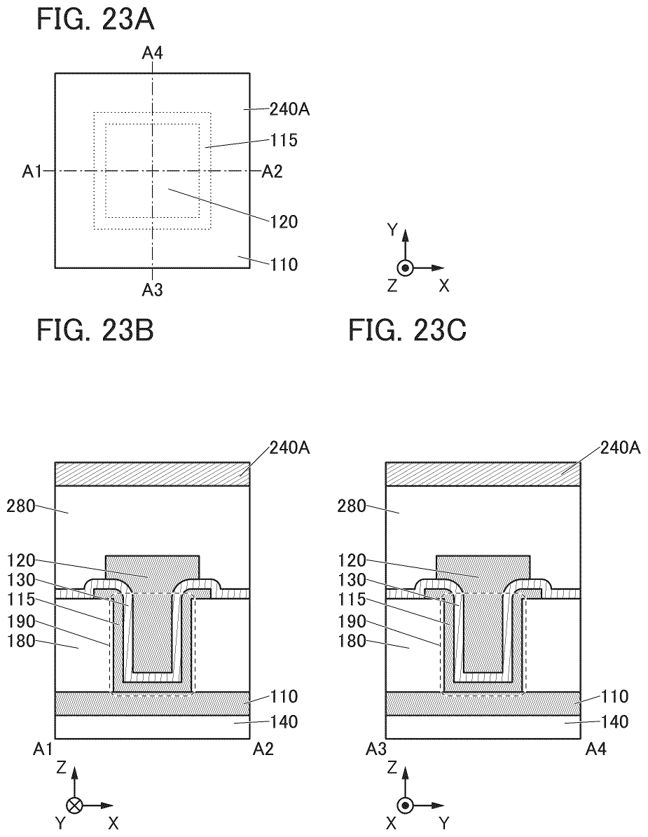

Next, the insulator 280 is formed over the insulator 130 and the conductor 120 (see FIG. 23A to FIG. 23C). Any of the above-described insulating materials can be used as the insulator 280 as appropriate. The insulator 280 can be deposited by a sputtering method, a CVD method, an MBE method, a PLD method, an ALD method, or the like as appropriate. A silicon oxide film is deposited by a sputtering method as the insulator 280, for example. The top surface of the deposited insulator 280 is preferably planarized by chemical mechanical polishing (CMP) treatment. The conductor 240 functioning as a wiring can be suitably formed by performing planarization treatment on the insulator 280. After aluminum oxide is deposited over the insulator 280 by, for example, a sputtering method, the aluminum oxide may be subjected to CMP treatment until the insulator 280 is reached. The CMP treatment can planarize and smooth the surface of the insulator 280. When the CMP treatment is performed on the aluminum oxide provided over the insulator 280, it is easy to detect the endpoint of the CMP treatment.

Note that the CMP treatment is not necessarily performed in some cases. In such a case, the top surface of the insulator 280 has a convex shape. By not performing planarization treatment, manufacturing cost can be reduced and production yield can be increased.

Note that since the thickness of the insulator 280 over the conductor 120 corresponds to the channel length of the transistor 200, the thickness of the insulator 280 can be set as appropriate depending on the design value of the channel length of the transistor 200.

When the insulator 280 is deposited by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. When the insulator 280 is formed in this manner, oxygen can be supplied from the insulator 280 to the channel formation region of the oxide semiconductor 230, so that oxygen vacancies and V_{O}H therein can be reduced.

Next, a conductive film 240A is formed over the insulator 280 (FIG. 23A to FIG. 23C). Any of the above conductive materials can be used for the conductive film 240A as appropriate. The conductive film 240A can be deposited by a sputtering method, a CVD method, an MBE method, a PLD method, an ALD method, or the like as appropriate.

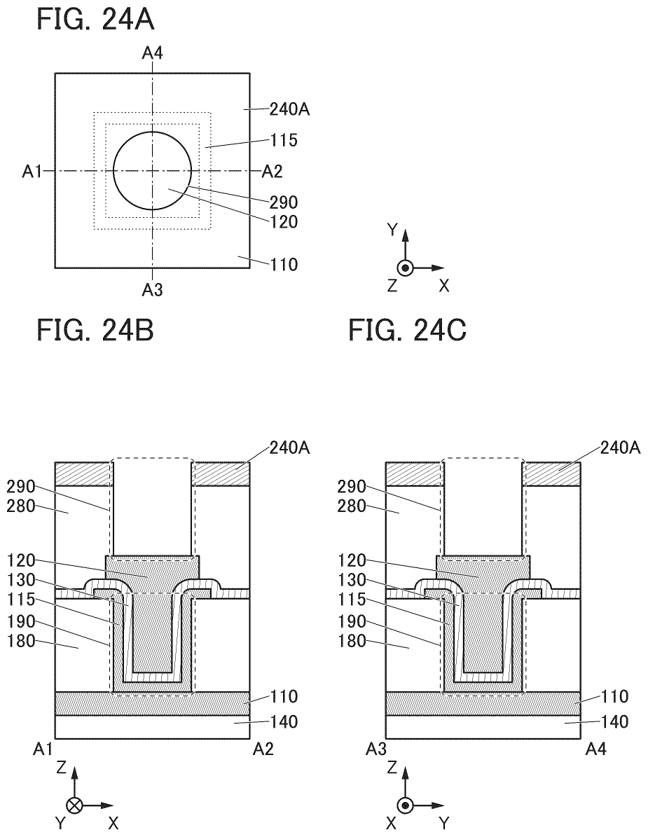

Next, part of the conductive film 240A and part of the insulator 280 are processed to form the opening portion 290 reaching the conductor 120 (see FIG. 24A to FIG. 24C). The opening portion 290 can be formed by a lithography method. Note that the opening portion 290 in FIG. 24A has a circular shape in the plan view; however, the shape is not limited to the circular shape. For example, the opening portion 290 in the plan view may have an almost circular shape such as an elliptical shape, a polygonal shape such as a quadrangular shape, or a polygonal shape such as a quadrangular shape with rounded corners.

The opening portion 290 is preferably formed using <Formation method of opening portion> described in the above section. Accordingly, miniaturization or high integration of the memory device can be achieved.

As described above, the sidewall of the opening portion 290 is preferably perpendicular to the top surface of the conductor 110. With such a structure, the memory device can be more miniaturized or highly integrated. The sidewall of the opening portion 290 may be tapered. When the sidewall of the opening portion 290 has a tapered shape, the coverage with an oxide semiconductor film to be the oxide semiconductor 230 described later and the like can be improved, so that defects such as voids can be reduced.

The maximum width of the opening portion 290 (the maximum diameter in the case where the opening portion 290 is circular in the plan view) is preferably small. For example, the maximum width of the opening portion 290 is preferably less than or equal to 60 nm, less than or equal to 50 nm, less than or equal to 40 nm, less than or equal to 30 nm, or less than or equal to 20 nm and greater than or equal to 1 nm or greater than or equal to 5 nm.

Since the opening portion 290 has a high aspect ratio, part of the conductive film 240A and part of the insulator 280 are preferably processed by anisotropic etching. Processing by a dry etching method is particularly preferable because it is suitable for microfabrication. The processing may be performed under different conditions depending on layers. Note that as described above, the inclination of the side surface of the conductor 240 in the opening portion 290 may be different from the inclination of the side surface of the insulator 280 in the opening portion 290 depending on the conditions for processing the part of the conductive film 240A and the part of the insulator 280.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at 10 ppm or more, 1% or more, or 10% or more in order to compensate for released oxygen. By the above-described heat treatment, impurities such as water contained in the insulator 280, for example, can be reduced before an oxide semiconductor film to be the oxide semiconductor 230 described later is deposited.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Next, an oxide semiconductor film to be the oxide semiconductor 230 is formed in contact with at least part of the bottom and sidewall of the opening portion 290 and at least part of the top surface of the conductive film 240A. For the oxide semiconductor film, any of the above-described metal oxides that can be used for the oxide semiconductor 230 can be appropriately used. The oxide semiconductor film can be deposited by a sputtering method, a CVD method, an MBE method, a PLD method, an ALD method, or the like. Here, the oxide semiconductor film is preferably formed in contact with the bottom portion and sidewall of the opening portion 290 with a high aspect ratio. Thus, the oxide semiconductor film is preferably formed by a deposition method with favorable coverage, and is preferably deposited by a CVD method, an ALD method, or the like. For example, an In—Ga—Zn oxide may be deposited by an ALD method as the oxide semiconductor film.

Note that in the case where the sidewall of the opening portion 290 has a tapered shape, the method for depositing the oxide semiconductor film to be the oxide semiconductor 230 is not limited to a CVD method or an ALD method. For example, a sputtering method may be employed.

In the case where the oxide semiconductor 230 has a stacked-layer structure as illustrated in FIG. 14A and FIG. 14B, the layers included in the oxide semiconductor 230 may be formed by the same method or different methods. For example, in the case where the oxide semiconductor 230 has a stacked-layer structure of two layers, the lower oxide semiconductor film may be deposited by a sputtering method and the upper oxide semiconductor film may be deposited by an ALD method. An oxide semiconductor film deposited by a sputtering method is likely to have crystallinity. Thus, when an oxide semiconductor film having crystallinity is provided as the lower oxide semiconductor film, the crystallinity of the upper oxide semiconductor film can be increased. Thus, even when a pinhole, disconnection, or the like is generated in the lower oxide semiconductor film deposited by a sputtering method, a portion overlapping with such a defect can be filled with the upper oxide semiconductor film with excellent coverage achieved by an ALD method.

Here, the oxide semiconductor film to be the oxide semiconductor 230 is preferably formed in contact with the top surface of the conductor 120 in the opening portion 290, the side surface of the insulator 280 in the opening portion 290, the side surface of the conductor 240 in the opening portion 290, and the top surface of the conductor 240. When the oxide semiconductor film is formed in contact with the conductor 120, the conductor 120 functions as one of a source electrode and a drain electrode of the transistor 200. When the oxide semiconductor film is formed in contact with the conductor 240, the conductor 240 functions as the other of the source electrode and the drain electrode of the transistor 200.

Next, heat treatment is preferably performed. The heat treatment can be performed in a temperature range where the oxide semiconductor film does not become polycrystals, i.e., at higher than or equal to 250° C. and lower than or equal to 650° C., preferably higher than or equal to 400° C. and lower than or equal to 600° C. For the details of the heat treatment, the above description can be referred to.

Here, the above-described heat treatment is preferably performed in the state where the insulator 280 containing excess oxygen is in contact with the oxide semiconductor film. By the heat treatment performed in that manner, oxygen is supplied from the insulator 280 to the channel formation region of the oxide semiconductor 230, whereby oxygen vacancies and VoH can be reduced.

Although the heat treatment is performed after the oxide semiconductor film is formed in the above, the present invention is not limited thereto. Heat treatment may be further performed in a later step.

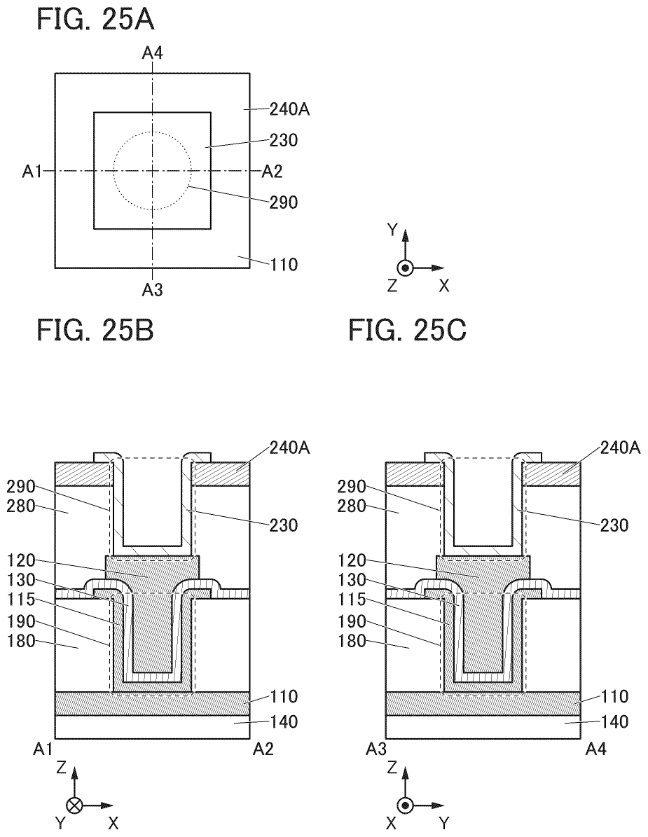

Next, the oxide semiconductor film to be the oxide semiconductor 230 is processed by a lithography method, so that the oxide semiconductor 230 is formed (FIG. 25A to FIG. 25C). Accordingly, part of the oxide semiconductor 230 is formed in the opening portion 290. The oxide semiconductor 230 is in contact with the side surface and part of the top surface of the conductor 240. Thus, the area of a region where the conductor 240 is in contact with the oxide semiconductor 230 can be increased.

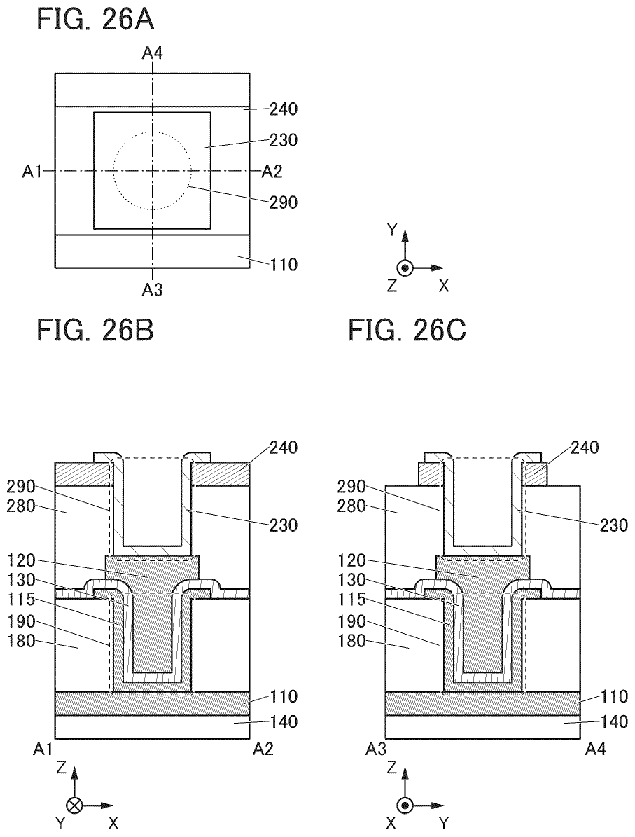

Next, the conductive film 240A is processed to form conductors 240 (see FIG. 26A to FIG. 26C). The conductor 240 can be formed by a lithography method. For the processing of the conductive film 240A, a dry etching method or a wet etching method can be employed. Processing by a dry etching method is suitable for microfabrication.

Here, a method that is different from the above-described method in formation of the conductor 240 and the oxide semiconductor 230 is described.

The steps up to the formation of the conductive film 240A illustrated in FIG. 23A to FIG. 23C are performed in a manner similar to the above method.

Next, the conductive film 240A is processed to form the conductor 240. The above description can be referred to for a method for forming the conductor 240, for example.

Next, part of the conductor 240 and part of the insulator 280 are processed to form the opening portion 290 reaching the conductor 120. The above description can be referred to for the method for forming the opening portion 290 or the like.

Next, heat treatment may be performed. The above description can be referred to for conditions of the heat treatment or the like.

Next, an oxide semiconductor film to be the oxide semiconductor 230 is deposited in contact with the bottom and sidewall of the opening portion 290 and at least part of the top surface of the conductor 240. In that case, the oxide semiconductor film includes a region in contact with the top surface of the insulator 280. The above description can be referred to for the method for forming the oxide semiconductor film or the like.

Next, heat treatment is preferably performed. The above description can be referred to for conditions of the heat treatment or the like.

Next, the oxide semiconductor film to be the oxide semiconductor 230 is processed by a lithography method, so that the oxide semiconductor 230 is formed (FIG. 26A to FIG. 26C).

The following steps for manufacturing the memory device are common in both of the methods.

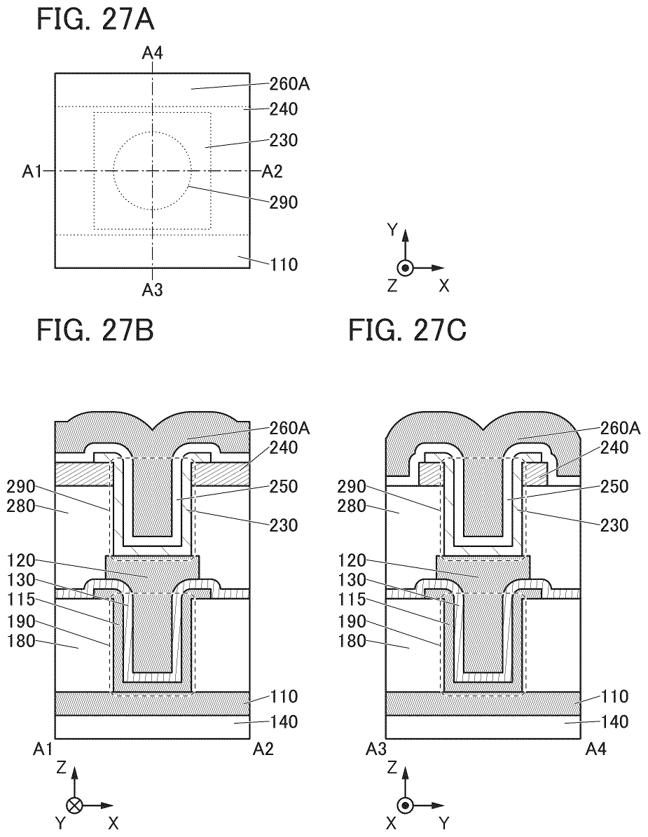

Next, the insulator 250 is formed over the oxide semiconductor 230, the conductor 240, and the insulator 280 (FIG. 27A to FIG. 27C). Any of the above-described insulating materials can be appropriately used for the insulator 250. The insulator 250 can be formed by a sputtering method, a CVD method, an MBE method, a PLD method, an ALD method, or the like. The insulator 250 is preferably formed in contact with the oxide semiconductor 230 that is provided inside the opening portion 290 having a high aspect ratio. Thus, the insulator 250 is preferably formed by a deposition method providing favorable coverage, and is further preferably formed by a CVD method, an ALD method, or the like. For example, silicon oxide may be deposited as the insulator 250 by an ALD method.

Note that in the case where the sidewall of the opening portion 290 has a tapered shape, the method for depositing the insulator 250 is not limited to a CVD method or an ALD method. For example, a sputtering method may be employed.

When the insulator 250 is formed after the oxide semiconductor 230 is formed, the side end portion of the oxide semiconductor 230 is covered with the insulator 250. Thus, a short circuit between the oxide semiconductor 230 and the conductor 260 can be prevented. Furthermore, in the above-described structure, the side end portion of the conductor 240 is covered with the insulator 250. Thus, a short circuit between the conductor 240 and the conductor 260 can be prevented.

Next, a conductive film 260A is deposited to fill the depressed portion of the insulator 250 (FIG. 27A to FIG. 27C). Any of the above conductive materials can be used for the conductive film 260A as appropriate. The conductive film 260A can be deposited by a sputtering method, a CVD method, an MBE method, a PLD method, an ALD method, or the like as appropriate. Here, the conductive film 260A is preferably formed in contact with the insulator 250 provided inside the opening portion 290 with a high aspect ratio. Thus, the conductive film 260A is preferably formed by a deposition method providing favorable coverage or a good filling property, and is further preferably deposited by a CVD method, an ALD method, or the like. For example, titanium nitride may be deposited by a CVD method or an ALD method as the conductive film 260A.

In the case where the conductive film 260A is deposited by a CVD method, the average surface roughness of the top surface of the conductive film 260A is sometimes large. In this case, the conductive film 260A is preferably planarized by a CMP method. At this time, before the CMP treatment, a silicon oxide film or a silicon oxynitride film may be formed over the conductive film 260A and the CMP treatment may be performed until the silicon oxide film or the silicon oxynitride film is removed.

Although the conductive film 260A is provided to fill the opening portion 290 in the above description, the present invention is not limited thereto. For example, the depressed portion reflecting the shape of the opening portion 290 is formed in a center portion of the conductive film 260A in some cases. The depressed portion may be filled with an inorganic insulating material or the like.

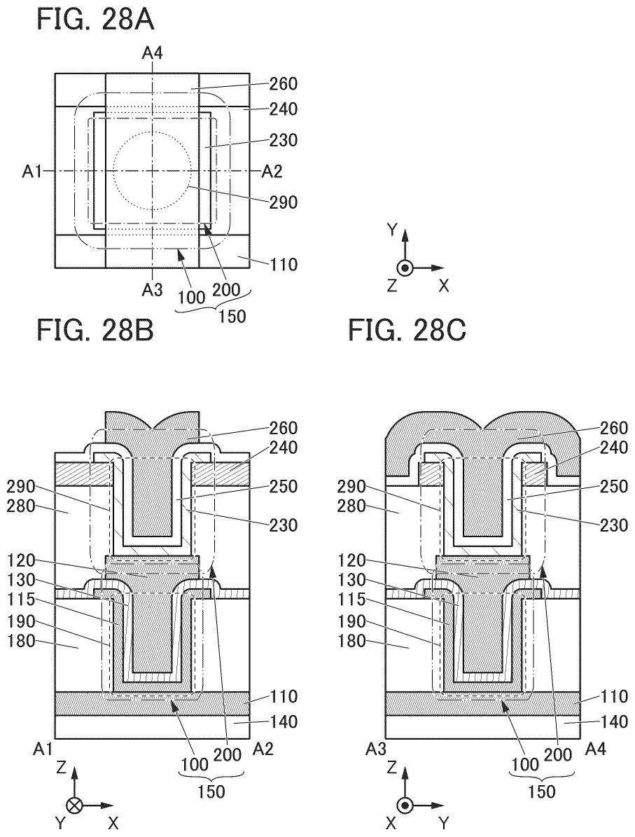

Next, the conductive film 260A is processed to form conductors 260 (see FIG. 28A to FIG. 28C). The conductor 260 can be formed by a lithography method. A dry etching method or a wet etching method can be used for the processing. Processing by a dry etching method is suitable for microfabrication.

Here, as illustrated in FIG. 7A, and FIG. 7B, the side end portion of the conductor 260 is preferably positioned inward from the side end portion of the oxide semiconductor 230 in the plan view. This can prevent a short circuit between the conductor 260 and the oxide semiconductor 230.

In the above manner, the transistor 200 including the conductor 120, the conductor 240, the oxide semiconductor 230, the insulator 250, and the conductor 260 can be formed.

Next, the insulator 283 is deposited to cover the conductor 260 and the insulator 250. Any of the above-described insulating materials can be appropriately used for the insulator 283. The insulator 283 can be deposited by a sputtering method, a CVD method, an MBE method, a PLD method, an ALD method, or the like as appropriate.

Through the above process, the memory device including the memory cell 150 illustrated in FIG. 7A to FIG. 7D can be manufactured. Through the above process, the memory device including the transistor 200 and the capacitor 100 illustrated in FIG. 7A to FIG. 7D can be manufactured.

### Manufacturing Method Example 2 for Memory Device

Next, a method for manufacturing the memory device of one embodiment of the present invention illustrated in FIG. 17A to FIG. 17C is described. For the steps up to the formation of the insulator 280, the description of <Manufacturing method example 1 for memory device> in the above section can be referred to.

Next, the insulator 281 is formed over the insulator 280. Any of the above-described insulating materials can be appropriately used for the insulator 281. The insulator 281 can be deposited by a sputtering method, a CVD method, an MBE method, a PLD method, an ALD method, or the like as appropriate. A silicon oxide film can be deposited by a sputtering method as the insulator 281, for example. The top surface of the deposited insulator 281 is preferably planarized by CMP treatment.

Then, an opening is formed in the insulator 281 to reach the insulator 280. Since the conductor 240 functioning as a wiring is formed in the opening, the opening is preferably provided to extend in the X direction. The opening can be formed by a lithography method. A dry etching method or a wet etching method can be used for the etching of the opening. Processing by a dry etching method is suitable for microfabrication.

Note that the insulator 280 may have a stacked-layer structure, and an insulator functioning as an etching stopper film may be provided on the uppermost surface of the insulator 280. The insulator corresponds to the insulator 280c in the structure illustrated in FIG. 15. For example, in the case where silicon oxide or silicon oxynitride is used for the insulator 281 in which the opening is to be formed, silicon nitride, aluminum oxide, hafnium oxide, or the like is preferably used as the etching stopper film.

Next, a conductive film to be the conductor 240 is formed to fill the opening in the insulator 281. Any of the above conductive materials can be used for the conductive film as appropriate. The conductive film can be deposited by a sputtering method, a CVD method, an MBE method, a PLD method, an ALD method, or the like. For example, a stacked film in which tantalum nitride and tungsten are deposited in this order by a sputtering method may be formed as the conductive film.

Next, part of the conductive film to be the conductor 240 over the insulator 281 is removed, and the conductor 240 is formed in the opening of the insulator 281. For the formation of the conductor 240, the conductive film may be subjected to CMP treatment until the top surface of the insulator 281 is exposed.

Note that for the steps after the formation of the conductor 240 (after the step of forming the opening portion 290), the above description of <Manufacturing method example 1 for memory device> in the above section can be referred to.

Through the above process, the memory device including the memory cell 150 illustrated in FIG. 17A to FIG. 17C can be manufactured. Through the above process, the memory device including the transistor 200 and the capacitor 100 illustrated in FIG. 17A to FIG. 17C can be manufactured.

With one embodiment of the present invention, a novel transistor, a novel semiconductor device, and a novel memory device can be provided. A memory device that can be miniaturized or highly integrated can be provided. A memory device with favorable frequency characteristics can be provided. A memory device with a high operation speed can be provided. A memory device having favorable reliability can be provided. A memory device with low power consumption can be provided. A transistor with high on-state current can be provided. A memory device with a small variation in transistor characteristics can be provided. A memory device having favorable electrical characteristics can be provided.

### Structure Example 2 of Memory Device

The memory cell 150 including the transistor 200 and the capacitor 100 described in this embodiment can be used as a memory cell of the memory device. The transistor 200 is a transistor in which a channel is formed in a semiconductor layer including an oxide semiconductor. Since the transistor 200 has a low off-state current, a memory device that uses the transistor 200 can retain stored contents for a long time. In other words, such a memory device does not require refresh operation or has extremely low frequency of the refresh operation, which leads to a sufficient reduction in power consumption of the memory device. The transistor 200 also has high frequency characteristics and thus enables high-speed reading and writing of the memory device.

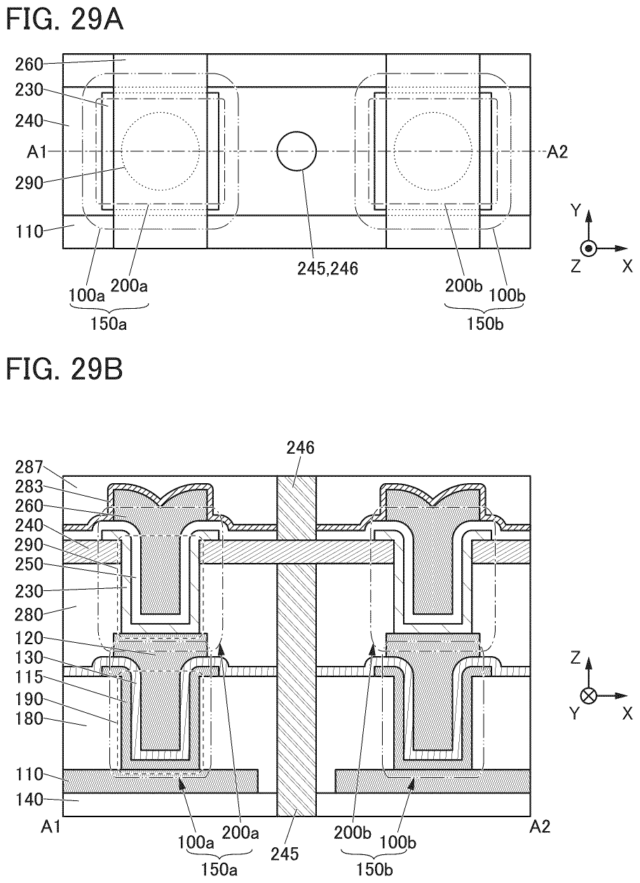

An example of a memory device in which two memory cells 150 (hereinafter referred to as a memory cell 150a and a memory cell 150b) are connected to a common wiring is described with reference to FIG. 29A and FIG. 29B. FIG. 29A is a plan view of the memory device. FIG. 29B is a cross-sectional view of a portion indicated by the dashed-dotted line A1-A2 in FIG. 29A. Note that for clarity of the drawing, some components are omitted in the plan view of FIG. 29A.

Here, the memory cell 150a and the memory cell 150b illustrated in FIG. 29A and FIG. 29B each have a structure similar to that of the memory cell 150. The memory cell 150a includes a capacitor 100a and a transistor 200a, and the memory cell 150b includes a capacitor 100b and a transistor 200b. Thus, in the memory device illustrated in FIG. 29A and FIG. 29B, components having the same functions as the components of the memory device illustrated in FIG. 7 are denoted by the same reference numerals. Note that the materials described in detail in <Structure example of memory device>can be used as component materials of the memory devices also in this section.

As illustrated in FIG. 29A and FIG. 29B, the conductor 260 functioning as the wiring WL is provided in each of the memory cell 150a and the memory cell 150b. The conductor 240 functioning as part of the wiring BL is provided in common to the memory cell 150a and the memory cell 150b. That is, the conductor 240 is in contact with the oxide semiconductor 230 of the memory cell 150a and the oxide semiconductor 230 of the memory cell 150b.

Here, the memory device illustrated in FIG. 29A and FIG. 29B includes a conductor 245 and a conductor 246 functioning as plugs (also can be referred to as connection electrodes) electrically connected to the memory cell 150a and the memory cell 150b. The conductor 245 is positioned in an opening formed in the insulator 180, the insulator 280, and the insulator 140 and is in contact with the bottom surface of the conductor 240. The conductor 246 is placed in an opening formed in an insulator 287, the insulator 283, and the insulator 250, and is in contact with the top surface of the conductor 240. Note that a conductive material or the like that can be used for the conductor 240 can be used for the conductor 245 and the conductor 246.

The insulator 287 functions as an interlayer film and thus preferably has a low dielectric constant. When a material with a low dielectric constant is used for an interlayer film, parasitic capacitance generated between wirings can be reduced. As the insulator 287, a single layer or stacked layers of an insulator containing any of the materials with low dielectric constants described in the section [Insulator] above can be used.

The concentration of impurities such as water and hydrogen in the insulator 287 is preferably reduced. This can inhibit entry of impurities such as water and hydrogen into the channel formation region of the oxide semiconductor 230.

Here, the conductor 245 and the conductor 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductor 245 can be electrically connected to a sense amplifier (not illustrated) provided below the memory device illustrated in FIG. 29, and the conductor 246 can be electrically connected to a similar memory device (not illustrated) provided above the memory device illustrated in FIG. 29. In this case, the conductor 245 and the conductor 246 function as part of the wiring BL. When the memory device or the like is provided above or below the memory device illustrated in FIG. 29 in this manner, the memory capacity per unit area can be increased.

The memory cell 150a and the memory cell 150b have a line-symmetric structure with a perpendicular bisector of the dashed-dotted line A1-A2 as the symmetric axis. Thus, the transistor 200a and the transistor 200b are also placed line-symmetrically with the conductor 245 and the conductor 246 therebetween. Here, the conductor 240 has a function of the other of a source electrode and a drain electrode of the transistor 200a and a function of the other of a source electrode and a drain electrode of the transistor 200b. The transistor 200a and the transistor 200b share the conductor 245 and the conductor 246 functioning as plugs. Accordingly, when the two transistors and the plug are connected as described above, and a memory device that can be miniaturized or highly integrated can be provided.

Note that the conductor 110 functioning as the wiring PL may be provided in each of the memory cell 150a and the memory cell 150b or may be provided in common to the memory cell 150a and the memory cell 150b. However, as illustrated in FIG. 29B, the conductor 110 is provided to be apart from the conductor 245 so that the conductor 110 and the conductor 245 are not short-circuited.

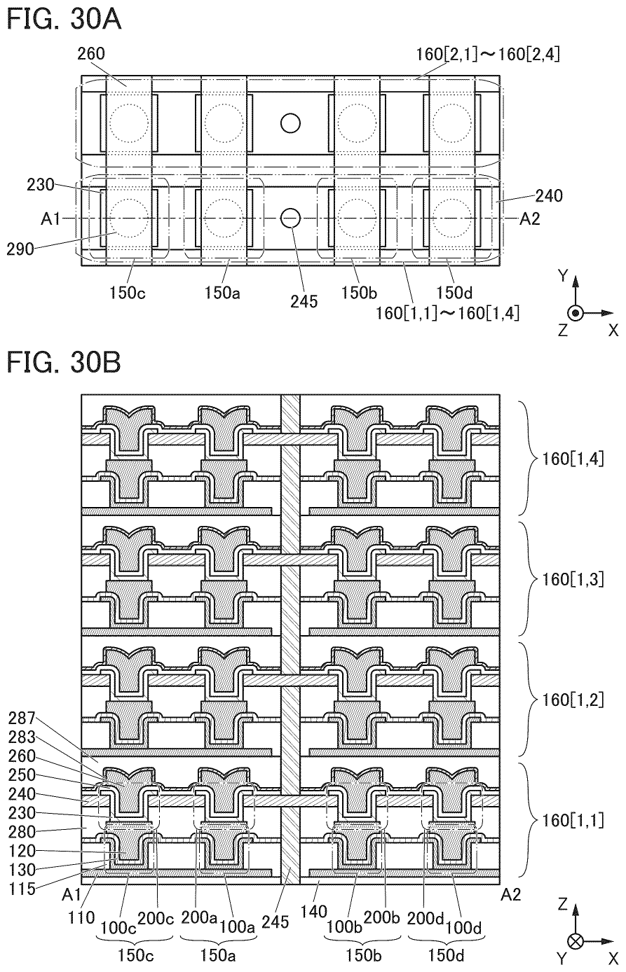

Note that a plurality of memory cells 150 can be three-dimensionally arranged in a matrix to form a memory cell array. As an example of the memory cell array, FIG. 30A and FIG. 30B illustrate an example of a memory device in which 4×2×2 memory cells 150 are arranged in the X direction, the Y direction, and the Z direction. FIG. 30A is a plan view of the memory device. FIG. 30B is a cross-sectional view of a portion indicated by the dashed-dotted line A1-A2 in FIG. 30A. Note that for clarity of the drawing, some components are not illustrated in the plan view of FIG. 30A.

Here, the memory cell 150a to a memory cell 150d illustrated in FIG. 30A and FIG. 30B each have a structure similar to that of the memory cell 150. The memory cell 150a includes the capacitor 100a and the transistor 200a, the memory cell 150b includes the capacitor 100b and the transistor 200b, a memory cell 150c includes a capacitor 100c and a transistor 200c, and the memory cell 150d includes a capacitor 100d and a transistor 200d. Thus, in the memory device illustrated in FIG. 30A and FIG. 30B, components having the same functions as the components of the memory device illustrated in FIG. 7 are denoted by the same reference numerals. Note that the materials described in detail in the section <Structure example of memory device> can be used as component materials of the memory devices also in this section.

Hereinafter, a memory device including the memory cell 150a to the memory cell 150d is referred to as a memory unit. The memory device illustrated in FIG. 30A and FIG. 30B each include a memory unit 160[1,1] to a memory unit 160[2,4]. Hereinafter, the memory unit 160[1,1] to the memory unit 160[2,4] are collectively referred to as a memory unit 160 in some cases. A memory unit 160[1,2] is provided over the memory unit 160[1,1], the memory unit 160[1,3] is provided over the memory unit 160[1,2], and the memory unit 160[1,4] is provided over the memory unit 160[1,3]. A memory unit 160[2,1] is provided adjacent to the memory unit 160[1,1] in the Y direction. A memory unit 160[2,2] is provided over the memory unit 160[2,1], a memory unit 160[2,3] is provided over the memory unit 160[2,2], and a memory unit 160[2,4] is provided over the memory unit 160[2,3].

In the memory unit 160, as illustrated in FIG. 30B, with the conductor 245 as the center the memory cell 150c is placed outwardly from the memory cell 150a, and the memory cell 150d is placed outwardly from the memory cell 150b. In other words, the memory unit 160 can be regarded as a memory device in which the memory cell 150c is provided adjacent to the memory cell 150a and the memory cell 150d is provided adjacent to the memory cell 150b in the memory device illustrated in FIG. 29.

As illustrated in FIG. 30A and FIG. 30B, the conductor 260 functioning as the wiring WL is shared by the memory cells 150 adjacent to each other in the Y direction. The conductor 240 functioning as part of the wiring BL is shared in the same memory unit. That is, the conductor 240 is in contact with the oxide semiconductor 230 of each of the memory cell 150a to the memory cell 150d.

The conductor 245 is provided between the conductors 240 included in the memory units adjacent to each other in the Z-axis direction. For example, as illustrated in FIG. 30B, the conductor 245 is provided in contact with the top surface of the conductor 240 of the memory unit 160[1,1] and the bottom surface of the conductor 240 of the memory unit 160[1,2]. In this manner, the conductor 240 and the conductor 245 provided in the memory units 160 form the wiring BL. The conductor 245 is electrically connected to a sense amplifier (not illustrated) provided below the memory device illustrated in FIG. 30. As described above, when a plurality of memory units are stacked in the memory device illustrated in FIG. 30, the memory capacity per unit area can be increased.

The memory cell 150a and the memory cell 150c are line-symmetrical to the memory cell 150b and the memory cell 150d with a perpendicular bisector of the dashed-dotted line Al-A2 as the symmetric axis. Thus, the transistor 200a and the transistor 200c are also arranged line-symmetrically to the transistor 200b and the transistor 200d with the conductor 245 therebetween. Here, the conductor 240 has a function of the other of the source electrode and the drain electrode of each of the transistor 200a to the transistor 200d. The transistor 200a to the transistor 200d share the conductor 245 functioning as a plug. Accordingly, when the four transistors are connected to the plug as described above, a memory device that can be miniaturized or highly integrated can be provided.

When a plurality of memory cells are stacked as illustrated in FIG. 30, cells can be integrally placed without increasing the footprint of the memory cell arrays. In other words, a 3D memory cell array can be formed. Although the structure is FIG. 30 shows that four layers each including two memory units are stacked, the present invention is not limited thereto. The memory device may include one layer including at least one memory cell 150, or two or more stacked layers.

In the structure of FIG. 30, the conductor 245 functioning as a plug is placed between the memory cells 150. In other words, the conductor 245 functioning as a plug is placed inside the memory unit 160. Note that the present invention is not limited thereto. The conductor 245 may be placed outside the memory unit.

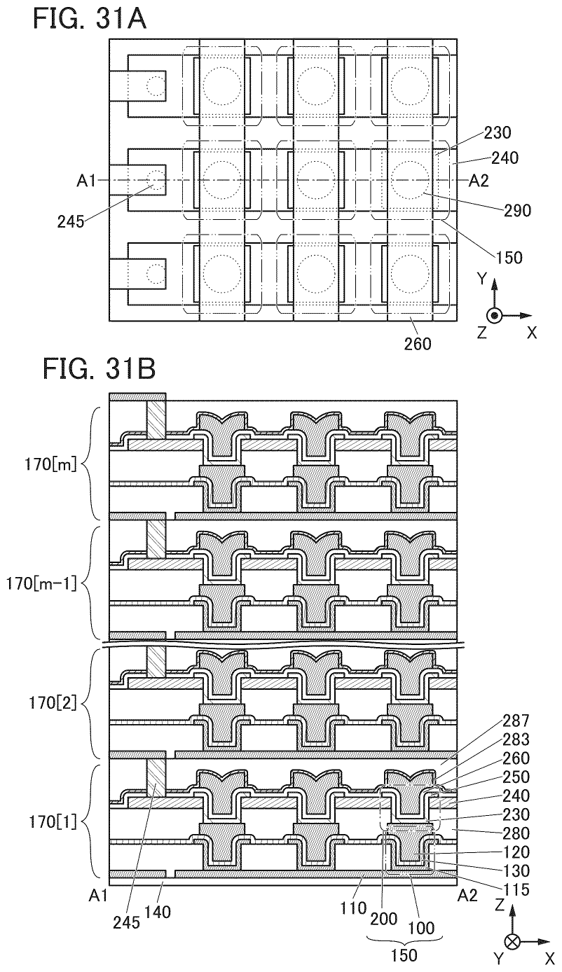

As an example of the memory cell array, FIG. 31A and FIG. 31B illustrate an example of a memory device in which 3×3×4 memory cells 150 are arranged in the X direction, the Y direction, and the Z direction. FIG. 31A is a plan view of the memory device. FIG. 31B is a cross-sectional view of a portion indicated by the dashed-dotted line A1-A2 in FIG. 31A. Note that for clarity of the drawing, some components are omitted in the top view of FIG. 31A.

In the memory device illustrated in FIG. 31A and FIG. 31B, m (m is an integer greater than or equal to 2) layers each including the memory cell 150 are stacked. Here, in FIG. 31B, the layers provided in the first layer (the lowermost layer), the second layer, the (m−1)-th layer, and the m-th layer (the uppermost layer) are denoted, respectively, as a layer 170[1], a layer 170[2], a layer 170[m−1], and a layer 170[m]. In other words, the memory device of one embodiment of the present invention may include a plurality of layers each including the memory cell 150 and have a structure in which the plurality of layers are stacked.

As illustrated in FIG. 31A and FIG. 31B, the conductor 245 may be provided outside the memory unit. The conductor 245 may be electrically connected to a wiring provided over the layer including the conductor 245. For example, the conductor 245 provided in the layer 170[1] is electrically connected to a wiring provided in the layer 170[2]. Note that the wiring provided in the layer 170[2] is provided in the same layer as the lower electrode (the conductor 110) of the memory cell 150 included in the layer 170[2]. That is, the wiring can be formed in the same step as the conductor 110.

Although FIG. 31 illustrates the structure in which the conductor 245 is electrically connected to a wiring provided over the layer including the conductor 245, the present invention is not limited thereto. For example, the conductor 245 may be electrically connected to a wiring provided in a layer including the conductor 245. For example, the conductor 245 provided in the layer 170[1] may be electrically connected to a wiring provided in the layer 170[1]. Note that the wiring provided in the layer 170[1] is provided in the same layer as the lower electrode (the conductor 110) of the memory cell 150 included in the layer 170[1]. That is, the wiring can be formed in the same step as the conductor 110.

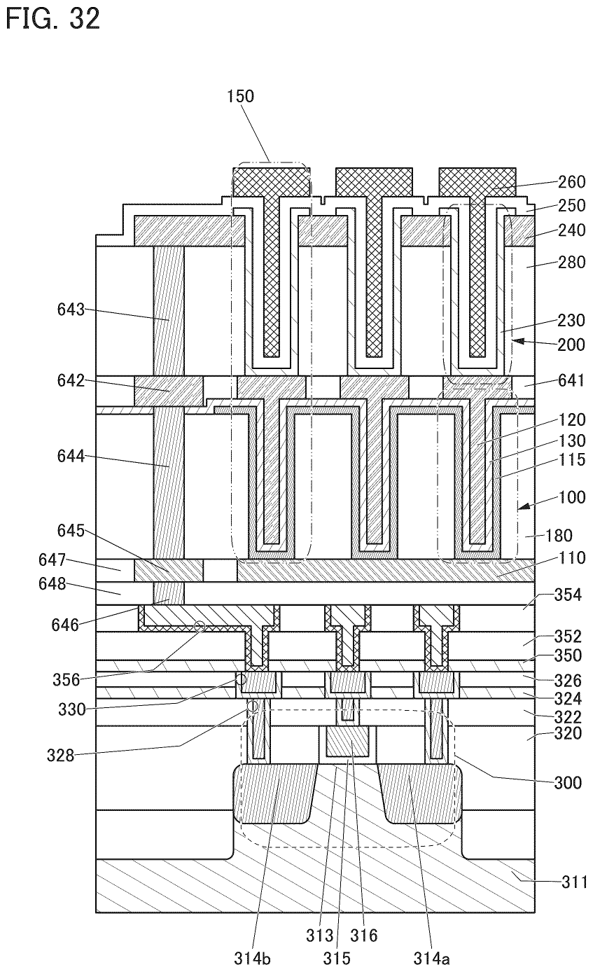

FIG. 32 illustrates a cross-sectional structure example of a memory device where a layer including a memory cell is stacked over a layer including a driver circuit provided with a sense amplifier.

In the memory device illustrated in FIG. 32, the capacitor 100 is provided above a transistor 300, and the transistor 200 is provided above the transistor 300 and the capacitor 100.

The transistor 300 is one of the transistors included in the sense amplifier.

The structure of the memory cells 150 (the transistor 200 and the capacitor 100) illustrated in FIG. 32 is as described above.

When the sense amplifier is provided to overlap with the memory cell 150 as illustrated in FIG. 32, the bit line can be shortened. This reduces bit line capacitance, which can reduce the storage capacitance of the memory cell.

When the transistor 200 is provided above the capacitor 100, the transistor 200 is not affected by thermal budget in fabricating the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

The memory device illustrated in FIG. 32 can correspond to a memory device 80 described in Embodiment 2. Specifically, the transistor 300 corresponds to a transistor included in a sense amplifier 46 in the memory device 80. The memory cell 150 corresponds to a memory cell 32, the transistor 200 corresponds to a transistor 37, and the capacitor 100 corresponds to a capacitor 38.

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 32, the semiconductor region 313 (part of the substrate 311) where a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. Such a transistor 300 is also referred to as a FIN-type transistor because it utilizes the protruding portion of the semiconductor substrate. Note that an insulator functioning as a mask for forming the protruding portion may be included in contact with an upper portion of the protruding portion. Although the case where the protruding portion is formed by processing part of the semiconductor substrate is described here, a semiconductor film having a protruding shape may be formed by processing an SOI substrate.

Note that the transistor 300 illustrated in FIG. 32 is an example and the structure is not limited thereto; an appropriate transistor can be used in accordance with a circuit configuration or a driving method.

A wiring layer provided with an interlayer film, a wiring, a plug, and the like may be provided between the components. A plurality of wiring layers can be provided in accordance with design. Here, a plurality of conductors functioning as a plug or a wiring are collectively denoted by the same reference numeral in some cases. In this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 is embedded in the insulator 320 and the insulator 322, and a conductor 330 is embedded in the insulator 324 and the insulator 326. Note that the conductor 328 and the conductor 330 function as a plug or a wiring.

Insulators functioning as a interlayer film may also function as a planarization film that cover uneven shapes therebelow. For example, the top surface of the insulator 322 may be planarized through planarization treatment using a CMP method or the like to increase the level of planarity.

A wiring layer may be provided over the insulator 326 and the conductor 330. For example, in FIG. 32, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

The insulator 352, the insulator 354, and the like functioning as interlayer films can be used for the insulator applicable to the memory device.

As the conductor functioning as a plug or a wiring, such as the conductor 328, the conductor 330, and the conductor 356, any of the conductors described in the section [Conductor] above can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The conductor 240 included in the transistor 200 is electrically connected to the low-resistance region 314b functioning as the source region or the drain region of the transistor 300 through a conductor 643, a conductor 642, a conductor 644, a conductor 645, a conductor 646, the conductor 356, the conductor 330, and the conductor 328.

The conductor 643 is embedded in the insulator 280. The conductor 642 is provided over the insulator 130 and is embedded in an insulator 641. The conductor 642 and the conductor 120 can be formed using the same material in the same step. The conductor 644 is embedded in the insulator 180 and the insulator 130. The conductor 645 is embedded in an insulator 647. The conductor 645 and the conductor 110 can be formed using the same material in the same step. The conductor 646 is embedded in an insulator 648. The transistor 300 and the conductive layer 110 are electrically insulated from each other by the insulator 648.

This embodiment can be combined with any of the other embodiments as appropriate. In this specification, in the case where a plurality of structure examples are shown in one embodiment, the structure examples can be combined as appropriate.

### Embodiment 2

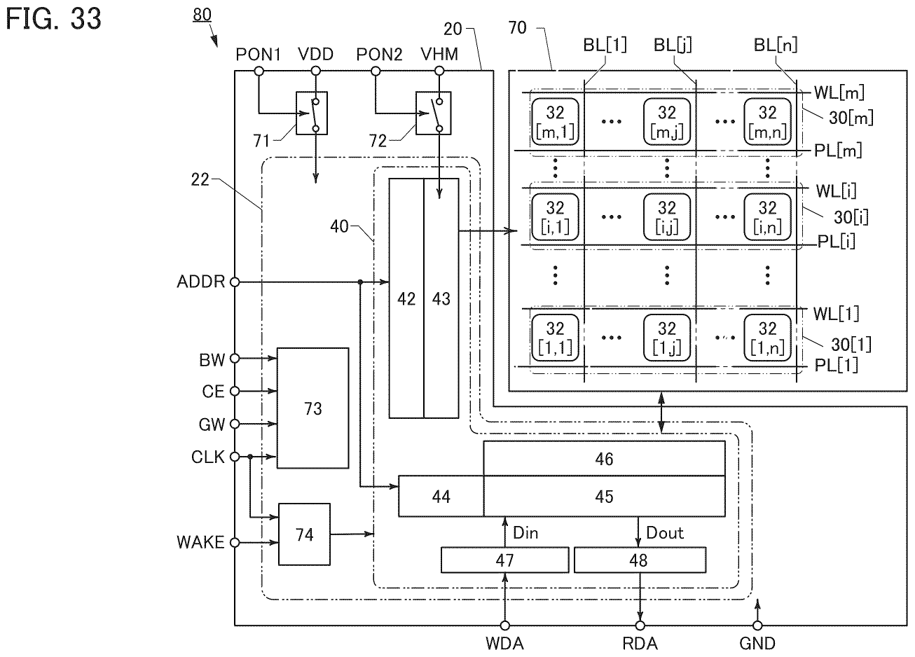

In this embodiment, a memory device of one embodiment of the present invention will be described with reference to FIG. 33 to FIG. 36. In this embodiment, a structure example of a memory device is described, in which a layer including a memory cell is stacked over a layer including a driver circuit provided with a sense amplifier.

### Structure Example 3 of Memory Device

FIG. 33 is a block diagram illustrating a structure example of the memory device 80 of one embodiment of the present invention. The memory device 80 illustrated in FIG. 33 includes a layer 20 and a layer 70 stacked over the layer 20.

The layer 20 is a layer including an Si transistor. In the layer 70, element layers 30[1] to 30[m] (m is an integer greater than or equal to 2) are provided to be stacked. The element layers 30[1] to 30[m] each include an OS transistor. The layer 70 provided with stacked layers each including an OS transistor can be stacked over the layer 20.

Elements such as the OS transistor and a capacitor included in the element layers 30[1] to 30[m] form memory cells. FIG. 33 illustrates an example in which the element layers 30[1] to 30[m] include a plurality of the memory cells 32 arranged in a matrix of m rows and n columns (each of m and n is an integer greater than or equal to 2).

In FIG. 33, the memory cell 32 in the first row and the first column is denoted as a memory cell 32[1,1], and the memory cell 32 in the m-th row and the n-th column is denoted as a memory cell 32[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 32 in the i-th row and the j-th column is denoted as a memory cell 32[i,j]. Note that in this embodiment and the like, “i+α” (a is a positive or negative integer) is not below 1 and does not exceed m. Similarly, “j+α” is not below 1 and does not exceed n.

As an example, FIG. 33 illustrates m wirings WL extending in the row direction, m wirings PL extending in the row direction, and n wirings BL extending in the column direction. In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[1] and an m-th (m-th row) wiring PL is referred to as a wiring PL[m]. Similarly, a first (first column) wiring BL is referred to as a wiring BL[1] and an n-th (n-th column) wiring BL is referred to as a wiring BL[n]. Note that the number of the element layers 30[1] to 30[m] is not necessarily the same as the number of the wirings WL (and the wirings PL).

The plurality of memory cells 32 provided in the i-th row are electrically connected to the wiring WL in the i-th row (wiring WL[i]) and the wiring PL in the i-th row (wiring PL[i]). A plurality of the memory cells 32 provided in the j-th column are electrically connected to the wiring BL in the j-th column (wiring BL[j]).

The wiring BL functions as a bit line for writing and reading data. The wiring WL functions as a word line for controlling the on and off state (conducting and non-conducting state) of the access transistor serving as a switch. The wiring PL has a function of a constant potential line connected to a capacitor. Note that a wiring CL (not illustrated) can be separately provided as a wiring for transmitting the back gate potential.

The memory cell 32 included in each of the element layers 30[1] to 30[m] is connected to the sense amplifier 46 through the wiring BL. The wiring BL can be provided in the direction horizontal and perpendicular to the surface of the substrate provided with the element layer 20. When the wiring BL provided to extend from the memory cells 32 included in the element layers 30[1] to 30[m] is formed using a wiring provided in the direction perpendicular to the substrate surface and a wiring provided in the direction horizontal to the substrate surface, the length of the wiring between the element layer 30 and the sense amplifier 46 can be shortened. The signal transmission distance between the memory cell and the sense amplifier can be shortened, and the resistance and parasitic capacitance of the bit lines can be significantly reduced, whereby power consumption and signal delays can be reduced. Thus, power consumption and signal delay of the memory device 80 can be reduced. Moreover, operation is possible even when the capacitance of the capacitors included in the memory cells 32 is reduced. Therefore, the memory device 80 can be downsized.

The layer 20 includes a power switch 71 (PSW), a power switch 72, and a peripheral circuit 22. The peripheral circuit 22 includes a driver circuit 40, a control circuit 73, and a voltage generation circuit 74. Note that each of the circuits included in the layer 20 is a circuit including a Si transistor.

In the memory device 80, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 73.

The control circuit 73 is a logic circuit having a function of controlling the entire operation of the memory device 80. For example, the control circuit performs a logical operation on the signal CE, the signal GW, and the signal BW to determine an operation mode (e.g., a writing operation or a reading operation) of the memory device 80. Alternatively, the control circuit 73 generates a control signal for the driver circuit 40 so that the operation mode is executed.

The voltage generation circuit 74 has a function of generating a negative voltage. The signal WAKE has a function of controlling the input of the signal CLK to the voltage generation circuit 74. For example, when an H-level signal is supplied as the signal WAKE, the signal CLK is input to the voltage generation circuit 74, and the voltage generation circuit 74 generates a negative voltage.

The driver circuit 40 is a circuit for writing and reading data to/from the memory cells 32. The driver circuit 40 includes a row decoder 42, a column decoder 44, a row driver 43, a column driver 45, an input circuit 47, an output circuit 48, and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 32, a function of reading data from the memory cells 32, a function of retaining the read data, and the like.

The input circuit 47 has a function of retaining the signal WDA. Data retained by the input circuit 47 is output to the column driver 45. Data output from the input circuit 47 is data (Din) to be written to the memory cells 32. Data (Dout) read from the memory cells 32 by the column driver 45 is output to the output circuit 48. The output circuit 48 has a function of retaining Dout. In addition, the output circuit 48 has a function of outputting Dout to the outside of the memory device 80. Data output from the output circuit 48 is the signal RDA.

The power switch 71 has a function of controlling the supply of VDD to the peripheral circuit 22. The power switch 72 has a function of controlling supply of VHM to the row driver 43. Here, in the memory device 80, a high power supply voltage is VDD and a low power supply voltage is GND (a ground potential). In addition, VHM is a high power supply voltage used to set a word line at a high level and is higher than VDD. The on/off state of the power switch 71 is controlled by the signal PON1, and the on/off state of the power switch 72 is controlled by the signal PON2. The number of power domains to which VDD is supplied is one in the peripheral circuit 22 in FIG. 33 but can be more than one. In this case, a power switch is provided for each power domain.

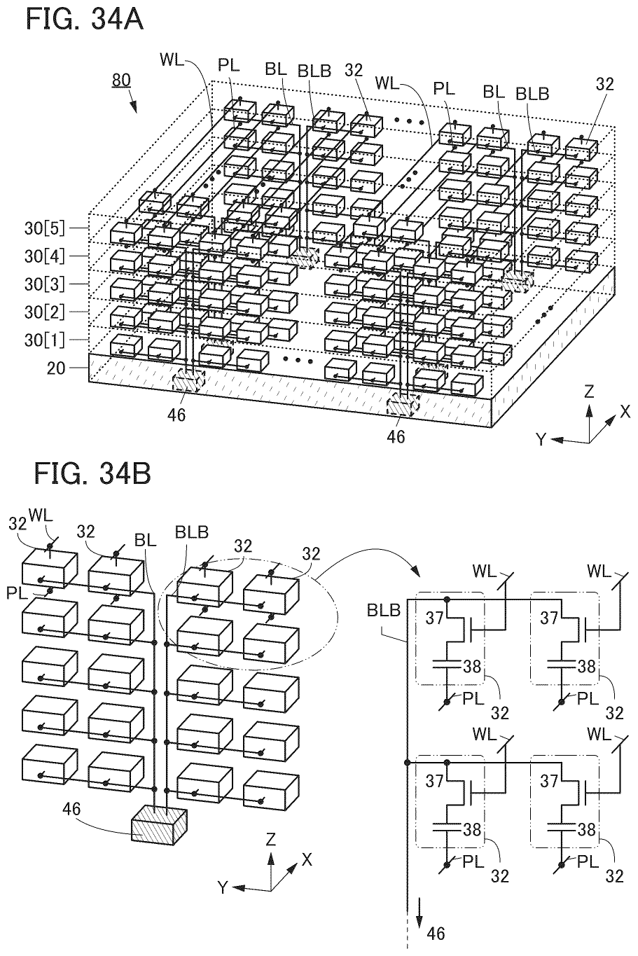

The element layers 30[1] to 30[m] can be provided over the element layer 20 to overlap with the element layer 20. FIG. 34A is a perspective view of the memory device 80 in which five element layers 30[1] to 30[5] (m=5) are provided over the element layer 20 to overlap with the element layer 20.

In FIG. 34A, the element layer 30 provided in the first layer is denoted as the element layer 30[1], the element layer 30 provided in the second layer is denoted as the element layer 30[2], and the element layer 30 provided in the fifth layer is denoted as the element layer 30[5]. FIG. 34A also illustrates the wiring WL and the wiring PL provided to extend in the X direction and the wiring BL and a wiring BLB provided to extend in the Y direction and the Z direction (the direction perpendicular to the surface of the substrate provided with the driver circuit). The wiring BLB is an inverted bit line. For easy viewing of the drawing, some of the wirings WL and the wirings PL included in the element layers 30 are not illustrated.

FIG. 34B is a schematic view for describing a structure example of the sense amplifier 46, which is connected to the wiring BL and the wiring BLB, and the memory cells 32 included in the element layers 30[1] to 30[5], which are connected to the wiring BL and the wiring BLB, illustrated in FIG. 34A. Note that a structure in which a plurality of memory cells (memory cells 32) are electrically connected to one wiring BL and one wiring BLB is also referred to as “memory string”.

FIG. 34B illustrates an example of a circuit structure of the memory cell 32 connected to the wiring BLB. The memory cell 32 includes the transistor 37 and the capacitor 38. As for the transistor 37, the capacitor 38, and the wirings (e.g., the wiring BL and the wiring WL), for example, the wiring BL[1] and the wiring WL[1] are referred to as the wiring BL and the wiring WL in some cases. The memory cell 150 exemplified in the above embodiment can be used as the memory cell 32, for example. That is, the transistor 200 can be used as the transistor 37, and the capacitor 100 can be used as the capacitor 38. As the transistor included in the sense amplifier 46, the transistor 300 (see FIG. 32) can be used.

In the memory cell 32, one of the source and the drain of the transistor 37 is connected to the wiring BL. The other of the source and the drain of the transistor 37 is connected to one electrode of the capacitor 38. The other electrode of the capacitor 38 is connected to the wiring PL. The gate of the transistor 37 is connected to the wiring WL.

The wiring PL is a wiring for supplying a fixed potential for retaining a potential of the capacitor 38. When a plurality of wirings PL are connected to each other as one wiring, the number of wirings can be reduced.

In one embodiment of the present invention, the OS transistors are provided to be stacked, and the wiring functioning as the bit line is placed in the direction perpendicular to the surface of the substrate provided with the element layer 20. In addition, the transistors 37 and the capacitors 38 included in the memory cell 32 are arranged in the direction perpendicular to the surface of the substrate provided with the layer 20. When the elements and the wirings are provided in the direction perpendicular to the surface of the substrate, the length of the wirings between the element layers can be shortened and the density of the elements provided per unit area can be increased. Thus, the memory device can have high memory capacity and low power consumption.

### Structure Example of Memory Cell 32 and Sense Amplifier 46

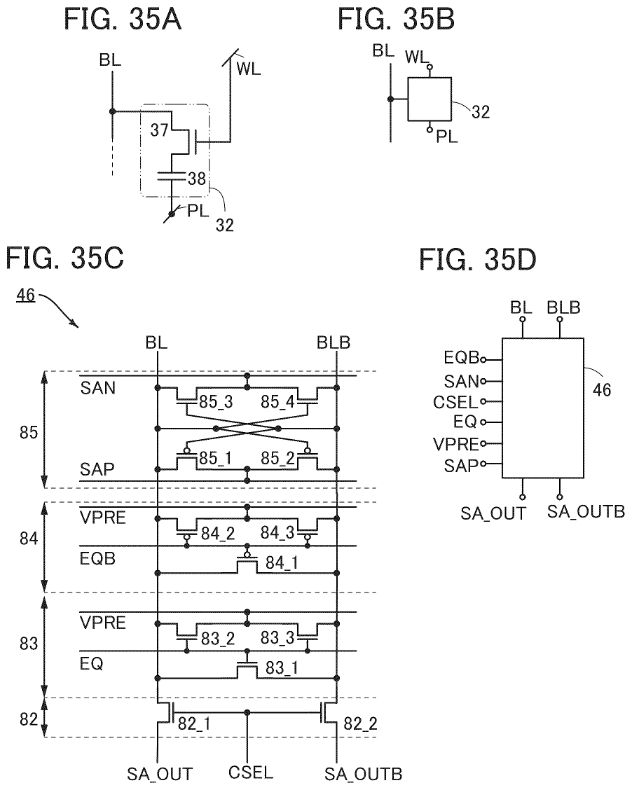

FIG. 35A and FIG. 35B show a circuit diagram corresponding to the memory cell 32 described above and a circuit block corresponding to the circuit diagram. As illustrated in FIG. 35A and FIG. 35B, the memory cell 32 is sometimes illustrated as a block in the drawing and the like. Note that the wiring BL illustrated in FIG. 35A and FIG. 35B can be replaced with the wiring BLB.

FIG. 35C and FIG. 35D are a circuit diagram corresponding to the above-described sense amplifier 46 and a diagram illustrating a circuit block corresponding to the circuit diagram. The sense amplifier 46 in the circuit diagram includes a switch circuit 82, a precharge circuit 83, a precharge circuit 84, and an amplifier circuit 85. In addition, a wiring SA_OUT and a wiring SA_OUTB that output a read signal are illustrated in addition to the wiring BL and the wiring BLB.

The switch circuit 82 includes, for example, n-channel transistors 82_1 and 82_2, as illustrated in FIG. 35C. The transistors 82_1 and 82_2 switch electrical continuity between the wiring SA_OUT and the wiring BL and between the wiring SA_OUTB and the wiring BLB in response to a signal CSEL; the wiring SA_OUT and the wiring SA_OUTB form a wiring pair and the wiring BL and the wiring BLB form a wiring pair.

The precharge circuit 83 is composed of n-channel transistors 83_1 to 83_3 as illustrated in FIG. 35C. The precharge circuit 83 is a circuit for precharging the wiring BL and the wiring BLB to an intermediate potential VPRE corresponding to half of the potential VDD in response to a signal EQ.

The precharge circuit 84 is composed of p-channel transistors 84_1 to 84_3 as illustrated in FIG. 35C. The precharge circuit 84 is a circuit for precharging the wiring BL and the wiring BLB to the intermediate potential VPRE, which corresponds to half of the potential VDD, in response to a signal EQB.

The amplifier circuit 85 is composed of p-channel transistors 85_1 and 85_2 and n-channel transistors 85_3 and 85_4 that are connected to a wiring SAP or a wiring SAN, as illustrated in FIG. 35C. The wiring SAP or the wiring SAN is a wiring having a function of supplying VDD or VSS. The transistors 85_1 to 85_4 are transistors that form an inverter loop.

FIG. 35D illustrates a circuit block corresponding to the sense amplifier 46 described with reference to FIG. 35C and the like. As illustrated in FIG. 35D, the sense amplifier 46 is expressed as a block in the drawing and the like in some cases.

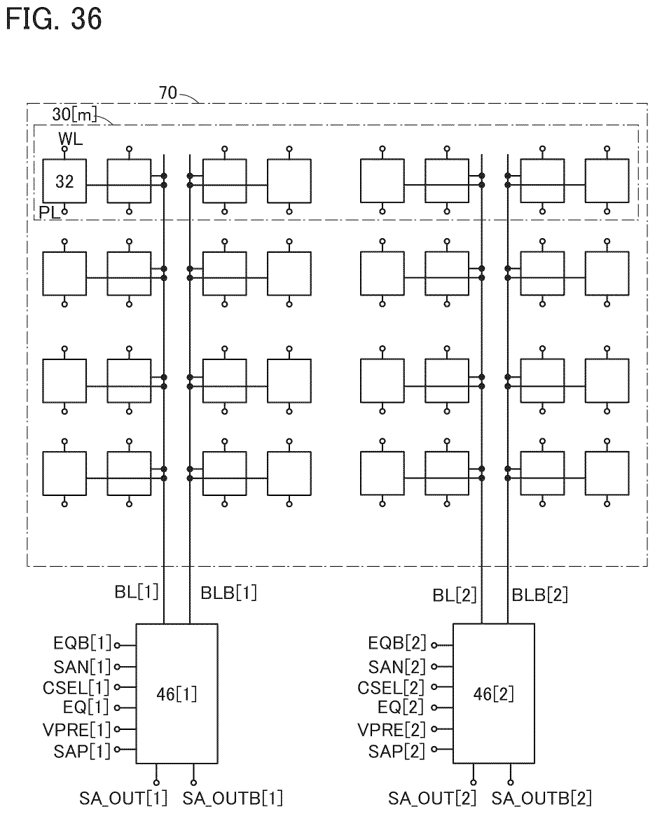

FIG. 36 is a circuit diagram of the memory device 80 in FIG. 33. In FIG. 36, the circuit block illustrated in FIG. 35A to FIG. 35D is used.

As illustrated in FIG. 36, the layer 70 including the element layer 30[m] includes the memory cells 32. The memory cell 32 illustrated in FIG. 36 is connected to a pair of wiring BL[1] and the wiring BLB[1], or a pair of wirings BL[2] and BLB[2], for example. The memory cells 32 connected to the wiring BL are memory cells to/from which data is written or read.

The wiring BL[1] and the wiring BLB[1] are connected to a sense amplifier 46[1], and the wiring BL[2] and the wiring BLB[2] are connected to a sense amplifier 46[2]. The sense amplifier 46[1] and the sense amplifier 46[2] enables reading data in accordance with various kinds of the signals described with reference to FIG. 35C.

This embodiment can be combined with the other embodiments and the examples as appropriate.

### Embodiment 3

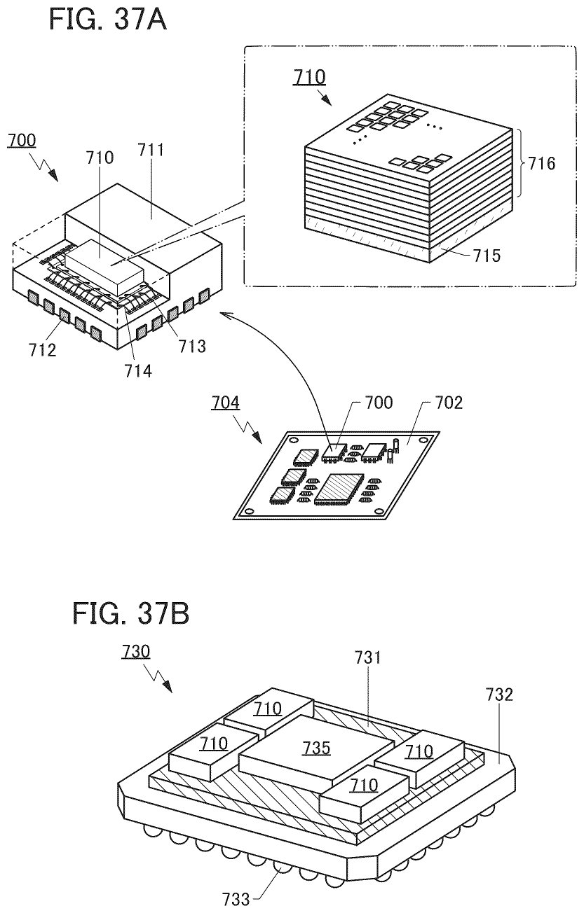

In this embodiment, application examples of the semiconductor device of one embodiment of the present invention will be described with reference to FIG. 37 to FIG. 40. The semiconductor device of one embodiment of the present invention can be used for an electronic component, an electronic device, a large computer, space equipment, and a data center (also referred to as DC), for example. An electronic component, an electronic device, a large computer, space equipment, and a data center each using the semiconductor device of one embodiment of the present invention are effective in achieving high performance, e.g., reducing power consumption.

### Electronic Component

FIG. 37A is a perspective view of a substrate (a mounting board 704) on which an electronic component 700 is mounted. The electronic component 700 illustrated in FIG. 37A includes a semiconductor device 710 in a mold 711. FIG. 37A omits part of the electronic component to illustrate the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 37B is a perspective view of an electronic component 730. The electronic component 730 is an example of a SiP (System in Package) or an MCM (Multi Chip Module). In the electronic component 730, an interposer 731 is provided over a package board 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package board 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package board 732. Accordingly, the interposer is sometimes referred to as a “redistribution substrate” or an “intermediate substrate”. A through electrode may be provided in the interposer 731 to be used for electrically connecting the integrated circuit and the package board 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

A heat sink (radiator plate) may be provided to overlap with the electronic component 730. In the case of providing a heat sink, integrated circuits provided on the interposer 731 are preferably level with each other. For example, in the electronic component 730 described in this embodiment, the heights of the semiconductor devices 710 and the semiconductor device 735 are preferably equal to each other.

An electrode 733 may be provided on the bottom portion of the package board 732 to mount the electronic component 730 on another substrate. FIG. 37B illustrates an example where the electrode 733 is formed of a solder ball. Solder balls are provided in a matrix on the bottom portion of the package board 732, whereby a BGA (Ball Grid Array) can be achieved. Alternatively, the electrode 733 may be formed of a conductive pin. When conductive pins are provided in a matrix on the bottom portion of the package board 732, a PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### Electronic Device

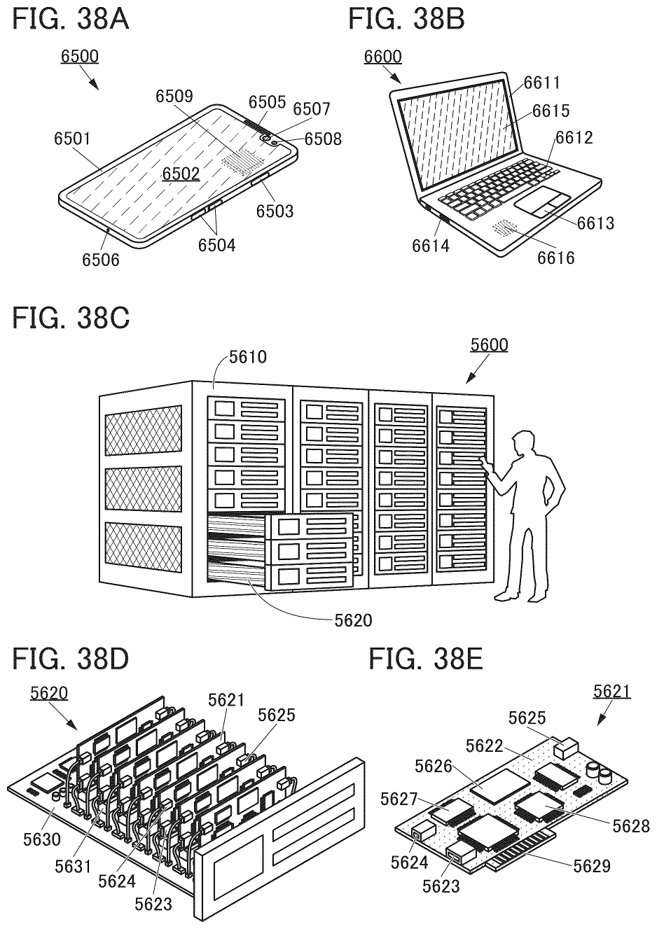

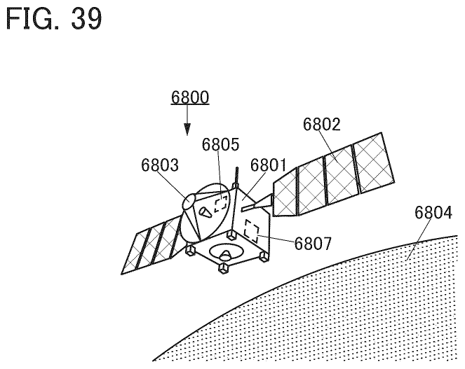

FIG. 38A is a perspective view of an electronic device 6500. The electronic device 6500 illustrated in FIG. 38A is a portable information terminal that can be used as a smartphone.
The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device of one embodiment of the present invention can be used for the display portion 6502, the control device 6509, and the like.

An electronic device 6600 illustrated in FIG. 38B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is suitably used for the control device 6509 and the control device 6616, in which case power consumption can be reduced.

### Large Computer

FIG. 38C is a perspective view of a large computer 5600. In the large computer 5600 illustrated in FIG. 38C, a plurality of rack mount computers 5620 are stored in a rack 5610. Note that the large computer 5600 may be referred to as a supercomputer.

The computer 5620 can have a structure in a perspective view of FIG. 38D, for example. In FIG. 38D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 38E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 38E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### Space Equipment

The semiconductor device of one embodiment of the present invention can be suitably used as space equipment.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, OS transistors can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of the thermosphere, mesosphere, and stratosphere.

FIG. 39 illustrates an artificial satellite 6800 as an example of space equipment. The artificial satellite 6800 includes a body 6801, a solar panel 6802, an antenna 6803, a secondary battery 6805, and a control device 6807. FIG. 39 illustrates a planet 6804 in outer space, for example.

Although not illustrated in FIG. 39, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, with a structure including a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### Data Center

The semiconductor device of one embodiment of the present invention can be suitably used for a storage system in a data center, for example. Long-term management of data, such as guarantee of data immutability, is required for the data center. The long-term data management needs an increase in building size owing to installation of storages and servers for storing an enormous amount of data, stable electric power for data retention, cooling equipment necessary for data retention, and the like.

With use of the semiconductor device of one embodiment of the present invention for the storage system used in the data center, electric power required for data retention can be reduced and a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

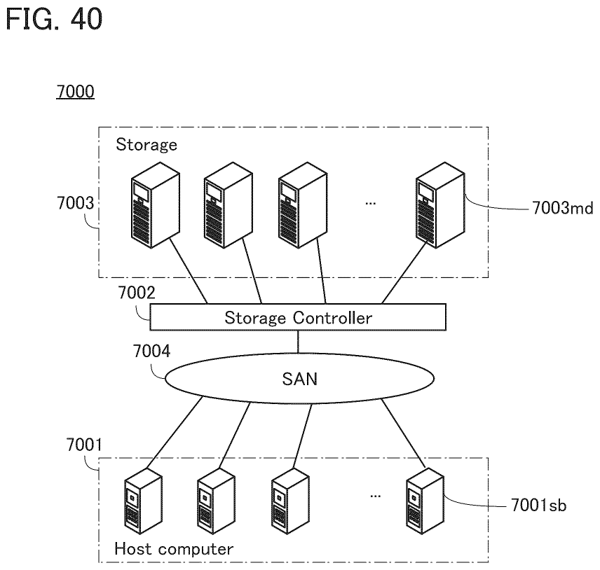

FIG. 40 illustrates a storage system applicable to a data center. A storage system 7000 illustrated in FIG. 40 includes a plurality of servers 7001sb as a host 7001 (indicated as “Host Computer” in the diagram). The storage system 7000 includes a plurality of storage devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

This embodiment can be combined with any of the other embodiments as appropriate.

### Reference Numerals

ADDR: signal, BL[1]: wiring, BL[2]: wiring, BL[j]: wiring, BL[n]: wiring, BL: wiring, BLB[1]: wiring, BLB[2]: wiring, BLB: wiring, BW: signal, CE: signal, CL: wiring, CLK: signal, CSEL: signal, EQ: signal, EQB: signal, GW: signal, PL[1]: wiring, PL[i]: wiring, PL[m]: wiring, PL: wiring, RDA: signal, SA_OUT: wiring, SA_OUTB: wiring, SAN: wiring, SAP: wiring, Tr: transistor, VPRE: intermediate potential, WAKE: signal, WDA: signal, WL[1]: wiring, WL[i]: wiring, WL[m]: wiring, WL: wiring, 20: layer, 22: peripheral circuit, 30[1]: element layer, 30[2]: element layer, 30[5]: element layer, 30[m]: element layer, 30: element layer, 32[1,1]: memory cell, 32[i,j]: memory cell, 32[m,n]: memory cell, 32: memory cell, 37: transistor, 38: capacitor, 40: driver circuit, 42: row decoder, 43: row driver, 44: column decoder, 45: column driver, 46[1]: sense amplifier, 46[2]: sense amplifier, 46: sense amplifier, 47: input circuit, 48: output circuit, 70: layer, 71: power switch, 72: power switch, 73: control circuit, 74: voltage generation circuit, 80: memory device, 82_1: transistor, 82_2: transistor, 82: switch circuit, 83_1: transistor, 83_3: transistor, 83: precharge circuit, 84_1: transistor, 84_3: transistor, 84: precharge circuit, 85_1: transistor, 85_2: transistor, 85_3: transistor, 85_4: transistor, 85: amplifier circuit, 100a: capacitor, 100b: capacitor, 100c: capacitor, 100d: capacitor, 100: capacitor, 110: conductor, 115: conductor, 120A: conductive film, 120: conductor, 125: conductor, 130: insulator, 135: insulator, 140: insulator, 150a: memory cell, 150b: memory cell, 150c: memory cell, 150d: memory cell, 150: memory cell, 160[1,1]: memory unit, 160[1,2]: memory unit, 160[1,3]: memory unit, 160[1,4]: memory unit, 160[2,1]: memory unit, 160[2,2]: memory unit, 160[2,3]: memory unit, 160[2,4]: memory unit, 160: memory unit, 170[1]: layer, 170[2]: layer, 170[m-1]: layer, 170[m]: layer, 180a: insulator, 180b: insulator, 180: insulator, 182: insulator, 185: insulator, 190: opening portion, 200a: transistor, 200b: transistor, 200c: transistor, 200d: transistor, 200: transistor, 230a: oxide semiconductor, 230b: oxide semiconductor, 230i: region, 230na: region, 230nb: region, 230: oxide semiconductor, 240A: conductive film, 240: conductor, 245: conductor, 246: conductor, 250a: insulator, 250b: insulator, 250c: insulator, 250: insulator, 260a: conductor, 260A: conductive film, 260b: conductor, 260: conductor, 280a: insulator, 280b: insulator, 280c: insulator, 280: insulator, 281: insulator, 283: insulator, 287: insulator, 290: opening portion, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 400: first layer, 401: second layer, 403: mask, 405: mask, 407 a: resist mask, 407b: resist mask, 407c: resist mask, 408a: reaction product, 408b: reaction product, 417a: opening portion, 417b: opening portion, 417c: opening portion, 418a: opening portion, 418b: opening portion, 419a: opening portion, 419b: opening portion, 419c: opening portion, 641: insulator, 642: conductor, 643: conductor, 644: conductor, 645: conductor, 646: conductor, 647: insulator, 648: insulator, 700: electronic component, 702: printed circuit board, 704: mounting board, 710: semiconductor device, 711: mold, 712: land, 713: electrode pad, 714: wire, 715: driver circuit layer, 716: memory layer, 730: electronic component, 731: interposer, 732: package board, 733: electrode, 735: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A method for manufacturing a semiconductor device comprising:
forming a second layer over a first layer;
forming a mask over the second layer;
forming a first resist mask over the mask;
forming a first opening portion in the first resist mask;
reducing the first opening portion in size in a plan view;
forming a second opening portion in a position of the mask that overlaps with the first opening portion;
removing the first resist mask;
forming a second resist mask over the mask provided with the second opening portion;
forming a third opening portion in the second resist mask;
reducing the third opening portion in size in the plan view;
forming a fourth opening portion in a position of the mask that overlaps with the third opening portion and does not overlap with the second opening portion;
removing the second resist mask;
forming a fifth opening portion in each position of the second layer that overlaps with the second opening portion or overlaps with the fourth opening portion;
removing the mask; and
forming an oxide semiconductor in contact with a side surface of the second layer and a top surface of the first layer inside the fifth opening portion.

2. A method for manufacturing a semiconductor device comprising:
forming a second layer over a first layer;
forming a first mask over the second layer;
forming a second mask over the first mask;
forming a first resist mask over the second mask;
forming a first opening portion in the first resist mask;
reducing the first opening portion in size in a plan view;
forming a second opening portion in a position of the second mask that overlaps with the first opening portion;
removing the first resist mask;
forming a second resist mask over the second mask provided with the second opening portion;
forming a third opening portion in the second resist mask;
reducing the third opening portion in size in the plan view;
forming a fourth opening portion in a position of the second mask that overlaps with the third opening portion and does not overlap with the second opening portion;
removing the second resist mask;
forming a fifth opening portion in each position of the first mask that overlaps with the second opening portion or overlaps with the fourth opening portion;
removing the second mask;
forming a sixth opening portion in a position of the second layer that overlaps with the fifth opening portion;
removing the first mask; and
forming an oxide semiconductor in contact with a side surface of the second layer and a top surface of the first layer inside the sixth opening portion.

3. The method for manufacturing a semiconductor device according to claim 1, wherein the reduction in size of the first opening portion and the formation of the second opening portion are concurrently performed.

4. The method for manufacturing a semiconductor device according to claim 1, wherein the reduction in size of the third opening portion and the formation of the fourth opening portion are concurrently performed.

5. The method for manufacturing a semiconductor device according to claim 2,
wherein the second mask comprises a material same as at least a part of the second layer, and
wherein the second resist mask is removed during the formation of the sixth opening portion.

6. The method for manufacturing a semiconductor device according to claim 1, wherein the first layer is a conductor.

7. The method for manufacturing a semiconductor device according to claim 1,
wherein the second layer comprises an insulator of one or more layers and a conductor over the insulator.

8. The method for manufacturing a semiconductor device according to claim 1, wherein an ALD method is used in forming the oxide semiconductor.
